(19) United States
(12) Patent Application Publication
(10) Pub. No.: US 2025/0359133 A1
(43) Pub. Date: Nov. 20, 2025

(54) SEMICONDUCTOR DEVICE AND ELECTRONIC APPARATUS

(71) Applicant: SONY SEMICONDUCTOR SOLUTIONS CORPORATION, Kanagawa (JP)

(72) Inventors: Hideomi KUMANO, Tokyo (JP); Shoji KOBAYASHI, Kanagawa (JP); Koichiro SAGA, Kanagawa (JP)

(73) Assignee: SONY SEMICONDUCTOR SOLUTIONS CORPORATION, Kanagawa (JP)

(21) Appl. No.: 18/874,032

(22) PCT Filed: May 16, 2023
(86) PCT No.: PCT/JP2023/018307

§ 371 Date: Dec. 11, 2024

(30) Foreign Application Priority Data
Jun. 22, 2022 (JP) 2022-100212

(51) Int. Cl. H10D 30/62; H10D 30/01; H10D 62/10; H10D 64/68; H10F 39/00; H10F 39/18

(52) U.S. Cl. CPC H10D 30/6211; H10D 30/024; H10D 62/102; H10D 64/687; H10F 39/014; H10F 39/182

(57) ABSTRACT

A semiconductor device includes an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface, an insulating layer that surrounds each of the first portion and the second portion, a field effect transistor including a gate electrode that is separated from the second portion and is provided across the upper surface and the side surface of the first portion with a gate insulating film interposed therebetween, and a dielectric portion that is provided between the gate electrode and the second portion and is lower in relative permittivity than the insulating layer.

### TECHNICAL FIELD

The present technology (the technology according to the present disclosure) relates to a semiconductor device and an electronic apparatus, and more particularly to a technology effective when applied to a semiconductor device including a fin field effect transistor and an electronic apparatus including the semiconductor device.

### BACKGROUND ART

As a semiconductor device, for example, a solid-state imaging device called a CMOS image sensor is known. The CMOS image sensor includes a pixel circuit (reading circuit) that converts a signal charge generated as a result of photoelectric conversion in a photoelectric conversion element into a pixel signal and outputs the pixel signal. The pixel circuit includes pixel transistors such as an amplification transistor, a selection transistor, and a reset transistor.

On the other hand, as a field effect transistor mounted on a semiconductor device, a fin field effect transistor (Fin-FET) is known in which a gate electrode is provided in an island-shaped semiconductor (fin portion) with a gate insulating film interposed therebetween. Such a fin field effect transistor can improve short-channel characteristics and achieve a necessary operation even with a shorter gate length, which allows a reduction in planar size and is useful for high integration.

Patent Document 1 discloses a solid-state imaging device in which an amplification transistor included in a pixel circuit is implemented by a fin field effect transistor.

### CITATION LIST

### Patent Document

Patent Document 1: Japanese Patent Application Laid-Open No. 2021-034435

### SUMMARY OF THE INVENTION

### Problems to be Solved by the Invention

Meanwhile, even in such a fin field effect transistor, parasitic capacitance is added. Such parasitic capacitance becomes a factor that degrades noise characteristics of the field effect transistor and hinders improvement in reliability of the semiconductor device, so that there is room for improvement.

It is therefore an object of the present technology to provide a technology capable of improving reliability.

### Solutions to Problems

(1) A semiconductor device according to an aspect of the present technology includes:
an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including the upper surface and the side surface;
an insulating layer that surrounds each of the first portion and the second portion;
a field effect transistor including a gate electrode that is separated from the second portion and is provided across the upper surface and the side surface of the first portion; and
a dielectric portion that is provided between the gate electrode and the second portion and is lower in relative permittivity than the insulating layer.
(2) A method for manufacturing a semiconductor device according to another aspect of the present technology includes:
forming an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
forming an insulating layer that surrounds each of the first portion and the second portion;
forming a gate electrode that is separated from the second portion and faces the upper surface and the side surface of the first portion; and
forming a dielectric portion between the gate electrode and the second portion in the first direction, the dielectric portion being lower in relative permittivity than the insulating layer.
(3) A method for manufacturing a semiconductor device according to another aspect of the present technology includes:
forming an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
forming an insulating layer that surrounds each of the first portion and the second portion;
forming a recessed portion by selectively removing the insulating layer located outside the first portion in the second direction;
forming a conductive film that covers the semiconductor so as to be embedded in the recessed portion;
forming a gate electrode by patterning the conductive film, the gate electrode including a leg and head, the leg being located adjacent to the first portion and embedded in the recessed portion, the head being integrated with the leg, overlapping the first portion, and having a width in a direction identical to a width of the leg along the first direction smaller than the width of the leg;
forming an extension region by selectively ion-implanting an impurity into the semiconductor located outside the head with the leg present outside the head; and
removing the leg located outside the head.
(4) A semiconductor device according to another aspect of the present technology includes:
a semiconductor including an upper surface and a side surface; and
a field effect transistor provided in the semiconductor, in which
the semiconductor includes a first region and a pair of second regions that are provided contiguous with the first region on both sides of the first region in a first direction and are higher than the first region, and
the field effect transistor includes a gate electrode provided across the upper surface and the side surface of the first region with a gate insulating film interposed between the gate electrode and the first region, and a pair of main electrode regions provided in the pair of second regions.
(5) A method for manufacturing a semiconductor device according to another aspect of the present technology includes:
forming a semiconductor including a first portion, a pair of second portions provided contiguous with the first portion on both sides of the first portion in a first direction, and an upper surface and a side surface provided across the first portion and the second portions;
forming a gate electrode facing the upper surface and the side surface of the first portion with a gate insulating film interposed between the gate electrode and the first portion in a second direction intersecting the first direction;
making each of the pair of second portions higher than the first portion by epitaxial growth; and
forming a pair of main electrode regions in the pair of second portions.
(6) An electronic apparatus according to another aspect of the present technology includes the semiconductor device, an optical lens that forms an image of image light from a subject on an imaging surface of the semiconductor device, and a signal processing circuit that performs signal processing on a signal output from the semiconductor device.

### BRIEF DESCRIPTION OF DRAWINGS

FIG. 1 is a schematic plan view of a main part, illustrating a configuration example of a semiconductor device according to a first embodiment of the present technology.

FIG. 1A is a plan view of a planar pattern of a semiconductor in FIG. 1.

FIG. 2 is a schematic longitudinal cross-sectional view of a longitudinal cross-sectional structure taken along line a1-a1 in FIG. 1.

FIG. 3 is a schematic longitudinal cross-sectional view of a longitudinal cross-sectional structure taken along line b1-b1 in FIG. 1.

FIG. 4 is a schematic longitudinal cross-sectional view of a longitudinal cross-sectional structure taken along line c1-c1 in FIG. 1.

FIG. 5 is a schematic plan view of the main part, illustrating a step of a method for manufacturing a semiconductor device according to the first embodiment of the present technology.

FIG. 6 is a schematic longitudinal cross-sectional view of a longitudinal cross-sectional structure taken along line a5-a5 in FIG. 5.

FIG. 7 is a schematic longitudinal cross-sectional view of a longitudinal cross-sectional structure taken along line b5-b5 in FIG. 5.

FIG. 8 is a schematic longitudinal cross-sectional view of a longitudinal cross-sectional structure taken along line c5-c5 in FIG. 5.

FIG. 9 is a schematic plan view of the main part, illustrating a step subsequent to FIG. 5.

FIG. 10 is a schematic longitudinal cross-sectional view of a longitudinal cross-sectional structure taken along line a9-a9 in FIG. 9.

FIG. 11 is a schematic longitudinal cross-sectional view of a longitudinal cross-sectional structure taken along line b9-b9 in FIG. 9.

FIG. 12 is a schematic longitudinal cross-sectional view of a longitudinal cross-sectional structure taken along line c9-c9 in FIG. 9.

FIG. 13 is a schematic plan view of the main part, illustrating a step subsequent to FIG. 9.

FIG. 14 is a schematic longitudinal cross-sectional view of a longitudinal cross-sectional structure taken along line b13-b13 in FIG. 13.

FIG. 15 is a schematic longitudinal cross-sectional view of a longitudinal cross-sectional structure taken along line c13-c13 in FIG. 13.

FIG. 16 is a schematic plan view of the main part, illustrating a step subsequent to FIG. 13.

FIG. 17 is a schematic longitudinal cross-sectional view of a longitudinal cross-sectional structure taken along line a16-a16 in FIG. 16.

FIG. 18 is a schematic longitudinal cross-sectional view of a longitudinal cross-sectional structure taken along line b16-b16 in FIG. 16.

FIG. 19 is a schematic longitudinal cross-sectional view of a longitudinal cross-sectional structure taken along line c16-c16 in FIG. 16.

FIG. 20 is a schematic plan view of the main part, illustrating a step subsequent to FIG. 16.

FIG. 21 is a schematic longitudinal cross-sectional view of a longitudinal cross-sectional structure taken along line a20-a20 in FIG. 20.

FIG. 22 is a schematic longitudinal cross-sectional view of a longitudinal cross-sectional structure taken along line b20-b20 in FIG. 20.

FIG. 23 is a schematic longitudinal cross-sectional view of a longitudinal cross-sectional structure taken along line c20-c20 in FIG. 20.

FIG. 24 is a schematic plan view of the main part, illustrating a step subsequent to FIG. 20.

FIG. 25 is a schematic longitudinal cross-sectional view of a longitudinal cross-sectional structure taken along line a24-a24 in FIG. 24.

FIG. 26 is a schematic longitudinal cross-sectional view of a longitudinal cross-sectional structure taken along line b24-b24 in FIG. 24.

FIG. 27 is a schematic longitudinal cross-sectional view of a longitudinal cross-sectional structure taken along line c24-c24 in FIG. 24.

FIG. 28 is a schematic plan view of the main part, illustrating a step subsequent to FIG. 24.

FIG. 29 is a schematic longitudinal cross-sectional view of a longitudinal cross-sectional structure taken along line b28-b28 in FIG. 28.

FIG. 30 is a schematic plan view of the main part, illustrating a step subsequent to FIG. 28.

FIG. 31 is a schematic longitudinal cross-sectional view of a longitudinal cross-sectional structure taken along line a30-a30 in FIG. 30.

FIG. 32 is a schematic longitudinal cross-sectional view of a longitudinal cross-sectional structure taken along line b30-b30 in FIG. 30.

FIG. 33 is a schematic plan view of the main part, illustrating a step subsequent to FIG. 30.

FIG. 34 is a schematic longitudinal cross-sectional view of a longitudinal cross-sectional structure taken along line a33-a33 in FIG. 33.

FIG. 35 is a schematic longitudinal cross-sectional view of a longitudinal cross-sectional structure taken along line b33-b33 in FIG. 33.

FIG. 36 is a schematic longitudinal cross-sectional view of a field effect transistor of the first embodiment, illustrating parasitic capacitance added to the field effect transistor.

FIG. 37 is a schematic longitudinal cross-sectional view of a field effect transistor of a comparative example, illustrating parasitic capacitance added to the field effect transistor.

FIG. 38 is a schematic longitudinal cross-sectional view of a semiconductor device according to a modification of the first embodiment of the present technology.

FIG. 39 is a schematic plan view of the semiconductor device according to the modification of the first embodiment of the present technology.

FIG. 40 is a schematic longitudinal cross-sectional view of a configuration example of a semiconductor device according to a second embodiment of the present technology.

FIG. 41 is a schematic plan view of a main part, illustrating a configuration example of a semiconductor device according to a third embodiment of the present technology.

FIG. 42 is a schematic longitudinal cross-sectional view of a longitudinal cross-sectional structure taken along line a41-a41 in FIG. 41.

FIG. 43 is a schematic longitudinal cross-sectional view of a longitudinal cross-sectional structure taken along line b41-b41 in FIG. 41.

FIG. 44 is a schematic plan view of a semiconductor device according to a modification of the third embodiment of the present technology.

FIG. 45 is a schematic plan view of a main part, illustrating a step of a method for manufacturing a semiconductor device according to a fourth embodiment of the present technology.

FIG. 46 is a schematic longitudinal cross-sectional view of a longitudinal cross-sectional structure taken along line a45-a45 in FIG. 45.

FIG. 47 is a schematic longitudinal cross-sectional view of a longitudinal cross-sectional structure taken along line b45-b45 in FIG. 45.

FIG. 48 is a schematic longitudinal cross-sectional view of a longitudinal cross-sectional structure taken along line c45-c45 in FIG. 45.

FIG. 49 is a schematic plan view of the main part, illustrating a step subsequent to FIG. 45.

FIG. 50 is a schematic longitudinal cross-sectional view of a longitudinal cross-sectional structure taken along line b49-b49 in FIG. 49.

FIG. 51 is a schematic longitudinal cross-sectional view of a longitudinal cross-sectional structure taken along line c49-c49 in FIG. 49.

FIG. 52 is a schematic plan view of the main part, illustrating a step subsequent to FIG. 49.

FIG. 53 is a schematic longitudinal cross-sectional view of a longitudinal cross-sectional structure taken along line a52-a52 in FIG. 52.

FIG. 54 is a schematic longitudinal cross-sectional view of a longitudinal cross-sectional structure taken along line b52-b52 in FIG. 52.

FIG. 55 is a schematic longitudinal cross-sectional view of a longitudinal cross-sectional structure taken along line c52-c52 in FIG. 52.

FIG. 56 is a schematic plan view of the main part, illustrating a step subsequent to FIG. 52.

FIG. 57 is a schematic longitudinal cross-sectional view of a longitudinal cross-sectional structure taken along line a56-a56 in FIG. 56.

FIG. 58 is a schematic longitudinal cross-sectional view of a longitudinal cross-sectional structure taken along line b56-b56 in FIG. 56.

FIG. 59 is a schematic longitudinal cross-sectional view of a longitudinal cross-sectional structure taken along line c56-c56 in FIG. 56.

FIG. 60 is a schematic plan view of the main part, illustrating a step subsequent to FIG. 56.

FIG. 61 is a schematic longitudinal cross-sectional view of a longitudinal cross-sectional structure taken along line a60-a60 in FIG. 60.

FIG. 62 is a schematic longitudinal cross-sectional view of a longitudinal cross-sectional structure taken along line b60-b60 in FIG. 60.

FIG. 63 is a schematic plan view of the main part, illustrating a step subsequent to FIG. 60.

FIG. 64 is a schematic longitudinal cross-sectional view of a longitudinal cross-sectional structure taken along line a63-a63 in FIG. 63.

FIG. 64A is a schematic longitudinal cross-sectional view of a part obtained by partially enlarging FIG. 64.

FIG. 65 is a schematic longitudinal cross-sectional view of a longitudinal cross-sectional structure taken along line b63-b63 in FIG. 63.

FIG. 66 is a schematic plan view of the main part, illustrating a step subsequent to FIG. 63.

FIG. 67 is a schematic longitudinal cross-sectional view of a longitudinal cross-sectional structure taken along line a66-a66 in FIG. 66.

FIG. 67A is a schematic longitudinal cross-sectional view of a part obtained by partially enlarging FIG. 67.

FIG. 68 is a schematic longitudinal cross-sectional view of a longitudinal cross-sectional structure taken along line b66-b66 in FIG. 66.

FIG. 69 is a schematic plan view of the main part, illustrating a step subsequent to FIG. 66.

FIG. 70 is a schematic longitudinal cross-sectional view of a longitudinal cross-sectional structure taken along line a69-a69 in FIG. 69.

FIG. 71 is a schematic longitudinal cross-sectional view of a longitudinal cross-sectional structure taken along line b69-b69 in FIG. 69.

FIG. 72 is a schematic plan layout diagram illustrating a configuration example of a solid-state imaging device according to a fifth embodiment of the present technology.

FIG. 73 is a block diagram illustrating a configuration example of the solid-state imaging device according to the fifth embodiment of the present technology.

FIG. 74 is an equivalent circuit diagram illustrating a configuration example of a pixel and a pixel circuit of the solid-state imaging device according to the fifth embodiment of the present technology.

FIG. 75 is a schematic longitudinal cross-sectional view of a longitudinal cross-sectional structure of a pixel array unit of the solid-state imaging device according to the fifth embodiment of the present technology.

FIG. 76 is a schematic plan view of a main part, illustrating a configuration example of a semiconductor device according to a sixth embodiment of the present technology.

FIG. 77 is a schematic longitudinal cross-sectional view of a longitudinal cross-sectional structure taken along line a76-a76 in FIG. 76.

FIG. 78 is a schematic longitudinal cross-sectional view of a longitudinal cross-sectional structure taken along line b76-b76 in FIG. 76.

FIG. 79 is a schematic longitudinal cross-sectional view of a longitudinal cross-sectional structure taken along line c76-c76 in FIG. 76.

FIG. 80 is a schematic plan view of a main part, illustrating a step of a method for manufacturing the semiconductor device according to the sixth embodiment of the present technology.

FIG. 81 is a schematic longitudinal cross-sectional view of a longitudinal cross-sectional structure taken along line a80-a80 in FIG. 80.

FIG. 82 is a schematic longitudinal cross-sectional view of a longitudinal cross-sectional structure taken along line b80-b80 in FIG. 80.

FIG. 83 is a schematic longitudinal cross-sectional view of a longitudinal cross-sectional structure taken along line c80-c80 in FIG. 80.

FIG. 84 is a schematic plan view of the main part, illustrating a step subsequent to FIG. 80.

FIG. 85 is a schematic longitudinal cross-sectional view of a longitudinal cross-sectional structure taken along line 84a-a84 in 84a.

FIG. 86 is a schematic longitudinal cross-sectional view of a longitudinal cross-sectional structure taken along line b84-b84 in FIG. 84.

FIG. 87 is a schematic longitudinal cross-sectional view of a longitudinal cross-sectional structure taken along line c84-c84 in FIG. 84c.

FIG. 88 is a schematic plan view of the main part, illustrating a step subsequent to FIG. 84.

FIG. 89 is a schematic longitudinal cross-sectional view of a longitudinal cross-sectional structure taken along line a88-a88 in FIG. 88.

FIG. 90 is a schematic longitudinal cross-sectional view of a longitudinal cross-sectional structure taken along line b88-b88 in FIG. 88.

FIG. 91 is a schematic longitudinal cross-sectional view of a longitudinal cross-sectional structure taken along line c88-c88 in FIG. 88.

FIG. 92 is a schematic plan view of the main part, illustrating a step subsequent to FIG. 88.

FIG. 93 is a schematic longitudinal cross-sectional view of a longitudinal cross-sectional structure taken along line a92-a92 in FIG. 92.

FIG. 94 is a schematic longitudinal cross-sectional view of a longitudinal cross-sectional structure taken along line b92-b92 in FIG. 92.

FIG. 95 is a schematic longitudinal cross-sectional view of a longitudinal cross-sectional structure taken along line c928-c92 in FIG. 92.

FIG. 96 is a schematic plan view of the main part, illustrating a step subsequent to FIG. 92.

FIG. 97 is a schematic longitudinal cross-sectional view of a longitudinal cross-sectional structure taken along line a96-a96 in FIG. 96.

FIG. 98 is a schematic longitudinal cross-sectional view of a longitudinal cross-sectional structure taken along line b96-b96 in FIG. 96.

FIG. 99 is a schematic longitudinal cross-sectional view of a longitudinal cross-sectional structure taken along line c96-c96 in FIG. 96.

FIG. 100 is a schematic plan view of the main part, illustrating a step subsequent to FIG. 96.

FIG. 101 is a schematic longitudinal cross-sectional view of a longitudinal cross-sectional structure taken along line a100-a100 in FIG. 100.

FIG. 102 is a schematic longitudinal cross-sectional view of a longitudinal cross-sectional structure taken along line b100-b100 in FIG. 100.

FIG. 103 is a schematic longitudinal cross-sectional view of a longitudinal cross-sectional structure taken along line c100-c100 in FIG. 100.

FIG. 104 is a schematic plan view of the main part, illustrating a step subsequent to FIG. 100.

FIG. 105 is a schematic longitudinal cross-sectional view of a longitudinal cross-sectional structure taken along line a104-a104 in FIG. 104.

FIG. 106 is a schematic longitudinal cross-sectional view of a longitudinal cross-sectional structure taken along line b104-b104 in FIG. 104.

FIG. 107 is a schematic longitudinal cross-sectional view of a longitudinal cross-sectional structure taken along line c104-c104 in FIG. 104.

FIG. 108 is a schematic plan view of the main part, illustrating a step subsequent to FIG. 104.

FIG. 109 is a schematic longitudinal cross-sectional view of a longitudinal cross-sectional structure taken along line a108-a108 in FIG. 108.

FIG. 110 is a schematic longitudinal cross-sectional view of a longitudinal cross-sectional structure taken along line b108-b108 in FIG. 108.

FIG. 111 is a schematic plan view of the main part, illustrating a step subsequent to FIG. 108.

FIG. 112 is a schematic longitudinal cross-sectional view of a longitudinal cross-sectional structure taken along line a111-a111 in FIG. 111.

FIG. 113 is a schematic longitudinal cross-sectional view of a longitudinal cross-sectional structure taken along line b111-b111 in FIG. 111.

FIG. 114 is a schematic longitudinal cross-sectional view of a longitudinal cross-sectional structure taken along line c111-c111 in FIG. 111.

FIG. 115 is a schematic longitudinal cross-sectional view of a longitudinal cross-sectional structure at the same position as line a111-a111 in FIG. 111, illustrating a step subsequent to FIG. 111.

FIG. 116 is a schematic longitudinal cross-sectional view of a longitudinal cross-sectional structure at the same position as line b111-b111 in FIG. 111, illustrating a step subsequent to FIG. 115.

FIG. 117 is a schematic longitudinal cross-sectional view of a longitudinal cross-sectional structure at the same position as line a111-a111 in FIG. 111, illustrating a step subsequent to FIG. 115.

FIG. 118 is a schematic longitudinal cross-sectional view of a longitudinal cross-sectional structure at the same position as line b111-b111 in FIG. 111, illustrating a step subsequent to FIG. 115.

FIG. 119 is a schematic longitudinal cross-sectional view of a configuration example of a semiconductor device according to a seventh embodiment of the present technology.

FIG. 120 is a schematic longitudinal cross-sectional view illustrating a step of a method for manufacturing the semiconductor device according to the seventh embodiment of the present technology.

FIG. 121 is a schematic longitudinal cross-sectional view illustrating a step subsequent to FIG. 120.

FIG. 122 is a schematic longitudinal cross-sectional view illustrating a step subsequent to FIG. 121.

FIG. 123 is a diagram illustrating a configuration example of an electronic apparatus according to an eighth embodiment of the present technology.

### MODE FOR CARRYING OUT THE INVENTION

Hereinafter, embodiments of the present technology will be described in detail with reference to the drawings.

In the illustration of the drawings referred to in the following description, the same or similar parts are denoted by the same or similar reference signs. It should be noted that the drawings are schematic, and a relationship between a thickness and a planar dimension, a ratio of the thicknesses between layers, and the like are different from actual ones. Therefore, specific thicknesses and dimensions should be determined in consideration of the following description.

Furthermore, it goes without saying that dimensional relationships and ratios are partly different between the drawings. Furthermore, the effects described herein are merely examples and are not limited, and other effects may be provided.

Furthermore, the following embodiments illustrate devices and methods for embodying the technical idea of the present technology, and do not limit configurations to those described below. That is, the technical idea of the present technology may be modified in various ways within the technical scope described in the claims.

Furthermore, the definitions of directions such as up and down in the following description are merely defined for convenience of description, and do not limit the technical idea of the present technology. For example, it goes without saying that if a target is observed while being rotated by 90°, the up and down are converted into left and right, and if the target is observed while being rotated by 180°, the up and down are inverted.

Furthermore, in the following embodiments, a case will be exemplarily described where a first conductivity type is p-type and a second conductivity type is n-type, but the relationship between the conductivity types may be inversed, that is, the first conductivity type may be n-type and the second conductivity type may be p-type.

Furthermore, in the following embodiments, in three directions orthogonal to each other in a space, a first direction and a second direction orthogonal to each other in the same plane are defined as an X direction and a Y direction, respectively, and a third direction orthogonal to the first direction and the second direction is defined as a Z direction. Then, in the following embodiments, a thickness direction of a semiconductor layer 2, which will be described later, will be described as the Z direction.

### First Embodiment

In the first embodiment, an example where the present technology is applied to a semiconductor device 1A including a semiconductor 5 in which a second portion 7 is provided on both end sides of a first portion 6 in the first direction (X direction) will be described.

### <<Overall Configuration of Semiconductor Device>>

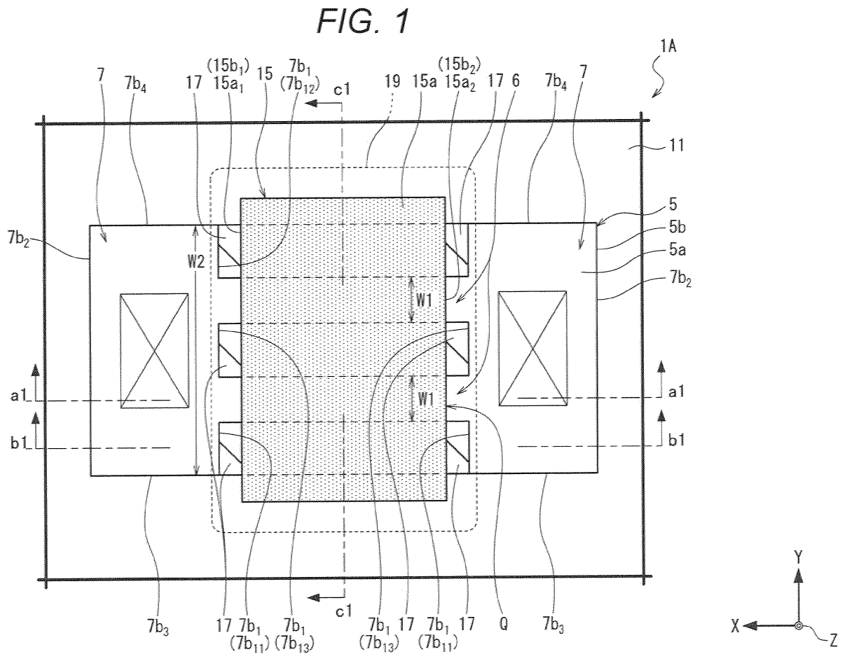

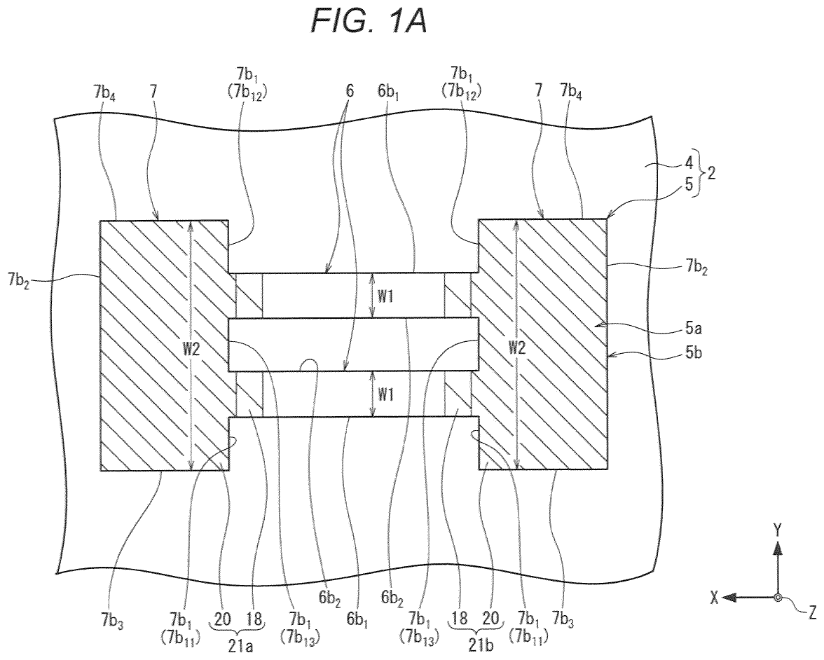

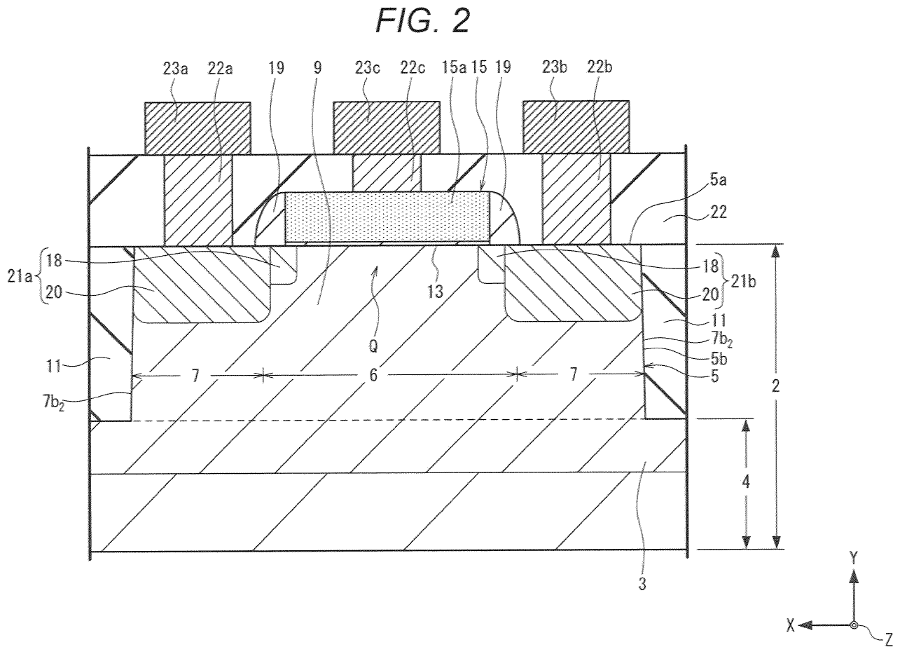

First, an overall configuration of a semiconductor device 1A will be described with reference to FIGS. 1 and 1A, and 2 to 4. In FIG. 1, illustration of an insulating layer 22, contact electrodes 22a, 22b, and 22c, and wires 23a, 23b, and 23c illustrated in FIGS. 2 to 4 is omitted for convenience of description.

As illustrated in FIGS. 1, 1A, and 2 to 4, the semiconductor device 1A according to the first embodiment of the present technology includes the island-shaped semiconductor 5 provided in the semiconductor layer 2, and a field effect transistor Q provided in the semiconductor 5. Furthermore, the semiconductor device 1A according to the first embodiment includes an insulating layer 11 provided outside the semiconductor 5 so as to surround the semiconductor 5.

### <Semiconductor Layer>

As illustrated in FIGS. 1, 1A, and 2 to 4, the semiconductor layer 2 includes a base 4 extending two-dimensionally in the X and Y directions, and the island-shaped semiconductor 5 protruding above (in the Z direction) the base 4.

The semiconductor 5 has a three-dimensional structure that includes the first portion 6 extending in the X direction (first direction), and the second portion 7 that is provided integrally alongside the first portion 6 (contiguous with the first portion 6) in the X direction and has a width W2 in a direction identical to a width W1 of the first portion 6 along the Y direction intersecting the X direction larger than the width W1 of the first portion 6, and in which the first portion 6 and the second portion 7 have an upper surface 5a and a side surface 5b.

The semiconductor 5 of the first embodiment has a three-dimensional structure including, but not limited to, two first portions 6 provided side by side at a predetermined interval in the Y direction, and two second portions 7 provided on both end sides of each of the two first portions 6 in the X direction, for example. The two first portions 6 and the two second portions 7 each have a rectangular planar shape in plan view. In the X direction, each of the two first portions 6 has one end connected to one of the two second portions 7 and the other end connected to the other of the two second portions 7.

As illustrated in FIGS. 1, 1A, and 2 to 4, the semiconductor 5 includes the upper surface 5a that is located on a side of the semiconductor 5 remote from the base 4 and extends two-dimensionally across the two first portions 6 and the two second portions 7, and the side surface 5b that extends two-dimensionally across the two first portions 6 and the two second portions 7 of the semiconductor 5 in the thickness direction (Z direction).

As illustrated in FIG. 1A, the side surface 5b includes side surfaces 6b₁ and 6b₂ located on the opposite sides of the first portion 6 in the Y direction, side surfaces 7b₁ and 7b₂ located on the opposite sides of the second portion 7 in the X direction, and side surfaces 7b₃ and 7b₄ located on the opposite sides of the second portion 7 in the Y direction. The side surface 7b₁ of the second portion 7 is divided into three portions (7b₁₁, 7b₁₂, and 7b₁₃) by a connecting portion where the first portion 6 is connected to the second portion 7.

The first side surface 7b₁ (7b₁₁) of the three side surfaces 7b₁ is located adjacent to the side surface 6b₁ of one of the two first portions 6. The second side surface 7b₁ (7b₁₂) of the three side surfaces 7b₁ is located adjacent to the side surface 6b₁ of the other of the two first portions 6. Then, the remaining third side surface 7b₁ (7b₁₃) is located adjacent to the side surface 6b₂ of each of the two first portions 6, in other words, between the two first portions 6. That is, the side surface 5b of the semiconductor 5 includes the side surfaces 6b₁ and 6b₂ of each of the two first portions 6 and the side surfaces 7b₁, 7b₂, 7b₃, and 7b₄ of the each of two second portions 7.

It is possible to form the semiconductor 5 including the first portion 6 and the second portion 7 by selectively etching the semiconductor layer 2 to such a depth that the base 4 remains. The semiconductor layer 2 can be, but not limited to, a semiconductor substrate that includes, for example, silicon (Si) as a semiconductor material, is, for example, monocrystalline as crystallinity, and is, for example, of a p-conductive type as a conductivity type.

As illustrated in FIGS. 2 to 4, the semiconductor layer 2 is provided with a p-type well region 3, which is, for example, a p-type semiconductor region. The p-type well region 3 is provided throughout the semiconductor 5 and provided throughout a surface layer of the base 4 adjacent to the semiconductor 5. Then, the p-type well region 3 is separated from a back surface of the base 4 remote from the semiconductor 5.

### <Insulating Layer>

As illustrated in FIGS. 2 to 4, the insulating layer 11 is provided on a side of the base 4 of the semiconductor layer 2 adjacent to the semiconductor 5 so as to surround the semiconductor 5. The insulating layer 11 has a surface layer remote from the base 4 of the semiconductor layer 2 planarized, and the insulating layer 11 has a film thickness almost equal to the height (protrusion) of the semiconductor 5 except for recessed portions 12a and 12b to be described later. The insulating layer 11 include, for example, a silicon oxide (SiO₂) film.

As illustrated in FIGS. 2 to 4, on the side of the insulating layer 11 remote from the base 4, the insulating layer 22 is provided to cover a head 15a of a gate electrode 15 of the field effect transistor Q to be described later and the semiconductor 5. The insulating layer 22 also includes, for example, a silicon oxide (SiO₂) film.

On a side of the insulating layer 22 remote from the semiconductor 5, a first wiring layer including the wires 23a, 23b, and 23c is provided. The wires 23a, 23b, and 23c of the first wiring layer each include, for example, a metal film of aluminum (Al), copper (Cu), or the like or an alloy film mainly containing Al or Cu.

### <Field Effect Transistor>

The field effect transistor Q illustrated in FIG. 1 is of, but not limited to, an n-channel conductivity type. Then, the field effect transistor Q includes a metal oxide semiconductor field effect transistor (MOSFET) in which a gate insulating film includes a silicon oxide (SiO₂) film. The field effect transistor Q may be of a p-channel conductivity type, instead. Alternatively, the field effect transistor Q may include a metal insulator semiconductor FET (MISFET) in which a gate insulating film includes a silicon nitride film or a multilayer film (composite film) including a silicon nitride (Si₃N₄) film and a silicon oxide film.

As illustrated in FIGS. 1 and 2 to 4, the field effect transistor Q is provided in the semiconductor 5 of the semiconductor layer 2.

The field effect transistor Q includes a channel formation portion 9 provided in the first portion 6 of the semiconductor 5, and the gate electrode 15 that is separated from the second portion 7 of the semiconductor 5 and is provided across the upper surface 5a and the side surfaces 6b₁ and 6b₂ of the first portion 6 of the semiconductor 5 with a gate insulating film 13 interposed therebetween.

Furthermore, the field effect transistor Q includes a sidewall spacer 19 provided on a sidewall of the gate electrode 15 so as to surround the gate electrode 15, and a pair of main electrode regions 21a and 21b provided in the semiconductor 5 on both sides of the gate electrode 15 in a gate length direction (X direction) and functioning as a source region and a drain region.

### <Gate Electrode>

As illustrated in FIGS. 2 to 4, the gate electrode 15 includes the head 15a provided on the upper surface 5a of the first portion 6 of the semiconductor 5 with the gate insulating film 13 interposed therebetween, and a leg 15b integrated with the head 15 and provided outside each of the two side surfaces 6b₁ and 6b₂ located on the opposite sides of the first portion 6 of the semiconductor 5 with the gate insulating film 13 interposed therebetween.

Here, the gate electrode 15 is preferably configured such that the first portion 6 of the semiconductor 5 is sandwiched between the legs 15b in the width direction (Y direction). Therefore, when the number of the first portions 6 is denoted by “n”, the number of the legs 15b of gate electrode 15 is normally “n+1”. In the first embodiment, since two first portions 6 are provided, the gate electrode 15 includes three legs 15b.

The head 15a of the gate electrode 15 protrudes above the insulating layer 11. Then, each of the three legs 15b of the gate electrode 15 is provided in the insulating layer 11 together with the semiconductor 5. The gate electrode 15 including the head 15a and the legs 15b includes, for example, a polycrystalline silicon (doped polysilicon) film doped with an impurity for reducing a resistance value.

The head 15a has a rectangular shape in plan view, and has a three-dimensional structure including an upper surface and four side surfaces. Each of the three legs 15b has a three-dimensional structure extending from the head 15a in the thickness direction (Z direction) of the semiconductor layer 2 and in the height direction of the semiconductor 5 and including a lower surface and four side surfaces.

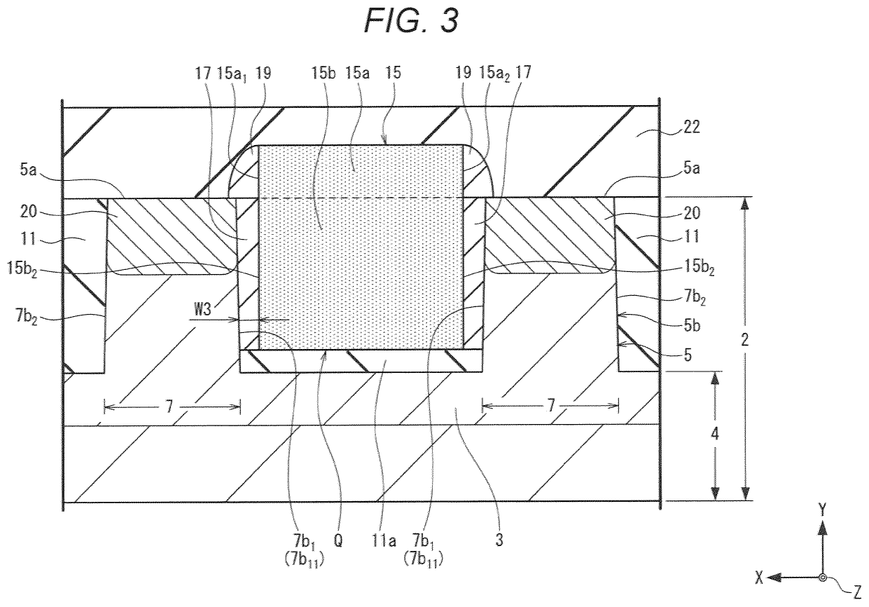

As illustrated in FIG. 3, the gate electrode 15 has two side surfaces 15a₁ and 15a₂ of the head 15a in the X direction (gate length direction) and two side surfaces 15b₁ and 5b₂ of the leg 15b in the X direction (gate length direction) flush with each other in cross-sectional view. In other words, the side surface 15a₁ of the head 15a and the side surface 15b₁ of the leg 15b form one flat surface continuously extending in the thickness direction (Z direction) of the semiconductor layer 2, and the side surface 15a₂ of the head 15a and the side surface 15b₂ of the leg 15b form one flat surface continuously extending in the thickness direction (Z direction) of the semiconductor layer 2.

Herein, the plan view refers to a case where the semiconductor layer 2 is viewed from a direction along the thickness direction (Z direction) of the semiconductor layer 2. Furthermore, the cross-sectional view refers to a case where a longitudinal cross section along the thickness direction (Z direction) of the semiconductor layer 2 is viewed from a direction (X direction or Y direction) orthogonal to the thickness direction (Z direction) of the semiconductor layer 2.

### <Gate Insulating Film>

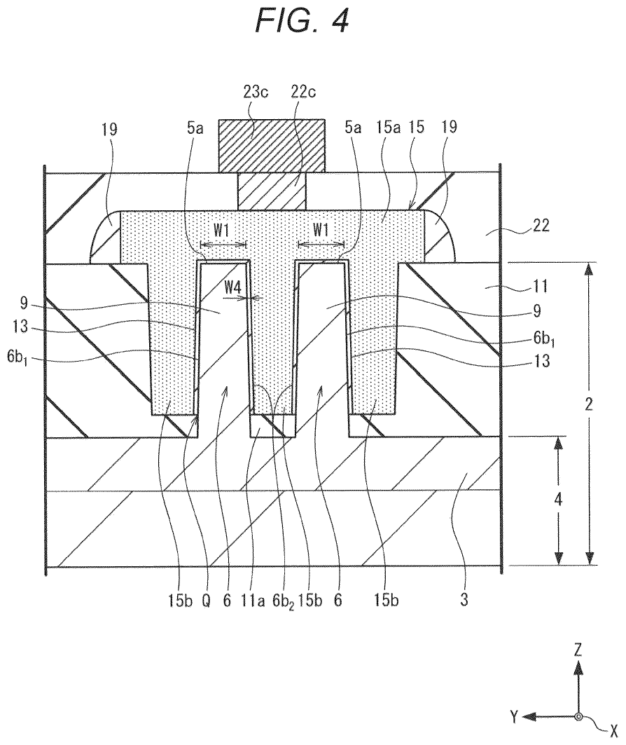

As illustrated in FIG. 4, the gate insulating film 13 is provided between the first portion 6 of the semiconductor 5 and the gate electrode 15 across the upper surface 5a of the first portion 6 and the two side surfaces 6b₁ and 6b₂ of the first portion 6. In the first embodiment, since the semiconductor 5 includes the two first portions 6, the gate insulating film 13 is provided across the upper surface 5a and the two side surfaces 6b₁ and 6b₂ of each of the two first portions 6. The gate insulating film 13 includes, for example, a silicon oxide film.

### <Sidewall Spacer>

As illustrated in FIGS. 1 and 2 to 4, the sidewall spacer 19 is provided on a sidewall of the head 15a of the gate electrode 15 so as to surround the head 15a. That is, the sidewall spacer 19 extends across the first portion 6 located outside the gate electrode 15 in the gate length direction (X direction) and a dielectric portion 17 to be described later in plan view to cover the first portion 6 located outside the gate electrode 15 in the gate length direction (X direction) and the dielectric portion 17.

The sidewall spacer 19 is provided in alignment with the head 15a of the gate electrode 15. In other words, the sidewall spacer 19 is formed in a self-aligned manner with respect to the head 15a of the gate electrode 15. It is possible to form the sidewall spacer 19, by, for example, forming an insulating film by a chemical vapor deposition (CVD) method on a side of the insulating layer 11 remote from the base 4 so as to cover the gate electrode 15, and then subjecting the insulating film to anisotropic dry-line etching such as reactive ion etching (RIE). The sidewall spacer 19 includes, for example, a silicon oxide film.

### <Main Electrode Region>

As illustrated in FIG. 2, each of the pair of main electrode regions 21a and 21b includes an n-type extension region 18 including an n-type semiconductor region provided in the semiconductor 5 in alignment with the gate electrode 15, and an n-type contact region 20 including an n-type semiconductor region provided in the semiconductor 5 in alignment with the sidewall spacer 19 located on the sidewall of the gate electrode 15. That is, each of the pair of main electrode regions 21a and 21b including the n-type extension region 18 and the n-type contact region 20 is provided in the semiconductor 5 in alignment with the gate electrode 15. Most of the n-type extension region 18 is provided in the first portion 6 of the semiconductor 5. Most of the n-type contact region 20 is provided in the second portion 7 of the semiconductor 5.

As illustrated in FIG. 1A, the n-type contact region 20 is provided throughout the second portion 7 of the semiconductor 5 in plan view, and is in contact with the side surfaces 7b₁ (7b₁₁, 7b₁₂, 7b₁₃), 7b₂, 7b₃, and 7b₄ of the second portion 7. The n-type contact region 20 and the n-type extension region 18 are in contact with each other in the first portion 6 of the semiconductor 5.

As illustrated in FIG. 3, the n-type extension region 18 and the n-type contact region 20 each have a thickness in the thickness direction (Z direction) of the semiconductor layer 2 and in the height direction of the semiconductor 5. Then, the n-type contact region 20 is formed deeper than the n-type extension region 18, in other words, is formed thicker.

As illustrated in FIGS. 2 and 4, the field effect transistor Q of the first embodiment is configured as a so-called fin type in which the gate electrode 15 is provided in the island-shaped semiconductor 5 as a fin portion with the gate insulating film 13 interposed therebetween.

In such a fin field effect transistor Q, a length between the pair of main electrode regions 21a and 21b is a channel length L (≈gate length Lg), and a value obtained by multiplying a length including the width W1 of the first portion 6 on the upper surface 5a side and a height of the two side surfaces 6b₁ and 6b₂ of the first portion 6 (length of a contour of the semiconductor 5) in a region where the gate electrode 15 and the first portion 6 of the semiconductor 5 overlap each other in three dimensions by the number of the first portions 6 is a channel width W (≈gate width).

It is therefore possible for the fin field effect transistor Q to increase the channel width W by increasing the width W1 of the first portion 6 of the semiconductor 5 and the height of the first portion 6, thereby allowing an increase in channel area (channel length L×channel width W). Then, it is possible for the fin field effect transistor Q to increase the channel area (channel length L×channel width W) by increasing the number of the first portions 6.

The field effect transistor Q is, for example, of an enhancement type (normally-off type) in which a drain current flows when a gate voltage higher than or equal to a threshold voltage is applied to the gate electrode 15 or a depression type (normally-off type) in which a drain current flows even with no voltage applied to the gate electrode 15. The first embodiment employs, but not limited to, the enhancement type, for example. In the case of the enhancement type, in the field effect transistor Q, a channel (inversion layer) electrically connecting the pair of main electrode regions 21a and 21b is formed (induced) in the channel formation portion 9 by a voltage applied to the gate electrode 15, and a current (drain current) flows from a drain region side (e.g., the main electrode region 21b side) to a source region side (e.g., the main electrode region 21a side) through the channel of the channel formation portion 9.

### <Contact Electrode and Wire>

As illustrated in FIG. 2, the gate electrode 15 is electrically connected to the wire 23c located on the insulating layer 22 via the contact electrode 22c provided in the insulating layer 22. Furthermore, the main electrode region 21a that is one of the pair of main electrode regions 21a and 21b is electrically connected to the wire 23a located on the insulating layer 22 via the contact electrode 22a provided in the insulating layer 22. Then, the main electrode region 21b that is the other of the pair of main electrode regions 21a and 21b, on the other hand, is electrically connected to the wire 23b located on the insulating layer 22 via the contact electrode 22b provided in the insulating layer 22. As a material of the contact electrodes 22a, 22b, and 22c, for example, a high melting point metal film such as titanium (Ti) or tungsten (W) can be used.

### <Dielectric Portion>

As illustrated in FIGS. 1 and 3, the semiconductor device 1A according to the first embodiment further includes the dielectric portion (isolation region) 17 that is provided between the gate electrode 15 and the second portion 7 of the semiconductor 5 in the X direction (first direction) and is lower in relative permittivity lower the insulating layer 11. Specifically, the dielectric portion 17 is provided between the side surface 7b₁ of the second portion 7 and the leg 15b of the gate electrode 15.

In the first embodiment, since the semiconductor 5 includes the two second portions 7, the dielectric portion 17 is provided between one of the two second portions 7 and the leg 15b of the gate electrode 15, and between the other of the two second portions 7 and the leg 15b of the gate electrode 15. That is, in the first embodiment, the dielectric portion 17 is provided on either side of the gate electrode 15 in the gate length direction (X direction).

Furthermore, in the first embodiment, since the semiconductor 5 includes the two first portions 6, the dielectric portion 17 is provided between each of the three side surfaces 7b₁ (7b₁₁, 7b₁₂, 7b₁₃) of the second portion 7 and the leg 15b of the gate electrode 15.

That is, in the first embodiment, three dielectric portions 17 separated from each other by the two first portions 6 are provided between the side surface part 7b₁ of one of the two second portions 7 and the leg 15b of the gate electrode 15, and three dielectric portions 17 separated from each other by the two first portions 6 are further provided between the side surface part 7b₁ of the other of the two second portions 7 and the leg 15b of the gate electrode 15.

In other words, the dielectric portion 17 is provided on either side of the first portion 6 in the width direction (Y direction) between the side surface 7b₁ of one second portion 7 and the leg 15b of the gate electrode 15 so as to sandwich the first portion 6. Then, also on the other second portion 7 side, the dielectric portion 17 is provided on either side of the first portion 6 in the width direction (Y direction) between the side surface 7b₁ of the other second portion 7 and the leg 15b of the gate electrode 15 so as to sandwich the first portion 6.

As illustrated in FIG. 3, the dielectric portion 17 between the side surface 7b₁₁ of the second portion 7 and the leg 15b of the gate electrode 15 extends from the upper surface 5a of the second portion 7 toward the base 4 (in the depth direction (Z direction) of the semiconductor layer 2), and is connected to an insulating layer 11a provided on a bottom surface of the leg 15b of the gate electrode 15. The dielectric portion 17 electrically isolates the second portion 7 of the semiconductor 5 from the leg 15b of the gate electrode 15, and electrically isolates the first portion 6 from the leg 15b of the gate electrode 15 between the second portion 7 and the leg 15a of the gate electrode 15.

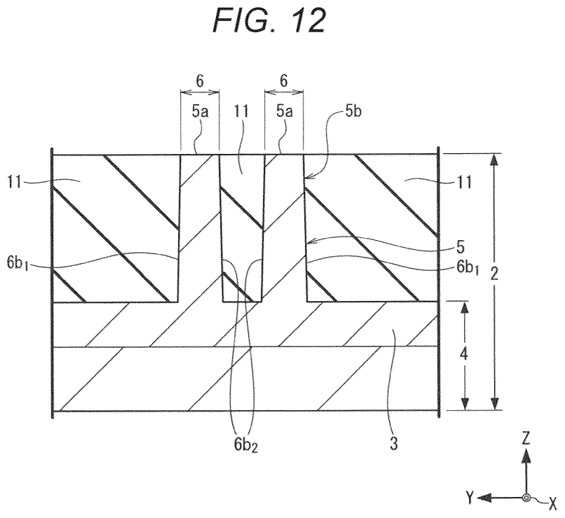

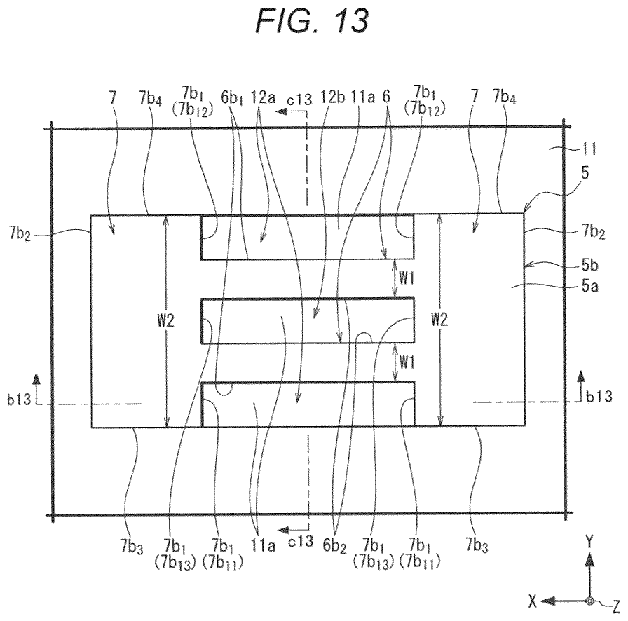

Here, in a manufacturing process of the semiconductor device 1A, the insulating layer 11a illustrated in FIG. 3 is obtained by selectively etching the insulating layer 11 between the two second portions 7 of the semiconductor 5 to form the recessed portions 12a and 12b (see FIGS. 13 to 15) with a smaller height (thickness) than the semiconductor 5, so as to cause the insulating layer 11 to remain on a bottom surface of each of the recessed portions 12a and 12b.

In the first embodiment, the insulating layer 11a is provided, but the insulating layer 11a need not be provided. In this case, a gate insulating film is interposed between the bottom surface of the leg 15b of the gate electrode 15 and the base 4 of the semiconductor layer 2.

Note that, in FIG. 3, the dielectric portion 17 between the side surface 7b₁₁ of the second portion 7 and the leg 15b of the gate electrode 15 is illustrated as an example, but the dielectric portion 17 between the side surface 7b₁₂ of the second portion 7 and the leg 15b of the gate electrode 15 and the dielectric portion 17 between the side surface 7b₁₃ of the second portion 7 and the leg 15b of the gate electrode 15 also have the same configuration as of the dielectric portion 17 illustrated in FIG. 3. Therefore, the dielectric portion 17 between the side surface 7b₁₂ of the second portion 7 and the leg 15b of the gate electrode 15, and the dielectric portion 17 between the side surface 7b₁₃ of the second portion 7 and the leg 15b of the gate electrode 15 will be described with reference to FIG. 3.

As illustrated in FIGS. 1 and 3, the dielectric portion 17 between side surface 7b₁₁ of the second portion 7 and the leg 15b of the gate electrode 15 is surrounded by the first portion 6, the second portion 7, the leg 15b of gate electrode 15, and the insulating layer 11 on all sides in plan view. Similarly, the dielectric portion 17 between the side surface 7b₁₂ of the second portion 7 and the leg 15b of the gate electrode 15 is also surrounded by the first portion 6, the second portion 7, the leg 15b of the gate electrode 15, and the insulating layer 11 on all sides in plan view.

On the other hand, the dielectric portion 17 between the side surface 7b₁₃ of the second portion 7 and the leg 15b of the gate electrode 15 is surrounded by the two first portions 6, the second portion 7, and the leg 15b of the gate electrode 15 on all sides in plan view.

The dielectric portion 7 is not limited to such a configuration, and includes, for example, a dielectric film (Low-k film) lower in relative permittivity than the insulating layer 11. As such a dielectric film, for example, a carbon-doped silicon oxide (SiOC) film obtained by doping silicon oxide (SiO) with carbon (C) can be used. The SiOC film is lower in relative permittivity than the silicon oxide film. For example, the relative permittivity of the SiOC film is about 1.5 to 2, the relative permittivity of the silicon oxide film is about 4 to 4.2, and the relative permittivity of air is about 1.

Note that the dielectric portion 7 is preferably lower in relative permittivity than the gate insulating film 13. Furthermore, a width W3 (see FIG. 3) of the dielectric portion 7 along the X direction is preferably larger than a film thickness W4 (see FIG. 4) of the gate insulating film 11.

### <<Method for Manufacturing Semiconductor Device>>

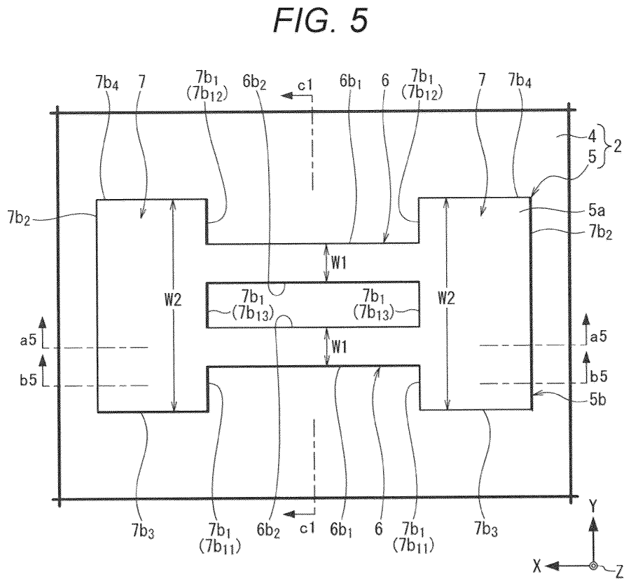

Next, a method for manufacturing the semiconductor device 1A will be described with reference to FIGS. 5 to 35.

In the first embodiment, a description will be given focusing on the formation of the field effect transistor Q and the dielectric portion 17 included in the method for manufacturing the semiconductor device 1A.

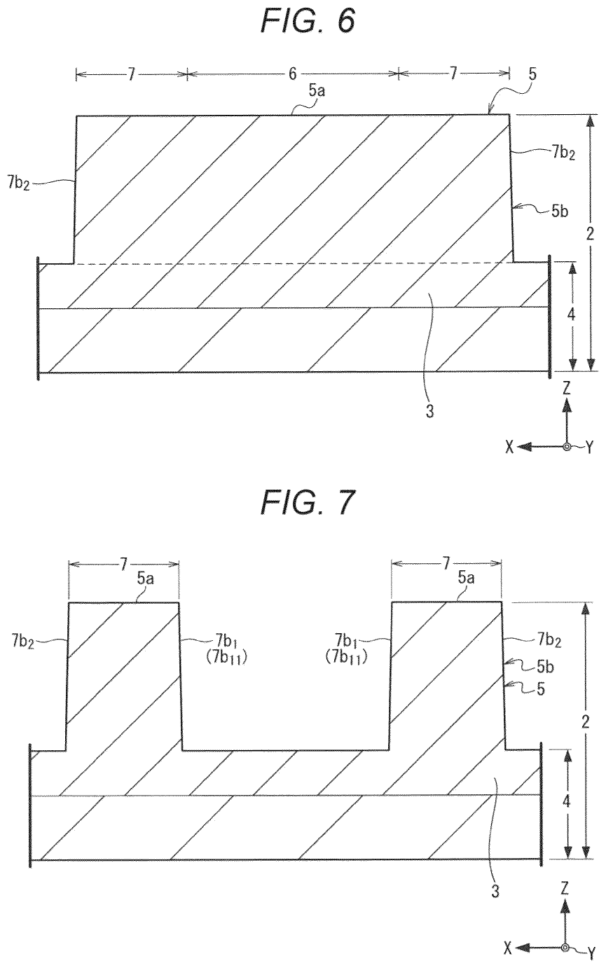

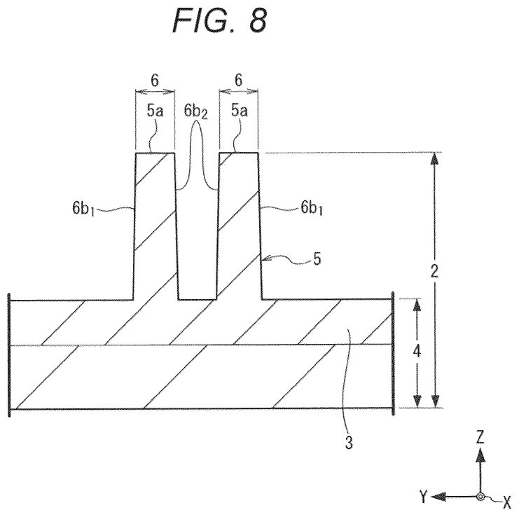

First, as illustrated in FIG. 5 (schematic plan view of the main part), FIG. 6 (schematic cross-sectional view taken along line a5-a5 in FIG. 5), FIG. 7 (schematic cross-sectional view taken along line b5-b5 in FIG. 5), and FIG. 8 (schematic cross-sectional view taken along line c5-c5 in FIG. 5), the island-shaped semiconductor 5 protruding above the base 4 is formed.

The semiconductor 5 is formed in a three-dimensional structure that includes the first portion 6 extending in the X direction (first direction), and the second portion 7 that is provided integrally alongside the first portion 6 in the X direction and has the width W2 in a direction identical to the width W1 of the first portion 6 along the Y direction (second direction) intersecting the X direction larger than the width W1 of the first portion 6, and in which the first portion 6 and the second portion 7 have the upper surface 5a and the side surface 5b. The side surface 5b includes the side surfaces 6b₁ and 6b₂ of the first portion 6 and the side surfaces 7b₁, 7b₂, 7b₃, and 7b₄ of the second portion 7.

In the first embodiment, for example, the semiconductor 5 is formed in, but not limited to, a three-dimensional structure including two first portions 6 provided side by side at a predetermined interval in the Y direction and two second portions 7 provided on both end sides of each of the two first portions 6 in the X direction. In this case, the side surface 5b includes, as the side surface 7b₁, three side surfaces 7b₁₁, 7b₁₂, and 7b₁₃ obtained by dividing the side surface 7b₁ by a connecting portion where the first portion 6 is connected to the second portion 7.

It is possible to form the semiconductor 5 including the first portion 6 and the second portion 7 by selectively etching the semiconductor layer 2 to such a depth that the base 4 remains. The semiconductor layer 2 can be, but not limited to, a semiconductor substrate that includes, for example, silicon (Si) as a semiconductor material, is, for example, monocrystalline as crystallinity, and is, for example, of a p-conductive type as a conductivity type.

Note that, in the semiconductor layer 2, the p-type well region 3, which is a p-type semiconductor region, is formed before the semiconductor 5 is formed.

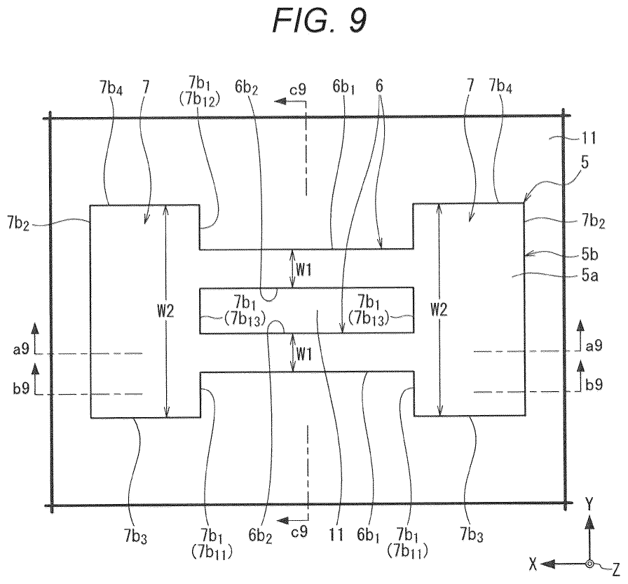

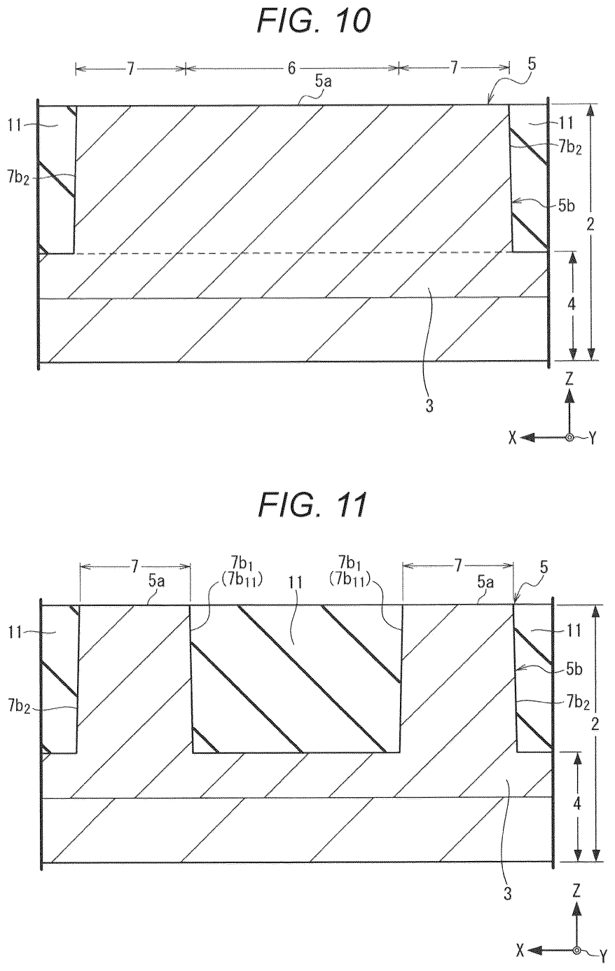

Next, as illustrated in FIG. 9 (schematic plan view of the main part), FIG. 10 (schematic cross-sectional view taken along line a9-a9 in FIG. 9), FIG. 11 (schematic cross-sectional view taken along line b9-b9 in FIG. 9), and FIG. 12 (schematic cross-sectional view taken along line c9-c9 in FIG. 9), the insulating layer 11 surrounding the first portion 6 and the second portion 7 of the semiconductor 5 is formed outside the semiconductor 5 in plan view. It is possible to form the insulating layer 11 by, for example, forming a silicon oxide film across a surface on the base 4 and the semiconductor 5 of the semiconductor layer 2 by a known film forming method, and then selectively removing the silicon oxide film on the semiconductor 5 by a CMP method.

In this step, a surface layer of the insulating layer 11 remote from the base 4 is planarized, and the surface layer of the insulating layer 11 and the upper surface 5a of the semiconductor 5 becomes almost flush with each other. Then, the insulating layer 11 is formed with a film thickness almost equal to the height (protrusion) of the semiconductor 5.

Furthermore, in this step, the insulating layer 11 flush with the upper surface 5a of the semiconductor 5 is also formed in a region surrounded by the two first portions 6 and the two second portions 7.

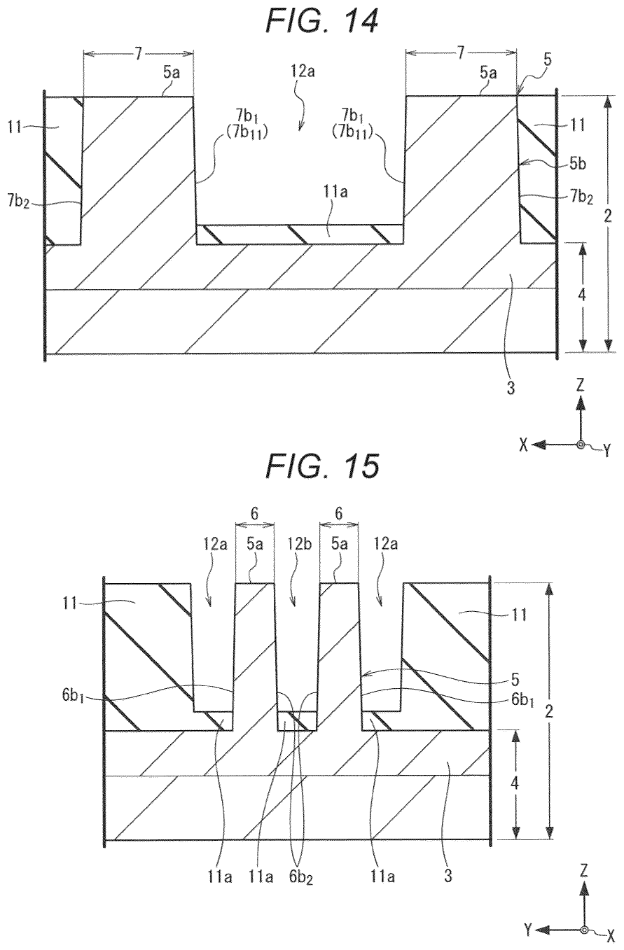

Next, the insulating layer 11 located outside the second portion 6 of the semiconductor 5 in the width direction (Y direction) is selectively removed to form the recessed portions 12a, 12a, and 12b that expose the sidewalls 6b₁ and 6b₂ of the first portion 6 and the sidewall 7b₁ of each of the two second portions 7 outside the first portion 6 of the semiconductor 5 in the width direction (Y direction) as illustrated in FIG. 13 (schematic plan view of the main part), FIG. 14 (schematic cross-sectional view taken along line b13-b13 in FIG. 13), and FIG. 15 (schematic cross-sectional view taken along line c13-c13 in FIG. 13).

One of the two recessed portion 12a and 12a is formed on a side of one of the first portions 6 remote from the other of the two first portions 6 to expose the side surface 6b₁ of the one first portion 6 and the side surface 7b₁ (7b₁₁) of each of the two second portions 7.

Furthermore, the other of the two recessed portions 12a and 12a is formed on a side of the other of the two first portions 6 remote from the one of the two first portions 6 to expose the side surface 6b₁ of the other first portion 6 and the side surface 7b₁ (7b₁₂) of each of the two second portions 7.

Then, the recessed portion 12b is formed between the two first portions 6 to expose the side surface 6b₂ of each of the two first portions 6 and the side surface 761 (7b₁₃) of each of the two second portions 7.

In this step, the recessed portions 12a and 12b are formed to, but not limited to, such a depth that a part of the insulating layer 11 remains as the insulating layer 11a on the bottom surface, for example.

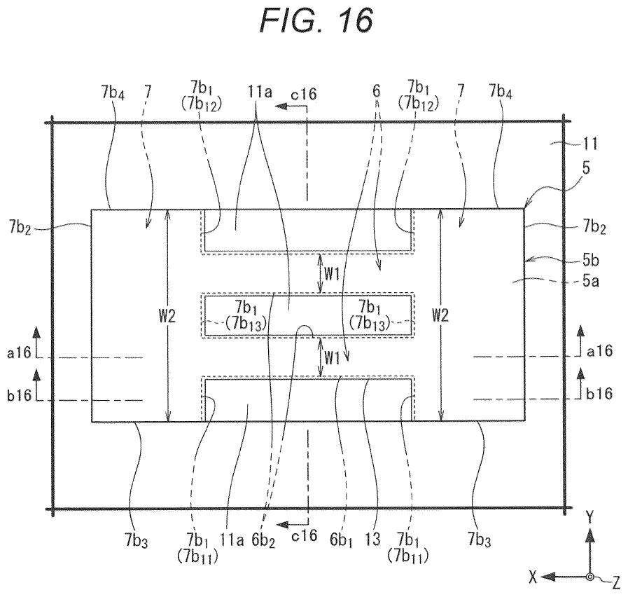

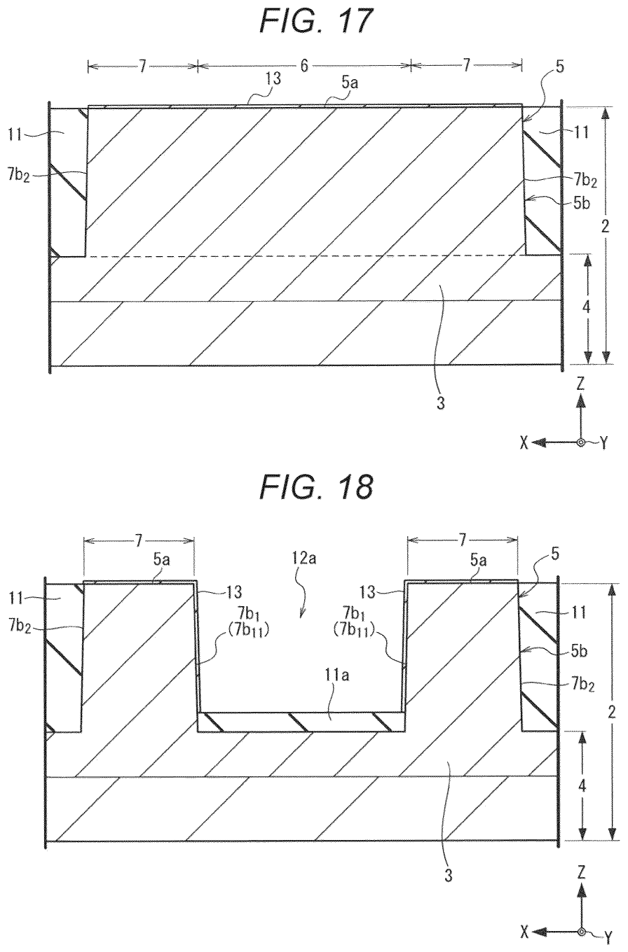

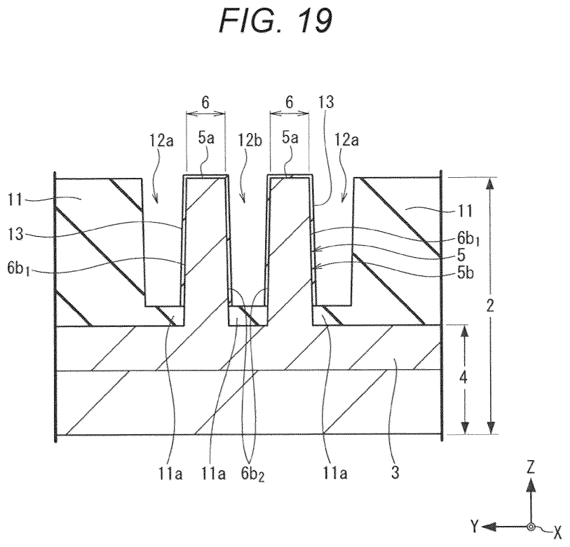

Next, as illustrated in FIG. 16 (schematic plan view of the main part), FIG. 17 (schematic cross-sectional view taken along line a16-a16 in FIG. 16), FIG. 18 (schematic cross-sectional view taken along line b16-b16 in FIG. 16), and FIG. 19 (schematic cross-sectional view taken along line c16-c16 in FIG. 16), the gate insulating film 13 is formed on the upper surface 5a of each of the two first portions 6 and the side surfaces 6b₁ and 6b₂ of each of the two first portions 6 of the semiconductor 5. It is possible to form the gate insulating film 13 by forming a silicon oxide film on the upper surface 5a and the side surfaces 6b₁ and 6b₂ of each of the two first portions 6 by, for example, a thermal oxidation method or a deposition method.

In this step, the gate insulating film 13 is further formed on the upper surface 5a and the side surface 7b₁ (7b₁₁, 7b₁₂, and 7b₁₃) of the second portion 7 of the semiconductor layer 5.

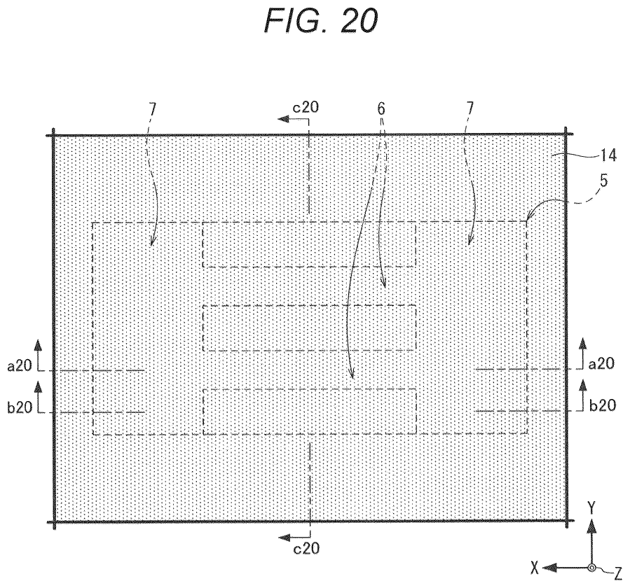

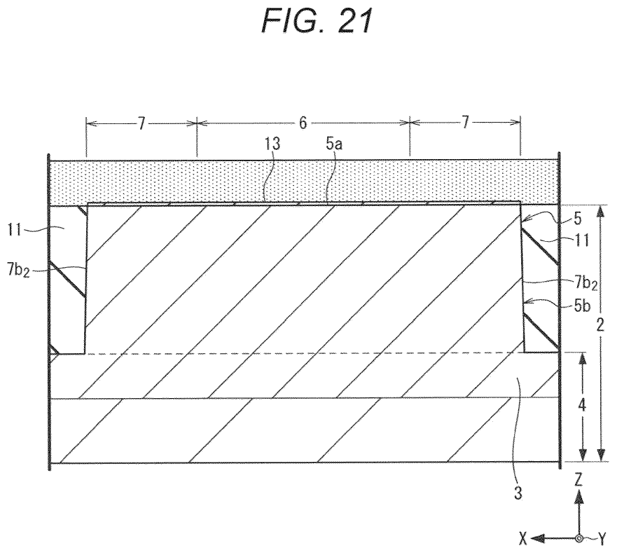

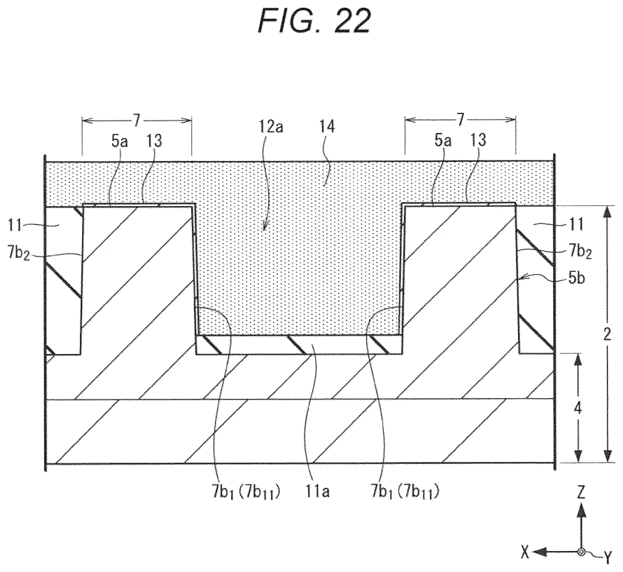

Next, as illustrated in FIG. 20 (schematic plan view of the main part), FIG. 21 (schematic cross-sectional view taken along line a20-a20 in FIG. 20), FIG. 22 (schematic cross-sectional view taken along line b20-b20 in FIG. 20), and FIG. 23 (schematic cross-sectional view taken along line c20-c20 in FIG. 20), a conductive film 14 is formed across the semiconductor layer 2 including the inside of each of the recessed portions 12a and 12b, the upper surface 5a of the semiconductor 5, and the insulating layer 11. As the conductive film 14, for example, a polycrystalline silicon (doped polysilicon) film doped with an impurity for reducing a resistance value during or after film formation can be used. At the portion where the gate insulating film 13 is formed on the semiconductor 5, the gate insulating film 13 is interposed between the semiconductor 5 and the conductive film 14.

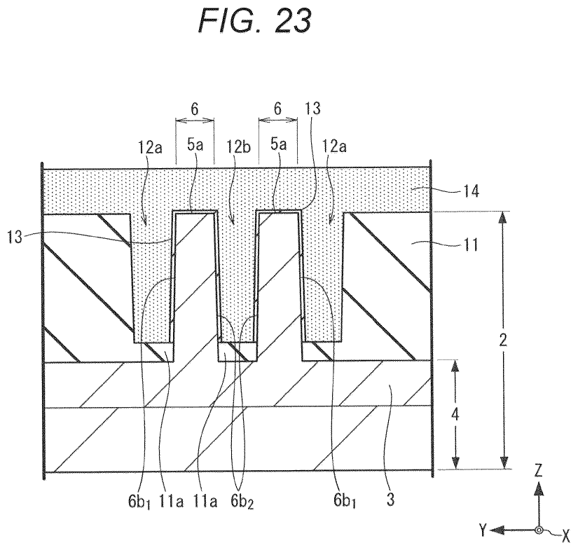

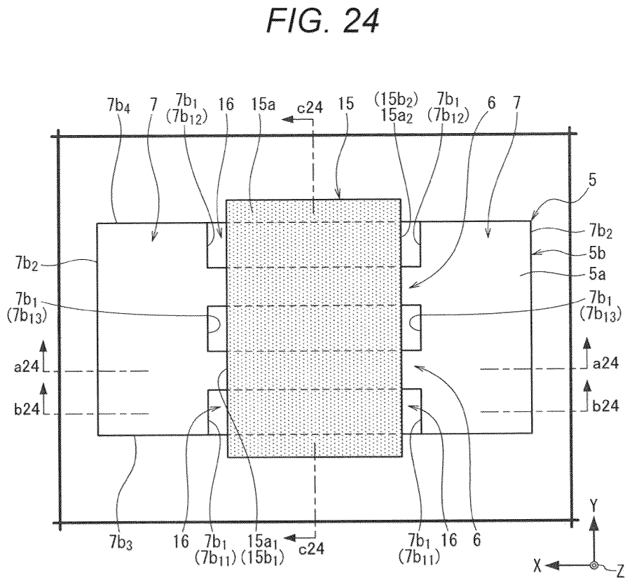

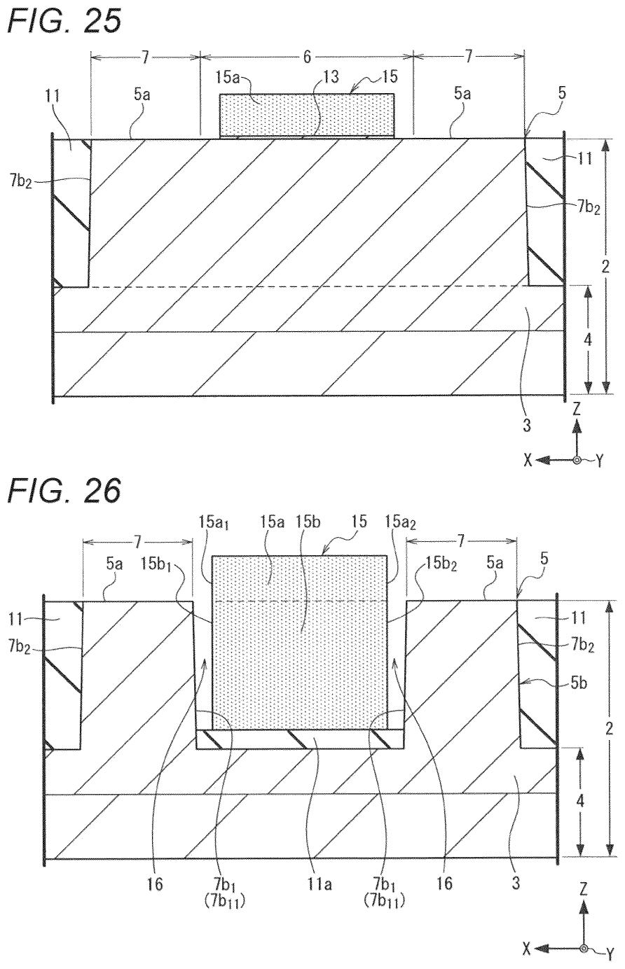

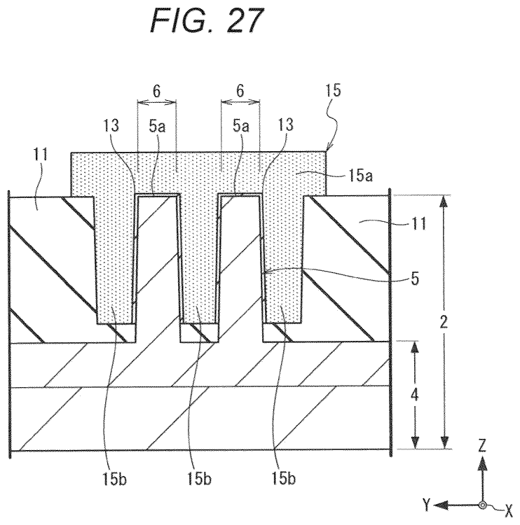

Next, the conductive film 14 is patterned using a known photolithography technique and dry etching technique, and as illustrated in FIG. 24 (schematic plan view of the main part), FIG. 25 (schematic cross-sectional view taken along line a24-a24 in FIG. 24), FIG. 26 (schematic cross-sectional view taken along line b24-b24 in FIG. 24), and FIG. 27 (schematic cross-sectional view taken along line c24-c24 in FIG. 24), the gate electrode 15 separated from each of the two second portions 7 of the semiconductor 5 and facing the upper surface 5a and the side surfaces 6b₁ and 6b₂ of each of the two first portions 6 with the gate insulating film 13 interposed therebetween is formed.

The gate electrode 15 includes the head 15a provided on the upper surface 5a of the first portion 6 of the semiconductor 5 with the gate insulating film 13 interposed therebetween, and the leg 15b integrated with the head 15 and provided outside each of the two side surfaces 6b₁ and 6b₂ located on the opposite sides of the first portion 6 of the semiconductor 5 with the gate insulating film 13 interposed therebetween.

The head 15a crosses the recessed portion 12a, the first portion 6, the recessed portion 12b, the first portion 6, and the recessed portion 12a in this order in the width direction (Y direction) of the first portion 6 of the semiconductor 5.

The leg 15b is formed in each of the three recessed portions 12a, 12b, and 12a, and has one end connected to the head 15a.

In this step, as illustrated in FIG. 26, the gate electrode 15 is formed to make two side surfaces 15a₁ and 15a₂ of the head 15a in the X direction (gate length direction) and two side surfaces 15b₁ and 5b₂ of the leg 15b in the X direction (gate length direction) flush with each other in cross-sectional view. In other words, one side surface 15a₁ of the head 15a and one side surface 15b₁ of the leg 15b form one flat surface continuously extending in the thickness direction (Z direction) of the semiconductor layer 2, and the other side surface 15a₂ of the head 15a and the other side surface 15b₂ of the leg 15b form one flat surface continuously extending in the thickness direction (Z direction) of the semiconductor layer 2.

Furthermore, in this step, as illustrated in FIGS. 24 and 26, a gap 16 is formed between the sidewall 7b₁ (7b₁₁, 7b₁₂, 7b₁₃) of the second portion 7 of the semiconductor 5 and leg 15b of gate electrode 15. In FIG. 26, the gap 16 between the sidewall 7b₁₁ of the second portion 7 and the side surfaces 15b₁ and 15b₂ of the leg 15b of the gate electrode 15 is illustrated as an example.

In the first embodiment, since the semiconductor 5 includes the two first portions 6 and the two second portions 7, the space 16 includes three spaces formed on each of both sides (sides adjacent to the two second portions 7) in the gate length direction of the gate electrode 15 in plan view.

Furthermore, in this step, the gate insulating film 13 on the upper surface 5a and the side surface 7b₁ of the second portion 7 is removed by side etching and over etching when the conductive film 14 is patterned.

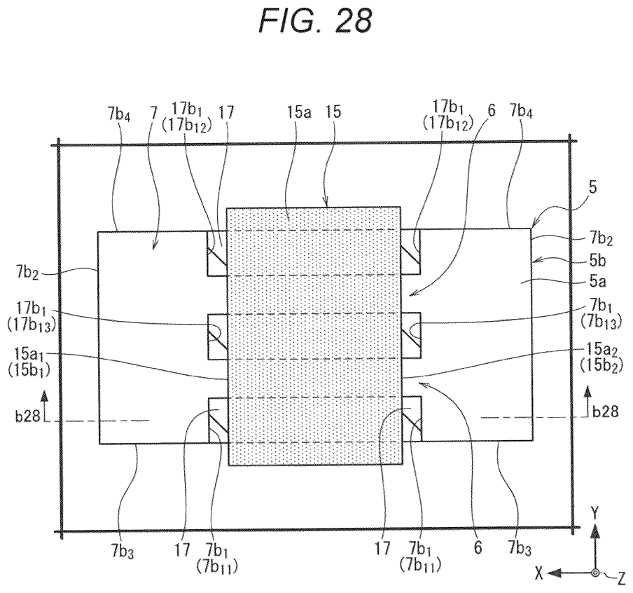

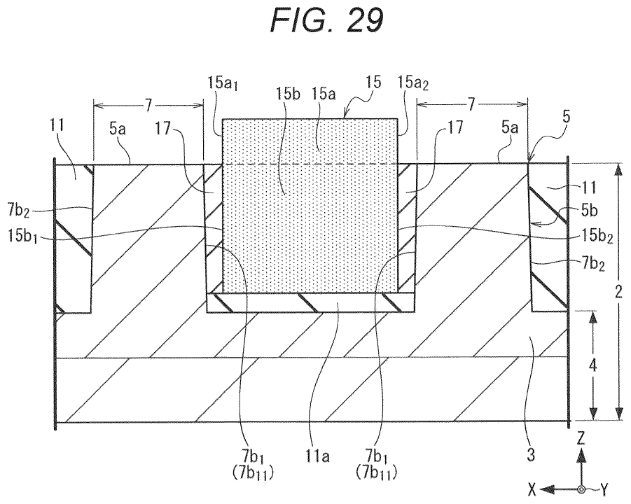

Next, as illustrated in FIG. 28 (schematic plan view of the main part) and FIG. 29 (schematic cross-sectional view taken along line b28-b28 in FIG. 28), the dielectric portion 17 lower in relative permittivity the insulating layer 11 is formed in each gap 16.

It is possible to form the dielectric portion 17 by, for example, but not limited to, forming an SiOC film lower in relative permittivity than a silicon oxide film across the semiconductor layer 2 including the inside of the gap 16, the semiconductor 5, and the insulating layer 11, and then selectively removing the SiOC film on the semiconductor 5 and the insulating layer 11.

Through this step, the dielectric portion 17 lower in relative permittivity than the insulating layer 11 can be selectively formed between the side surface 7b₁ (7b₁₁, 7b₁₂, and 7b₁₃) of the second portion 7 of the semiconductor 5 and the leg 15b of the gate electrode 15 in the X direction.

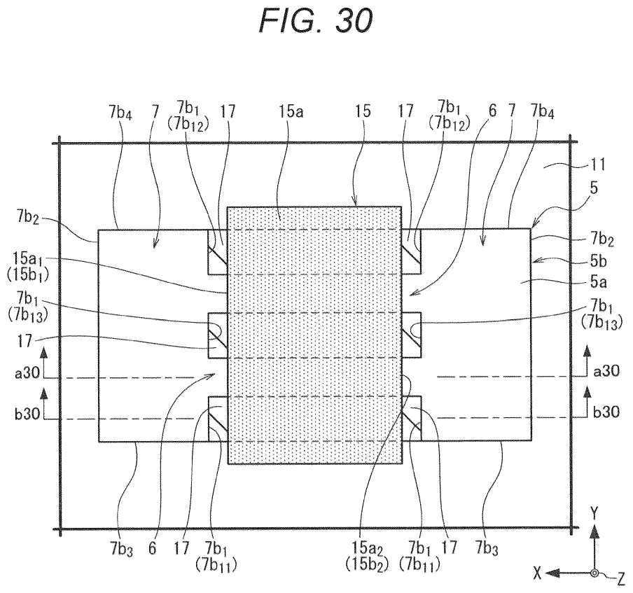

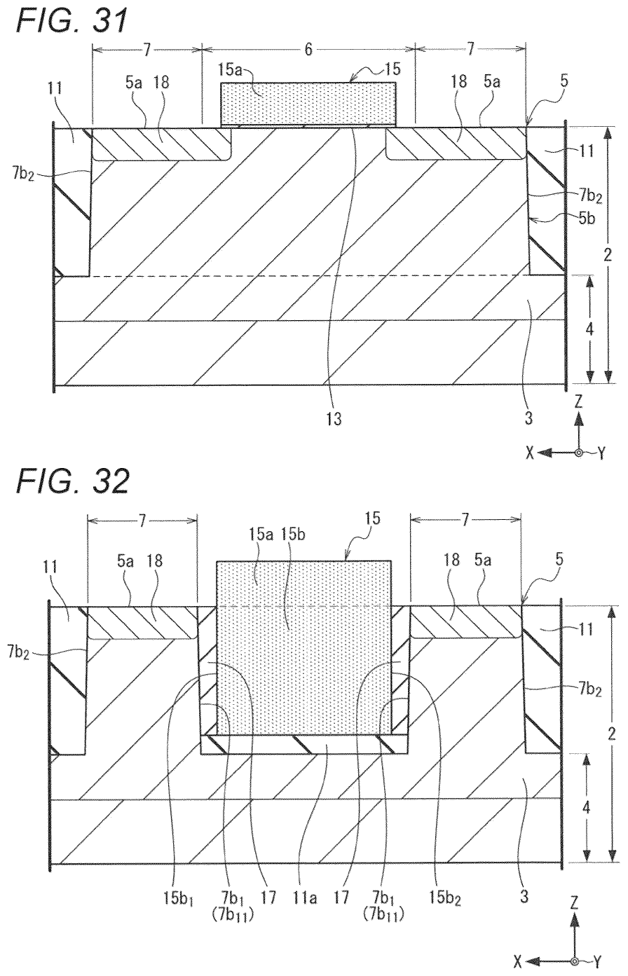

Next, as illustrated in FIG. 30 (schematic plan view of the main part), FIG. 31 (schematic cross-sectional view taken along line a30-a30 in FIG. 30), and FIG. 32 (schematic cross-sectional view taken along line b30-b30 in FIG. 30), a pair of n-type extension regions 18 each including an n-type semiconductor region are formed in each semiconductor 5 located on both sides of the gate electrode 15 in the X direction. It is possible to form the extension region 18 by, using the gate electrode 15, the dielectric portion 17, and the insulating layer 11 as a mask for impurity introduction, ion-implanting an n-type impurity such as arsenic ions (As⁺) or phosphorus ions (P⁺) into each semiconductor 5 located on both sides of the gate electrode 15 in the gate length direction (X direction), and then subjecting the semiconductor 5 to heat treatment for activating the impurity.

In this step, each of the pair of n-type extension regions 18 is formed in both the first portion 6 and the second portion 7 of the semiconductor 5 in alignment with the gate electrode 15.

Furthermore, in this step, the dielectric portion 17 functions as a protective layer and thus can suppress a phenomenon where impurity ions are implanted into the semiconductor 5 and the base 4 through between the second portion 7 of the semiconductor 5 and the leg 15b of the gate electrode 15.

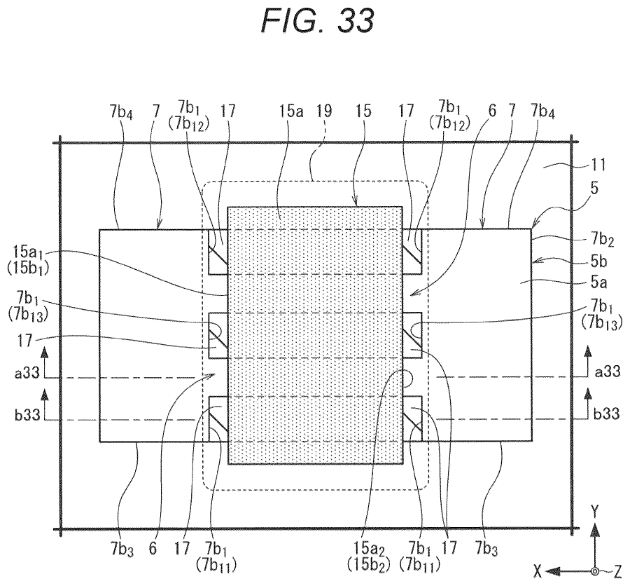

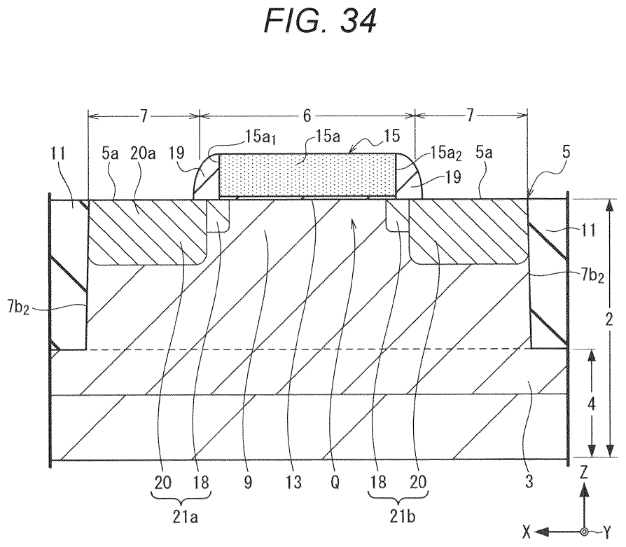

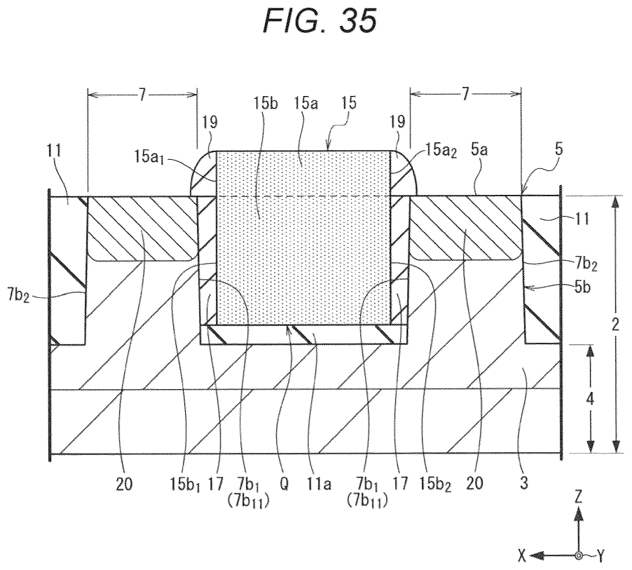

Next, as illustrated in FIG. 33 (schematic plan view of the main part), FIG. 34 (schematic cross-sectional view taken along line a33-a33 in FIG. 33), and FIG. 35 (schematic cross-sectional view taken along line b33-b33 in FIG. 33), the sidewall spacer 19 is formed on a sidewall including the side surfaces 15a₁ and 15a₂ of the head 15a of the gate electrode 15 protruding from the insulating layer 11. It is possible to form the sidewall spacer 19 by forming an insulating film across the insulating layer 11 by a CVD method so as to cover the semiconductor 5 and the head 15a of the gate electrode 15, and then subjecting the insulating film to anisotropic dry etching such as RIE. As the insulating film, for example, a silicon oxide film can be used.

The sidewall spacer 19 is formed on the sidewall of the head 15a of the gate electrode 15 so as to surround the head 15a of the gate electrode 15, and is formed in a self-aligned manner with respect to the gate electrode 15. The sidewall spacer 19 extends across the first portion 6 and the dielectric portion 17 located outside the gate electrode 15 in the gate length direction to cover the first portion 6 and the dielectric portion 17.

Next, as illustrated in FIG. 33 (schematic plan view of the main part), FIG. 34 (schematic cross-sectional view taken along line a33-a33 in FIG. 33), and FIG. 35 (schematic cross-sectional view taken along line b33-b33 in FIG. 33), a pair of n-type contact regions 20 each including an n-type semiconductor region are formed in each semiconductor 5 located on both end sides of the gate electrode 15 in the gate length direction (X direction). It is possible to form the pair of n-type contact regions 20 by, using the insulating layer 11, the gate electrode 15, and the sidewall spacer 19 as a mask for impurity introduction, ion-implanting an n-type impurity such as arsenic ions (As⁺) or phosphorus ions (P⁺) into the semiconductor 5 (second portion 7) between the insulating layer 11 and the sidewall spacer 19 in plan view, and then subjecting the semiconductor 5 (second portion 7) to heat treatment for activating the impurity. The pair of n-type contact regions 20 are formed across the second portion 7 and the first portion 6 in a self-aligned manner with respect to the sidewall spacer 19.

In this step, the n-type extension region 18 and the n-type contact region 20 are in contact with each other at the first portion 6.

Furthermore, in this step, the pair of main electrode regions 21a and 21b each including the n-type extension region 18 and the n-type contact region 20 are formed in the semiconductor 5.

Through this step, the field effect transistor Q illustrated in FIGS. 1 to 4 becomes almost completed.

Note that it is possible to form the n-type contact region 20 selectively in the second portion 6 (only the second portion 6) by controlling the width of the sidewall spacer 19 in the planar direction.

### Main Effects of First Embodiment

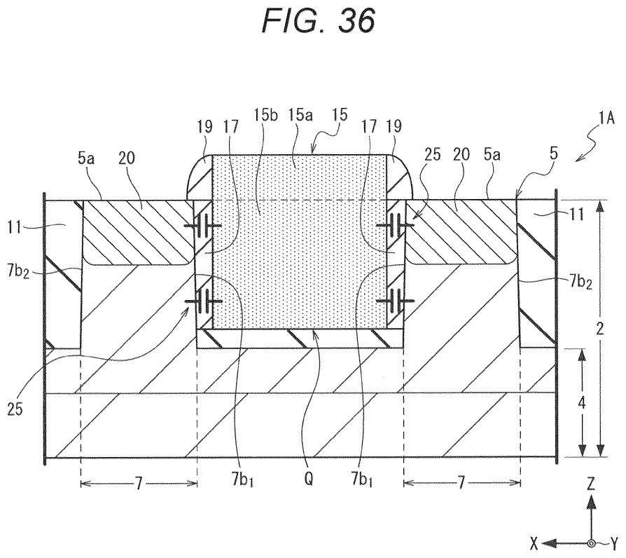

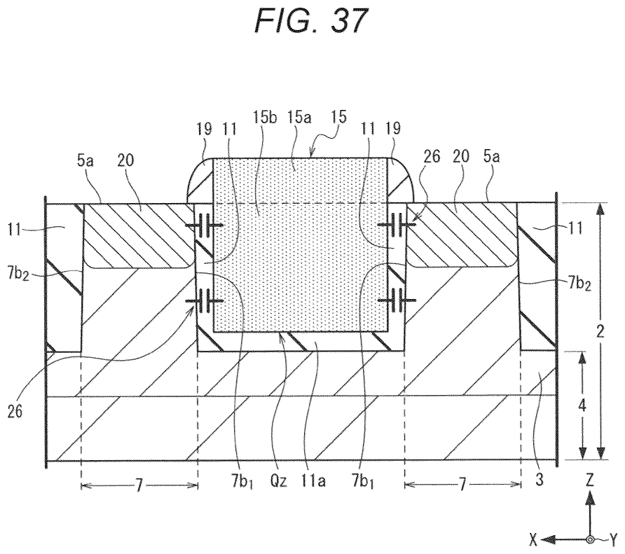

Next, main effects of the first embodiment will be described with reference to FIGS. 36 and 37.

FIG. 36 is a schematic longitudinal cross-sectional view of the field effect transistor Q of the first embodiment, illustrating parasitic capacitance added to the field effect transistor Q. FIG. 37 is a schematic longitudinal cross-sectional view of a field effect transistor Qz of a comparative example, illustrating parasitic capacitance added to the field effect transistor Qz.

As illustrated in FIG. 37, in a semiconductor device of the comparative example, the insulating layer 11 surrounding the semiconductor 5 is further provided between the second portion 7 of the semiconductor 5 and the leg 15b of the gate electrode 15. Therefore, a parasitic amount 26 with the second portion 7 as one electrode, the leg 15b of the gate electrode 15 as the second electrode, and the insulating layer 11 between the second portion 7 of the semiconductor 5 and the leg 15b of the gate electrode 15 as a dielectric is added to the field effect transistor Qz. Such parasitic capacitance 26 becomes a factor of degrading the noise characteristics of the field effect transistor Qz, and lowering the reliability of the semiconductor device.

On the other hand, as illustrated in FIG. 36, in the semiconductor device 1A of the first embodiment, the dielectric portion 17 is provided between the second portion 7 of the semiconductor 5 and the leg 15b of the gate electrode 15. Therefore, even in the first embodiment, a parasitic amount 25 with the second portion 7 as one electrode, the leg 15a of the gate electrode 15 as the second electrode, and the dielectric portion 17 between the second portion 7 and the leg 15b of the gate electrode 15 as a dielectric is added to the field effect transistor Q.

The dielectric portion 17, however, is lower in relative permittivity than the insulating layer 11. Therefore, the parasitic capacitance 25 added to the field effect transistor Q can be made smaller than the parasitic capacitance 26 added to the field effect transistor Qz of the comparative example.

Furthermore, the parasitic capacitance added to the field effect transistor Q includes not only the parasitic capacitance 25 but also other parasitic capacitance, but the parasitic capacitance 25 can be reduced, so that it is possible to suppress degradation of the noise characteristics of the field effect transistor Q and improve the reliability of the semiconductor device 1A.

Furthermore, in the step of forming the gate electrode 15 of the method for manufacturing the semiconductor device 1A according to the first embodiment, the gate electrode 15 including the head 15a and the leg 15b is formed by processing the conductive film 14 once, so that the two side surfaces 15a₁ and 15a₂ of the head 15a in the X direction (gate length direction) and the two side surfaces 15b₁ and 15b₂ of the leg 15b in the X direction (gate length direction) can be made flush with each other in cross-sectional view.

Furthermore, on the basis of a description using the reference signs in the first embodiment, in the conventional manufacturing process, the head 15a and the leg 15b of the gate electrode 15 are formed in separate processing steps. Accordingly, a step is formed between the head 15a and the leg 15b due to misalignment or dimensional variation of a mask, and moreover, variations occur in step height. Due to the variations in step height, parasitic capacitance Cgd between the gate electrode and the drain region also varies, and the noise characteristics of the field effect transistor degrade accordingly.

On the other hand, in the method for manufacturing the semiconductor device 1A of the first embodiment, the side surfaces 15a₁ and 15a₂ of the head 15a and the side surfaces 15b₁ and 5b₂ of the leg 15b can be made flush with each other in cross-sectional view, so that the parasitic capacitance Cgd between the gate electrode 15 and the drain region (for example, the main electrode region 21b) is not affected by process variations as in the related art. Therefore, according to the method for manufacturing the semiconductor device 1A of the first embodiment, it is possible to suppress degradation of the noise characteristics of the field effect transistor Q

Furthermore, according to the method for manufacturing the semiconductor device 1A of the first embodiment, the dielectric portion 17 lower in relative permittivity than the insulating layer 11 surrounding the semiconductor 5 can be formed between the second portion 7 of the semiconductor 5 and the leg 15b of the gate electrode 15, so that it is possible to further suppress degradation of the noise characteristics of the field effect transistor Q. It is therefore possible to further improve the reliability of the semiconductor device 1A.

### Modification of First Embodiment

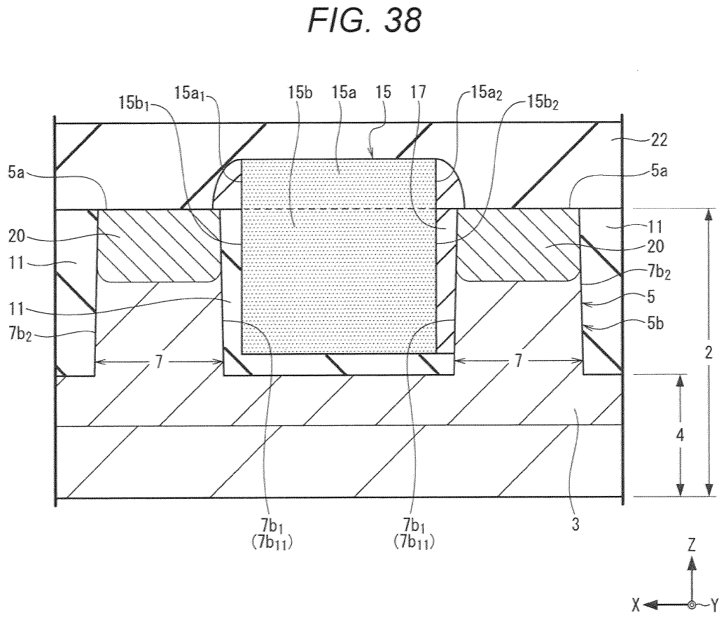

Note that, although a case where the dielectric portion 17 is provided on either side of the gate electrode 15 in the gate length direction has been described in the above-described first embodiment, as illustrated in FIG. 38, the dielectric portion 17 may be provided on any one side of the gate electrode 15 in the gate length direction (X direction). That is, the dielectric portion 17 may be provided on at least any one side the gate electrode 15 in the gate length direction. Note that, taking degradation of the noise characteristics of the field effect transistor Q into consideration, it is preferable that the dielectric portion 17 be provided on both sides of the gate electrode 15 in the gate length direction as in the first embodiment described above.

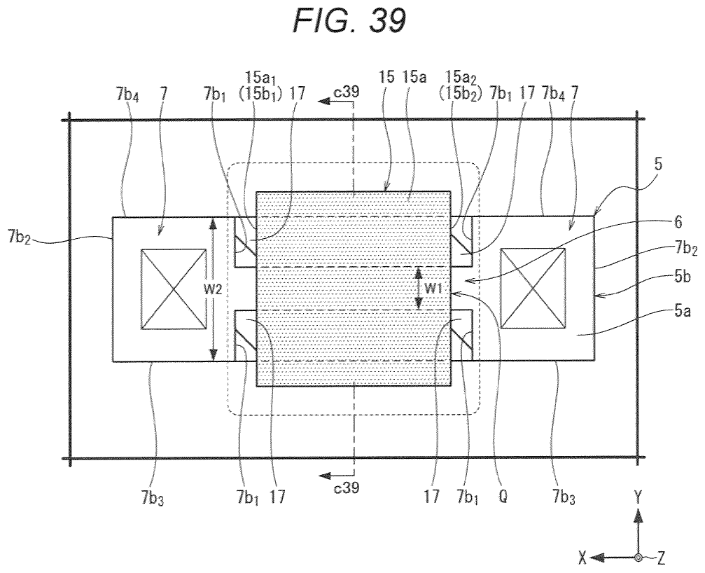

Furthermore, although the semiconductor 5 including the two first portions 6 provided side by side in the Y direction has been described in the above-described first embodiment, the present technology is also applicable to a semiconductor 5 including one first portion 6 as illustrated in FIG. 39. Even in this case, it is only required that the dielectric portion 17 be provided on at least any one side of the gate electrode 15 in the gate length direction. FIG. 39 illustrates, as an example, a configuration where the dielectric portion 17 is provided on both sides of the gate electrode 15 in the gate length direction.

Furthermore, the present technology is also applicable to a semiconductor 5 including three or more first portions 6 provided side by side in the Y direction.

Furthermore, although the semiconductor 5 including the second portion 7 provided on both sides of the first portion 6 in the X direction has been described in the above-described embodiment, the present technology is also applicable to a semiconductor 5 including the second portion 7 provided on at least any one side of the first portion 6 in the X direction.

Furthermore, although a case where the field effect transistor Q is of the n-channel conductivity type has been described in the above-described first embodiment, the present technology is also applicable to a case where the field effect transistor Q is of the p-channel conductivity type.

Furthermore, although a case where the field effect transistor Q is of the enhancement type has been described in the above-described first embodiment, the present technology is also applicable to a case where the field effect transistor Q is of the depression type.

Furthermore, although a case where one field effect transistor Q is provided in the first portion 6 of the semiconductor 5 has been described in the above-described first embodiment, the present technology is also applicable to a case where a plurality of field effect transistors Q is provided in the first portion 6.

### Second Embodiment

A semiconductor device 1B according to a second embodiment of the present technology has a configuration basically similar to the configuration of the semiconductor device 1A according to the above-described first embodiment, and the following configuration is different.

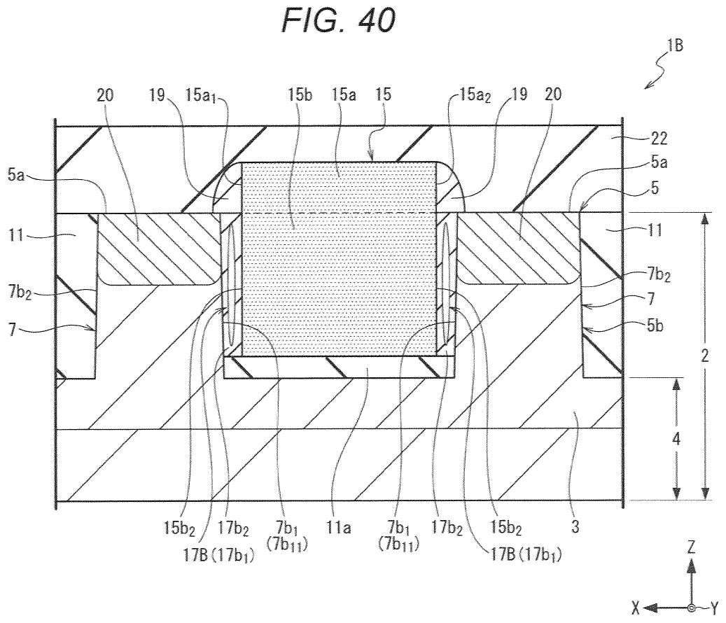

That is, as illustrated in FIG. 40, the semiconductor device 1B according to the second embodiment of the present technology includes a dielectric portion 17B instead of the dielectric portion 17 illustrated in FIG. 3 of the above-described first embodiment. The dielectric portion 17B includes a cavity 17b₁ that is lower in relative permittivity than the insulating layer 11. It is possible to form the cavity 17b₁ in a simple manner by forming an insulating film 17b₂ having low coverage in the gap 16 (see FIGS. 24 and 26) between the second portion 7 of the semiconductor 5 and the leg 15b of the gate electrode 15 in the manufacturing process of the semiconductor device 1B. The other configuration is substantially similar to the configuration of the above-described first embodiment.

The semiconductor device 1B according to the second embodiment can also produce effects similar to the effects produced by the semiconductor device 1A according to the above-described first embodiment.

Note that the insulating film 17b₂ extending from the upper surface 5a of the semiconductor 5 to the cavity 17b₁ and the insulating film 17b₂ extending from the cavity 17b₁ to the insulating layer 11a are preferably formed with a film thickness that prevents an ion-implanted impurity from penetrating through in the step of forming the extension region. In the second embodiment, in a manner similar to the above-described first embodiment, the insulating layer 11a remains, but in a case where the insulating layer 11a does not remain, the film thickness of the insulating film 17b₂ need to be controlled.

Furthermore, as the insulating film 17b₂, an insulating film lower in relative permittivity than the insulating layer 11 may be used.

### Third Embodiment

In the third embodiment, a case where two field effect transistors are provided in one semiconductor will be described.

A semiconductor device 1C according to a third embodiment of the present technology is basically similar in configuration to the semiconductor device 1A according to the above-described first embodiment, and the following configuration is different.

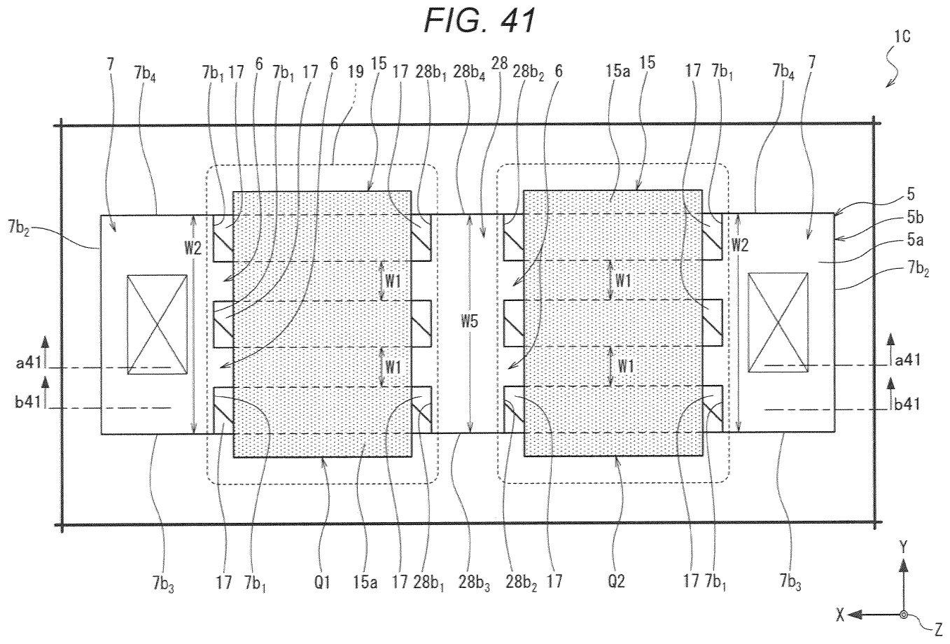

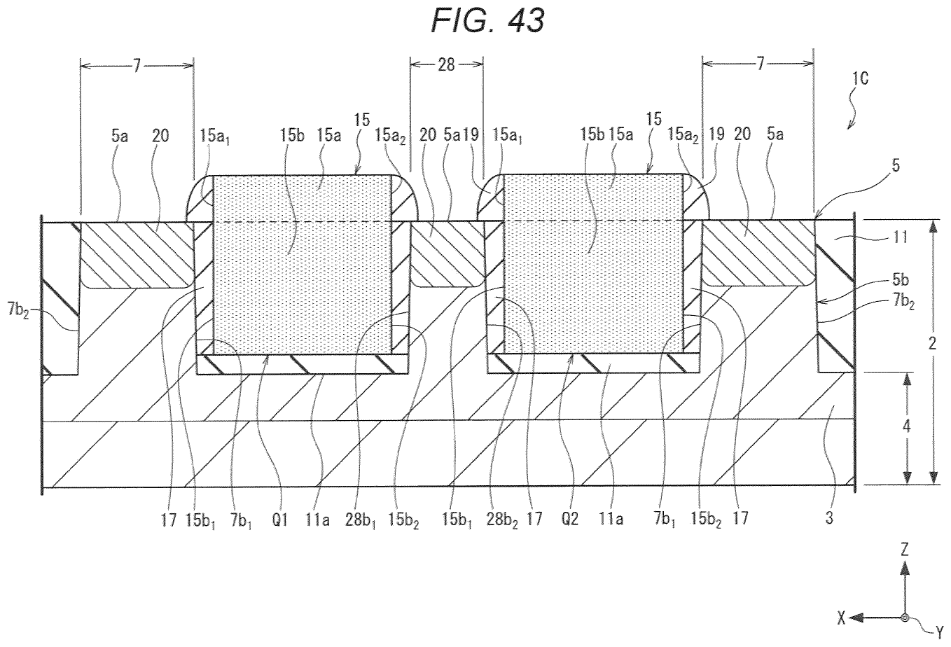

That is, as illustrated in FIGS. 41 to 43, the semiconductor device 1C according to the third embodiment of the present technology includes an island-shaped semiconductor 5 provided in a semiconductor layer 2, and two field effect transistors Q1 and Q2 provided in the semiconductor 5. Furthermore, the semiconductor device 1C according to the third embodiment includes an insulating layer 11 provided outside the semiconductor 5 so as to surround the semiconductor 5, in a manner similar to the above-described first embodiment. The semiconductor layer 2 includes a base 4 extending two-dimensionally in the X and Y directions, and the island-shaped semiconductor 5 protruding above the base 4 (in the Z direction).

The semiconductor 5 of the third embodiment has a three-dimensional structure that includes two first portions 6 provided side by side at a predetermined interval in the Y direction, two second portions 7 provided on both end sides of each of the two first portions 6 in the X direction, and a third portion 28 provided at an intermediate portion between the two first portions 6 in the X direction, and in which the first portion 6, the second portion 7, and the third portion 28 have an upper surface 5a and a side surface 5b. The semiconductor 5 of the third embodiment is basically similar in configuration to the semiconductor 5 of the above-described first embodiment, and is different in that the third portion 28 is included.

The third portion 28 is basically similar in configuration to the second portion 7. In a manner similar to the second portion 7, the third portion 28 has a width W5 in a direction identical to the width W1 of the first portion 6 wider than the width W1 of the first portion 6. The third portion 28 includes side surfaces 28b₁ and 28b₂ located on opposite sides in the X direction, and side surfaces 28b₃ and 28b₄ located on opposite sides in the Y direction. Then, each of the side surfaces 28b₁ and 28b₂ is divided into three portions by a connecting portion where the first portion 6 is connected to the third portion 28.

That is, the side surface 5b of the semiconductor 5 of the third embodiment includes the side surfaces 6b₁ and 6b₂ of each of the two first portions 6, the side surfaces 7b₁, 7b₂, 7b₃, and 7b₄ of each of the two second portions 7, and the side surfaces 28b₁, 28b₂, 28b₃, and 28b₄ of the third portion 28.

The field effect transistor Q1 is provided in the first portion 6 between one of the two second portions 7 and the third portion 28. The field effect transistor Q2 is provided in the first portion 6 between the other of the two second portions 7 and the third portion 28. Then, each of the field effect transistors Q1 and Q2 is similar in configuration to the field effect transistor Q of the above-described first embodiment.

The semiconductor device 1C of the third embodiment includes a dielectric portion 17 lower in relative permittivity than the insulating layer 11 surrounding the semiconductor 5 between one of the two second portions 7 of the semiconductor 5 and the leg 15b of the gate electrode 15 of the field effect transistor Q1, in a manner similar to the above-described first embodiment. Furthermore, the semiconductor device 1C of the third embodiment includes a dielectric portion 17 lower in relative permittivity than the insulating layer 11 surrounding the semiconductor 5 between the other of the two second portions 7 of the semiconductor 5 and the leg 15b of the gate electrode 15 of the field effect transistor Q2, in a manner similar to the above-described first embodiment. Then, the semiconductor device 1C of the third embodiment further includes a dielectric portion 17 lower in relative permittivity than the insulating layer 11 surrounding the semiconductor 5 between the third portion 28 of the semiconductor 5 and the leg 15b of the gate electrode 15 of the field effect transistor Q1 and between the third portion 28 of the semiconductor 5 and the leg 15b of the gate electrode 15 of the field effect transistor Q2.

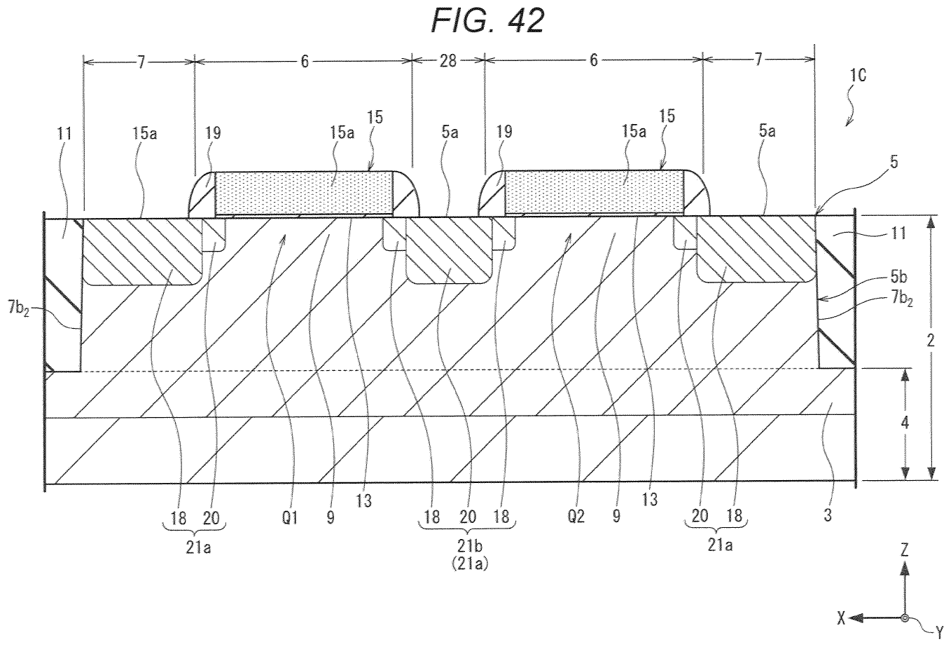

As illustrated in FIG. 42, the field effect transistors Q1 and Q2 share a main electrode region 21b that is the other of a pair of main electrode regions 21a and 21b of the field effect transistor Q1 and a main electrode region 21a that is one of a pair of main electrode regions 21a and 21b of the field effect transistor Q2.

The semiconductor device 1C according to the third embodiment can also produce effects similar to the effects produced by the semiconductor device 1A according to the above-described first embodiment.

### Modification of Third Embodiment

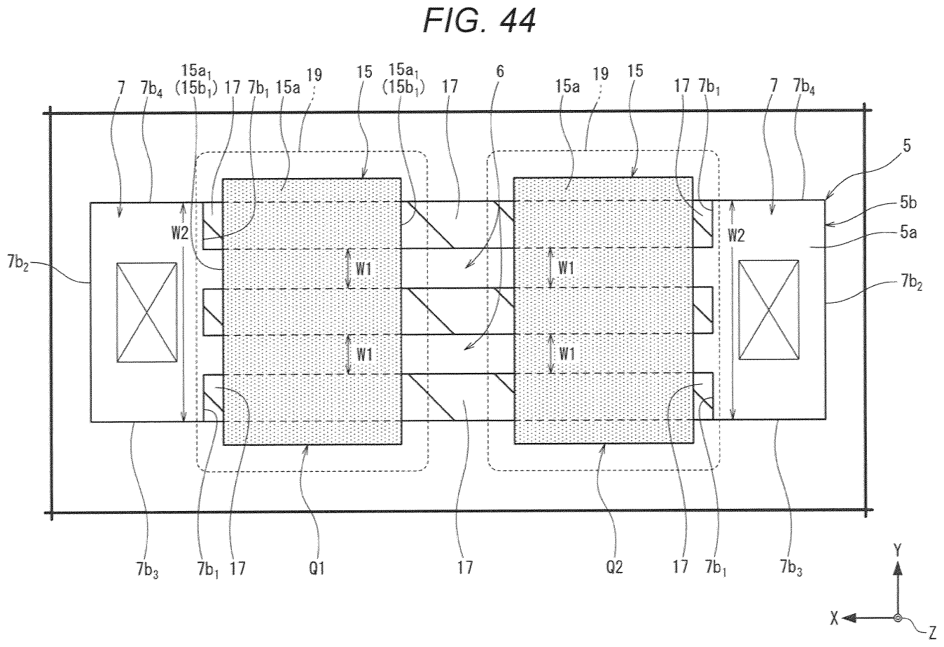

Note that, although a case where the two field effect transistors Q1 and Q2 are provided in the semiconductor 5 including the third portion 28 provided at the intermediate portion between the first portions 6 in the X direction has been described in the above-described third embodiment, as illustrated in FIG. 44, the present technology is also applicable to a case where the two field effect transistors Q1 and Q2 are provided in a semiconductor 5 including no third portion 28 illustrated in FIG. 41.

### Fourth Embodiment

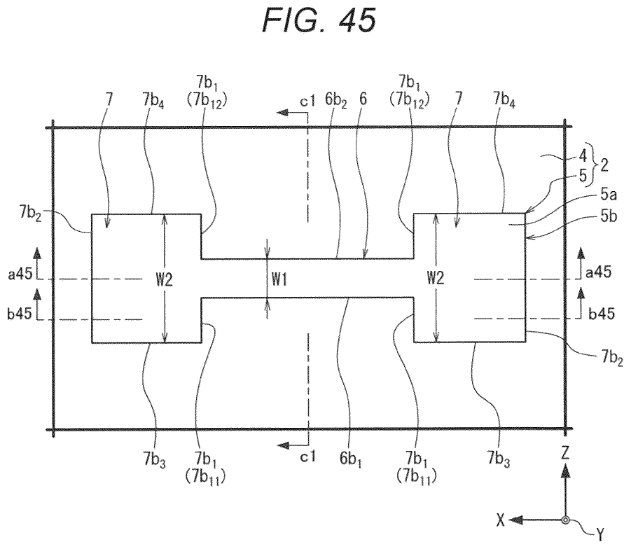

A method for manufacturing a semiconductor device according to a fourth embodiment of the present technology will be described with reference to FIGS. 45 to 69.

In the fourth embodiment, a description will be given focusing on the formation of the field effect transistor Q and the dielectric portion 17 included in the method for manufacturing the semiconductor device.

Furthermore, in the fourth embodiment, a case where the gate electrode 15 is formed by processing the conductive film 14 twice will be described.

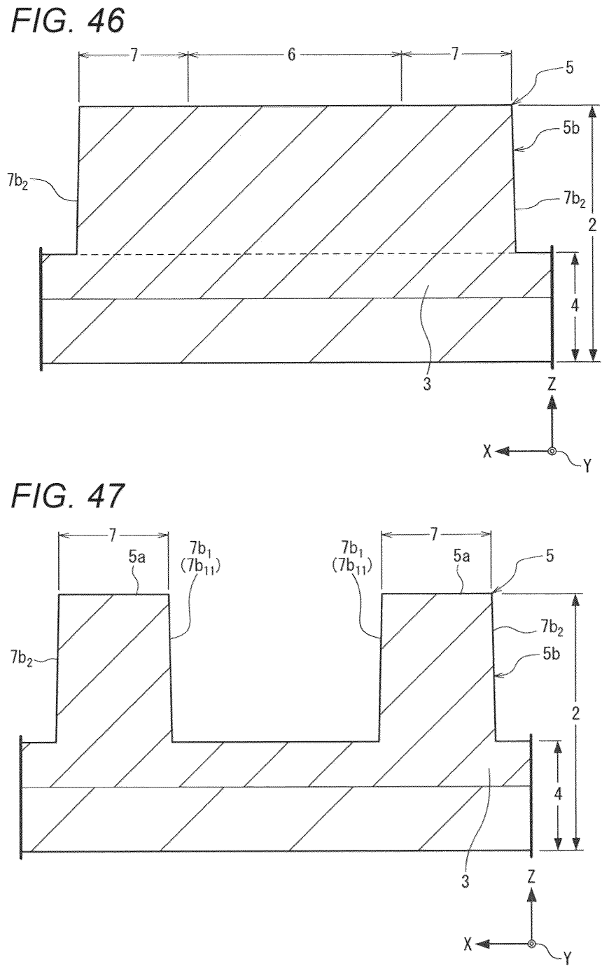

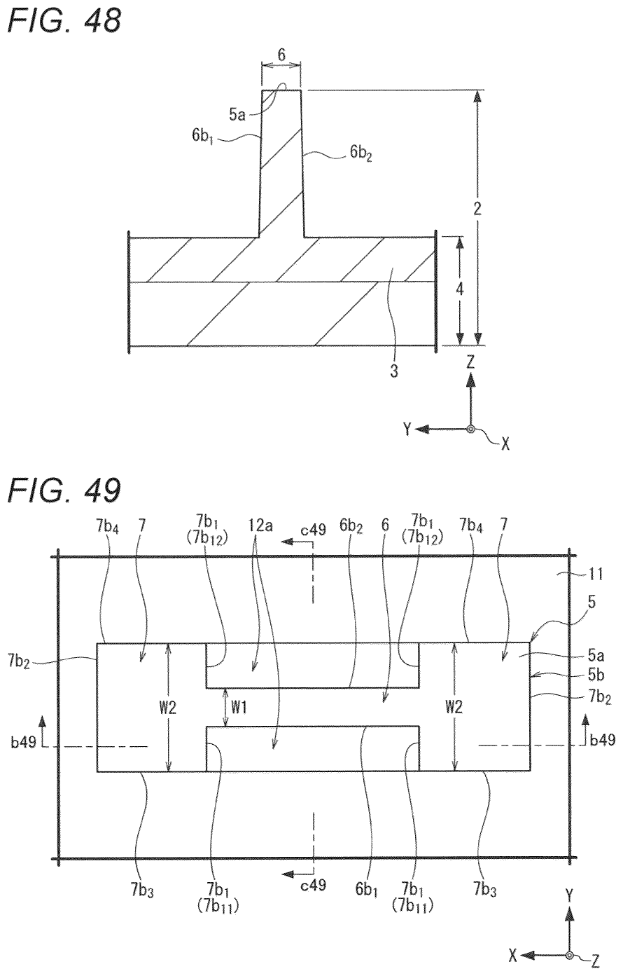

First, as illustrated in FIG. 45 (schematic plan view of the main part), FIG. 46 (schematic cross-sectional view taken along line a45-a45 in FIG. 45), FIG. 47 (schematic cross-sectional view taken along line b45-b45 in FIG. 45), and FIG. 48 (schematic cross-sectional view taken along line c45-c45 in FIG. 45), the island-shaped semiconductor 5 protruding above the base 4 is formed.

The semiconductor 5 is formed in a three-dimensional structure that includes the first portion 6 extending in the X direction (first direction), and the second portion 7 that is provided integrally alongside the first portion 6 in the X direction and has the width W2 in a direction identical to the width W1 of the first portion 6 along the Y direction (second direction) intersecting the X direction larger than the width W1 of the first portion 6, and in which the first portion 6 and the second portion 7 have the upper surface 5a and the side surface 5b. The side surface 5b includes the side surfaces 6b₁ and 6b₂ of the first portion 6 and the side surfaces 7b₁, 7b₂, 7b₃, and 7b₄ of the second portion 7. In the fourth embodiment, the semiconductor 5 is formed in a three-dimensional structure including one first portion 6 and two second portions 7 provided on both end sides of the one first portion 6 in the X direction.

It is possible to form the semiconductor 5 including the first portion 6 and the second portion 7 by selectively etching the semiconductor layer 2 to such a depth that the base 4 remains. The semiconductor layer 2 can be, but not limited to, a semiconductor substrate that includes, for example, silicon (Si) as a semiconductor material, is, for example, monocrystalline as crystallinity, and is, for example, of a p-conductive type as a conductivity type. Note that, in the semiconductor layer 2, the p-type well region 3, which is a p-type semiconductor region, is formed before the semiconductor 5 is formed.

Next, the insulating layer 11 surrounding the semiconductor 5 is formed by a method similar to the method of the above-described first embodiment.

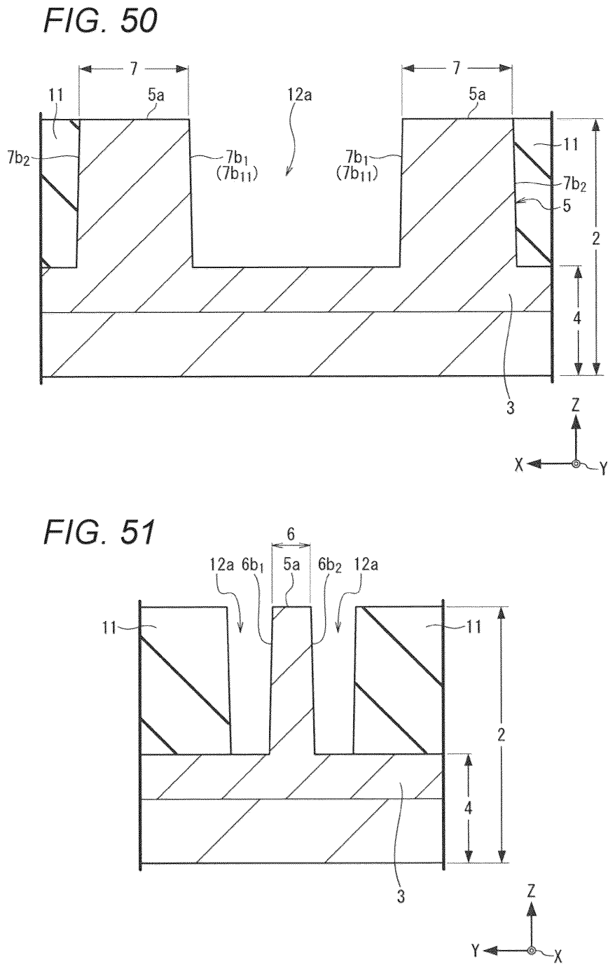

Then, after the insulating layer 11 is formed, the insulating layer 11 located outside the second portion 6 of the semiconductor 5 in the width direction (Y direction) is selectively removed to form the recessed portions 12a and 12a that expose the sidewalls 6b₁ and 6b₂ of the first portion 6 and the sidewall 7b₁ of the second portion 7 outside the first portion 6 of the semiconductor 5 in the width direction (Y direction) as illustrated in FIG. 49 (schematic plan view of the main part), FIG. 50 (schematic cross-sectional view taken along line b49-b49 in FIG. 49), and FIG. 51 (schematic cross-sectional view taken along line c49-c49 in FIG. 49).

The recessed portion 12a that is one of the two recessed portions 12a and 12a is formed on the side surface 6b₁ side of the first portion 6 to expose the side surface 6b₁ of the first portion 6 and the side surface 7b₁ (7b₁₁) of each of the two second portions 7.

Furthermore, the recessed portion 12a that is the other of the two recessed portions 12a and 12a is formed on the side surface 6b₂ side of the first portion 6 to expose the side surface 6b₂ of the first portion 6 and the side surface 7b₁ (7b₁₂) of each of the two second portions 7.

In this step, the recessed portions 12a and 12a are formed to, but not limited to, a depth that reaches the base 4 of the semiconductor layer 2, for example, unlike the above-described first embodiment.

Next, the gate insulating film 13 is formed on the upper surface 5a and the side surfaces 6b₁ and 6b₂ of the first portion 6 of the semiconductor 5. It is possible to form the gate insulating film 13 by forming a silicon oxide film on the upper surface 5a and the side surfaces 6b₁ and 6b₂ of the first portion 6 by, for example, a thermal oxidation method or a deposition method.

In this step, the gate insulating film 13 is further formed on the upper surface 5a and the side surface 7b₁ (7b₁₁ and 7b₁₂) of the second portion 7 of the semiconductor layer 5 and on a front surface of the base 4 of the semiconductor layer 2.

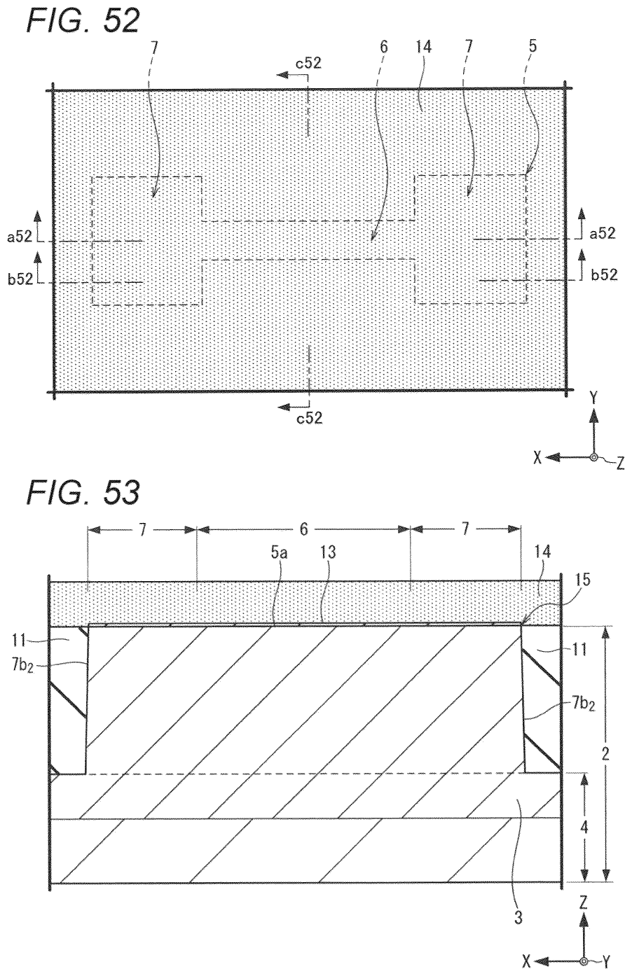

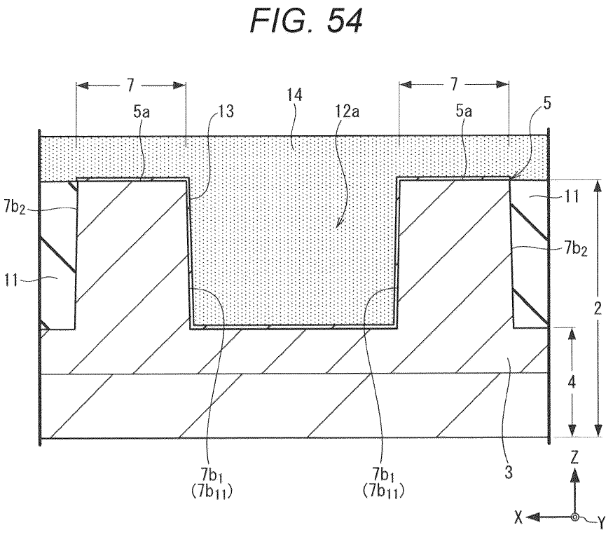

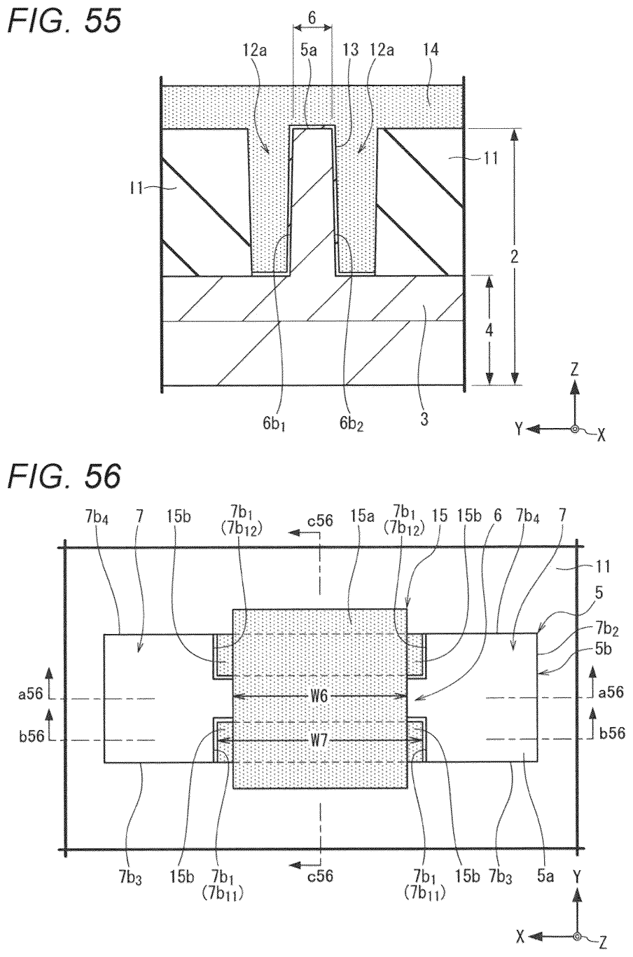

Next, after the gate insulating film 13 is formed, as illustrated in FIG. 52 (schematic plan view of the main part), FIG. 53 (schematic cross-sectional view taken along line a52-a52 in FIG. 52), FIG. 54 (schematic cross-sectional view taken along line b52-b52 in FIG. 52), and FIG. 55 (schematic cross-sectional view taken along line c52-c52 in FIG. 52), the conductive film 14 (gate electrode material) covering the semiconductor layer 2 and the insulating layer 11 is formed to fill the inside of each of the two recessed portions 12a. As the conductive film 14, for example, a polycrystalline silicon (doped polysilicon) film doped with an impurity for reducing a resistance value during or after film formation can be used. At the portion where the gate insulating film 13 is formed on the semiconductor 5, the gate insulating film 13 is interposed between the semiconductor 5 and the conductive film 14.

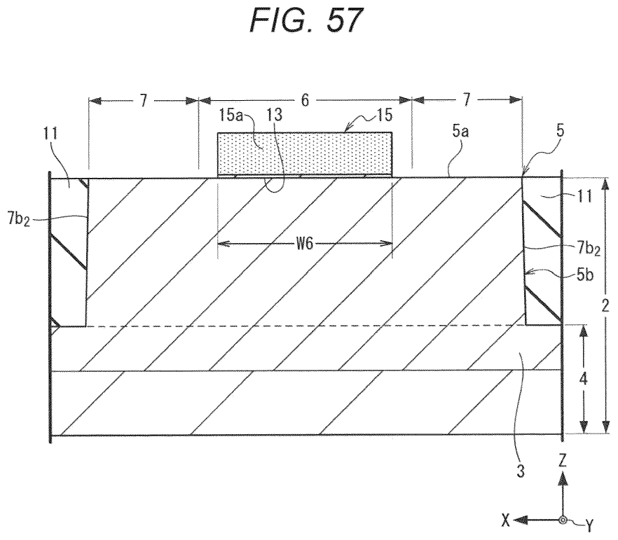

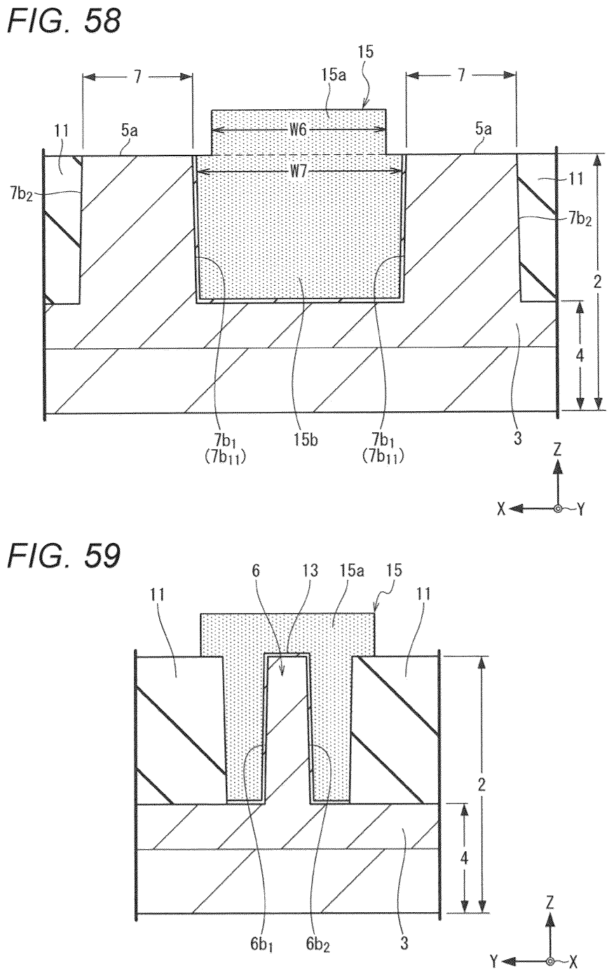

Next, the conductive film 14 is patterned using a known photolithography technique and dry etching technique, and as illustrated in FIG. 56 (schematic plan view of the main part), FIG. 57 (schematic cross-sectional view taken along line a56-a56 in FIG. 56), FIG. 58 (schematic cross-sectional view taken along line b56-b56 in FIG. 56), and FIG. 59 (schematic cross-sectional view taken along line c56-c56 in FIG. 56), a gate electrode 15 including a leg 7 embedded in each of the two recessed portions 12a adjacent to the first portion 6, and a head 15 that is integrated with the leg 15b, overlaps the first portion 6, and has a width W6 in a direction identical to a width W7 of the leg 15b along the first direction (X direction) smaller than the width W7 of the leg 15b is formed.

In this step, the head 15a of the gate electrode 15 is provided on the upper surface of the first portion 6 of the semiconductor 5 with the gate insulating film 13 interposed therebetween, and crosses the first portion 6 in the Y direction. The leg 15b of the gate electrode 15 is formed in each of the two recessed portions 12a, and has one end connected to the head 15a. Then, one of the two legs 15b is provided outside the side surface 6b₁ of the first portion 6 of the semiconductor 5 with the gate insulating film 13 interposed therebetween. Then, the other of the two legs 15b is provided outside the side surface 6b₂ of the first portion 6 of the semiconductor 5 with the gate insulating film 13 interposed therebetween.

Furthermore, in this step, the gate insulating film 13 on the upper surface 5a of the semiconductor 5 located outside the head 15a in the X direction is removed by side etching and over etching when the conductive film 14 is patterned.

Note that, in this embodiment, the conductive film 14 is subject to, but not limited to, a process to make the leg 15b located outside the head 15a almost flush with the upper surface 5a of the semiconductor 5.

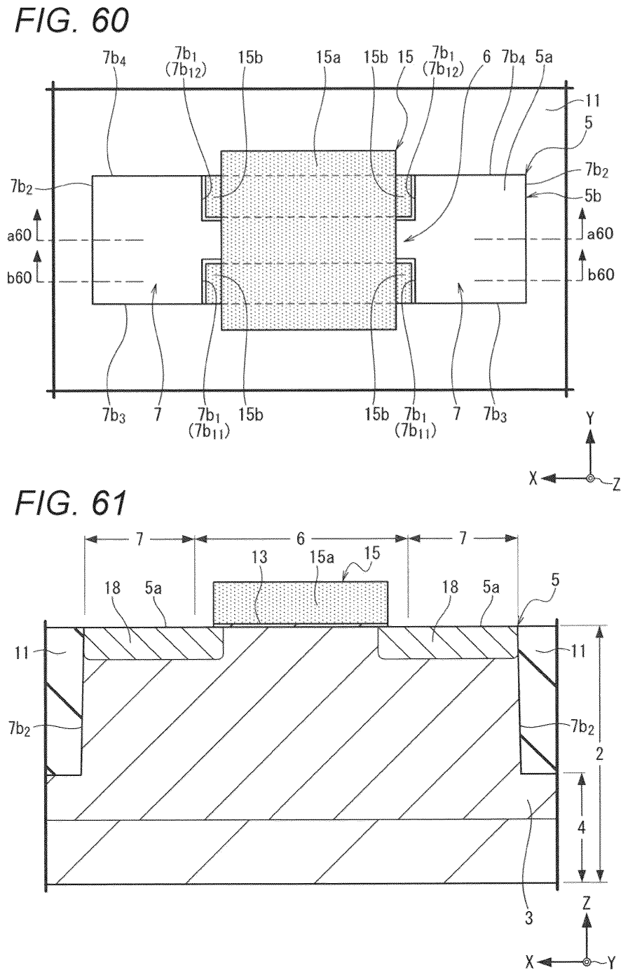

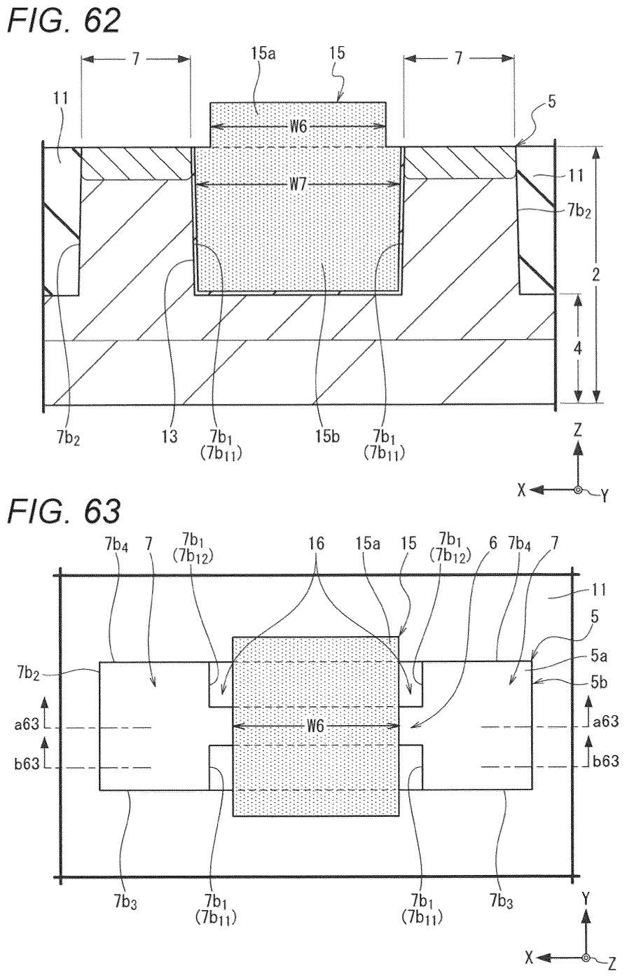

Next, as illustrated in FIG. 60 (schematic plan view of the main part), FIG. 61 (schematic cross-sectional view taken along line a60-a60 in FIG. 60), and FIG. 62 (schematic cross-sectional view taken along line b60-b60 in FIG. 60), a pair of n-type extension regions 18 each including an n-type semiconductor region are formed in each semiconductor 5 located on both sides of the gate electrode 15 in the gate length direction (X direction). It is possible to form the extension region 18 by, using the head 15a of the gate electrode 15, the leg 5b located outside the head 15a, and the insulating layer 11 as a mask for impurity introduction, ion-implanting an n-type impurity such as arsenic ions (As⁺) or phosphorus ions (P⁺) into the semiconductor 5 located on both sides of the gate electrode 15 in the gate length direction (X direction), and then subjecting the semiconductor 5 to heat treatment for activating the impurity.

In this step, each of the pair of n-type extension regions 18 is formed in both the first portion 6 and the second portion 7 of the semiconductor 5 in alignment with the head 15a of the gate electrode 15.

Furthermore, in this step, the leg 15b located outside the head 15a functions as a protective layer (impurity introduction suppression layer) and thus can suppress a phenomenon where impurity ions are implanted into the semiconductor 5 and the base 4 through between the second portion 7 of the semiconductor 5 and the leg 15b of the gate electrode 15.

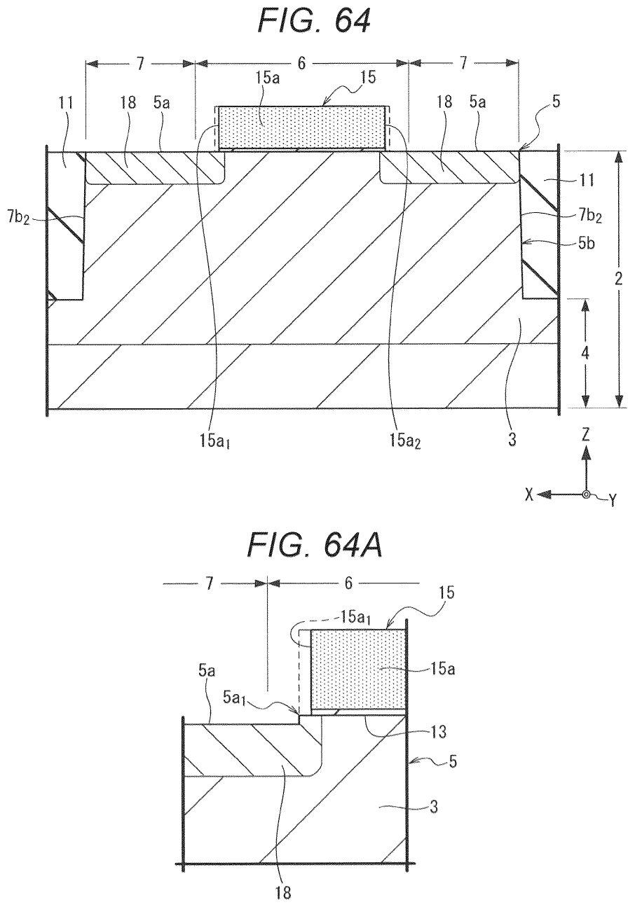

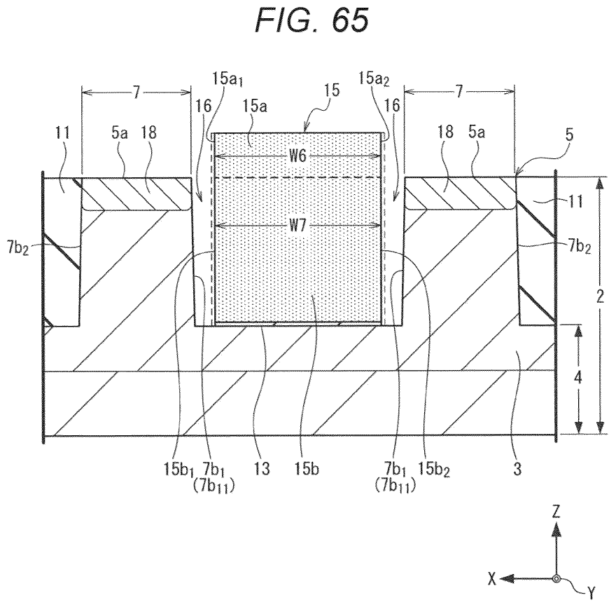

Next, as illustrated in FIG. 63 (schematic plan view of the main part), FIG. 64 (schematic cross-sectional view taken along line a63-a63 in FIG. 63), and FIG. 65 (schematic cross-sectional view taken along line a63-a63 in FIG. 63), the leg 15b located outside the head 15a is selectively removed.

The leg 15b located outside the head 15a is removed using a known photolithography technique and dry etching technique.

Furthermore, the removal of the leg 15b located outside the head 15a is performed by collectively etching the head 15a and the leg 15b in the height direction of the semiconductor 5 so as to recess the side surfaces 15a₁ and 15a₂ on both sides of the head 15a in the X direction inward.

Furthermore, this etching is performed to a depth near the bottom of the recessed portion 12a. That is, the etching is performed to such a depth that the leg 15b located outside the head 15a is completely removed, in other words, to such a depth that the leg 15b located outside the leg 15b does not remain.

In this step, a gap 16 is formed between the sidewall 7b₁ (7b₁₁ and 7b₁₂) of the second portion 7 of the semiconductor 5 and the leg 15b of the gate electrode 15.

Furthermore, in this step, the two side surfaces 15a₁ and 15a₂ of the head 15a in the X direction (gate length direction) and the two side surfaces 15b₁ and 5b₂ of the leg 15b in the X direction (gate length direction) are formed to be flush with each other in cross-sectional view. In other words, one side surface 15a₁ of the head 15a and one side surface 15b₁ of the leg 15b form one flat surface continuously extending in the thickness direction (Z direction) of the semiconductor layer 2, and the other side surface 15a₂ of the head 15a and the other side surface 15b₂ of the leg 15b form one flat surface continuously extending in the thickness direction (Z direction) of the semiconductor layer 2. In other words, the width W6 of the head 15a in the X direction and the width W7 of the leg 16b in the X direction have the same design value.

Furthermore, in this step, as illustrated in FIG. 64A, a step portion 5a₁ is formed on the upper surface 5a of the first portion 6 of the semiconductor 5 due to the inward recess of the side surfaces 15a₁ and 15a₂ on both sides of the head 15a in the X direction.

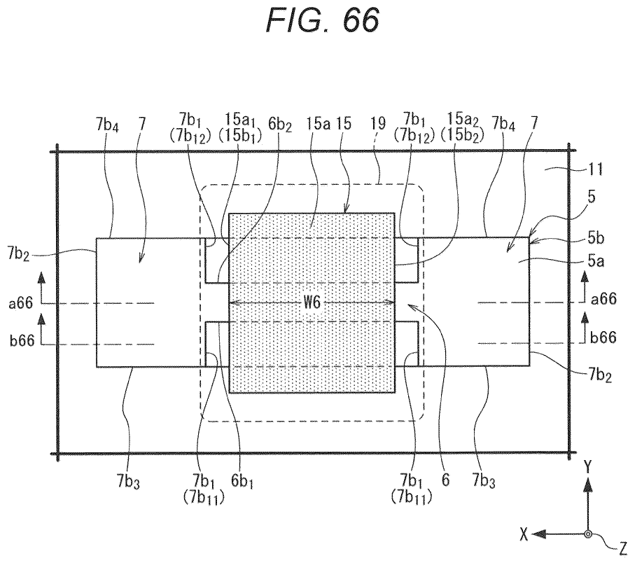

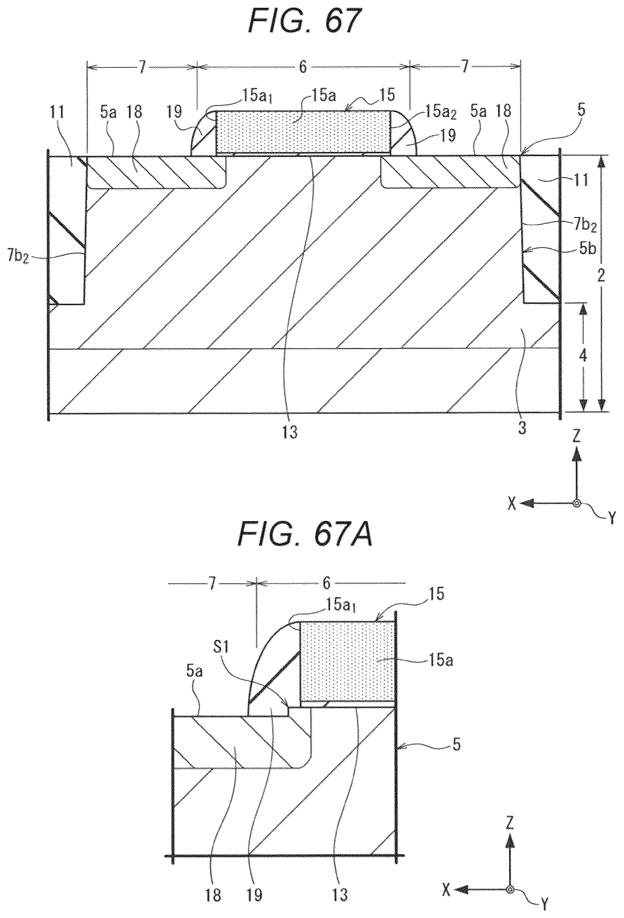

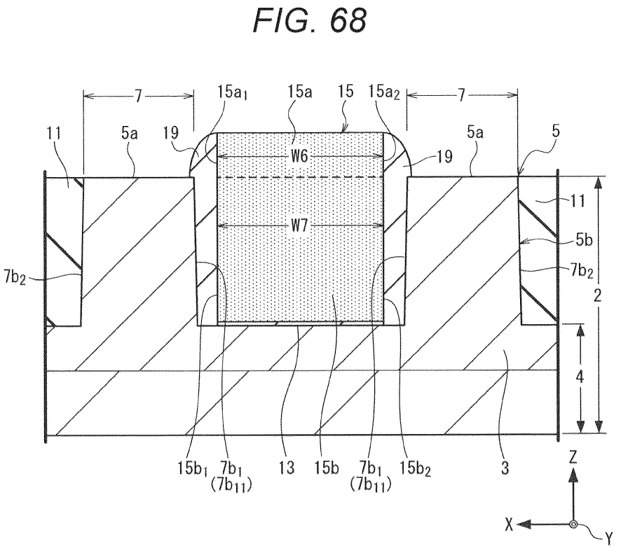

Next, as illustrated in FIG. 66 (schematic plan view of the main part), FIG. 67 (schematic cross-sectional view taken along line b66-b66 in FIG. 66), and FIG. 68 (schematic cross-sectional view taken along line b66-b66 in FIG. 66), a sidewall spacer 19 is formed on a sidewall of the gate electrode 15 so as to cover the side surfaces 15a₁ and 15a₂ of the head 15a and the side surfaces 15b₁ and 15b₂ of the leg 15b. It is possible to form the sidewall spacer 19 by forming an insulating film across the insulating layer 11 by a CVD method so as to fill the gap 16 illustrated in FIG. 65 and cover the semiconductor 5 and the head 15a of the gate electrode 15, and then subjecting the insulating film to anisotropic dry etching such as RIE. As the insulating film, for example, a silicon oxide film can be used.

The sidewall spacer 19 is formed on the sidewall of the head 15a of the gate electrode 15 so as to surround the head 15a of the gate electrode 15, and is formed in a self-aligned manner with respect to the gate electrode 15. The sidewall spacer 19 crosses, in the Y direction, the first portion 6 located outside the gate electrode 15 in the gate length direction.

In this step, as illustrated in FIG. 67A, the step portion 5a₁ of the first portion 6 of the semiconductor 5 is covered with the sidewall spacer 19. That is, the step portion 5a₁ is arranged at a position overlapping the sidewall spacer 19 in plan view.

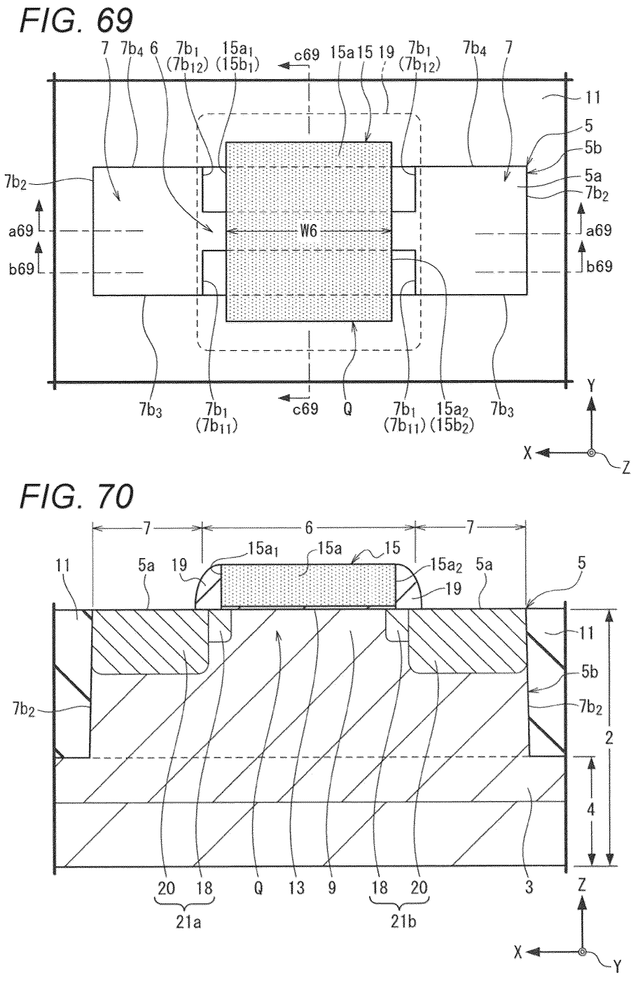

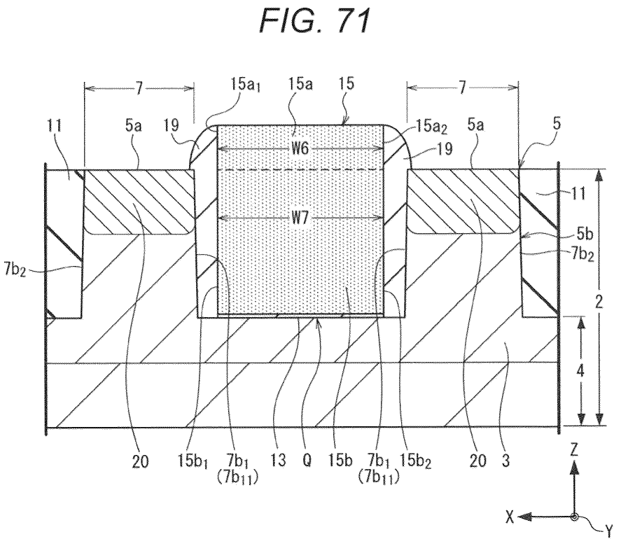

Next, as illustrated in FIG. 69 (schematic plan view of the main part), FIG. 70 (schematic cross-sectional view taken along line a69-a69 in FIG. 69), and FIG. 71 (schematic cross-sectional view taken along line b69-b69 in FIG. 69), a pair of n-type contact regions 20 each including an n-type semiconductor region are formed in each semiconductor 5 located on both end sides of the gate electrode 15 in the gate length direction (X direction). It is possible to form the pair of n-type contact regions 20 by, using the insulating layer 11, the gate electrode 15, and the sidewall spacer 19 as a mask for impurity introduction, ion-implanting an n-type impurity such as arsenic ions (As⁺) or phosphorus ions (P⁺) into the semiconductor 5 (second portion 7) between the insulating layer 11 and the sidewall spacer 19 in plan view, and then subjecting the semiconductor 5 (second portion 7) to heat treatment for activating the impurity. The pair of n-type contact regions 20 are formed across the second portion 7 and the first portion 6 in a self-aligned manner with respect to the sidewall spacer 19.

In this step, the n-type extension region 18 and the n-type contact region 20 are in contact with each other at the first portion 6.

Furthermore, in this step, the pair of main electrode regions 21a and 21b each including the n-type extension region 18 and the n-type contact region 20 are formed in the semiconductor 5.

Through this step, the field effect transistor Q including the channel formation portion 9 provided in the first portion 5a of the semiconductor 5, the gate electrode 15 provided across the upper surface 5a and the side surfaces 6b₁ and 6b₂ of the first portion 6 of the semiconductor 5 with the gate insulating film 13 interposed therebetween, the sidewall spacer 19 provided on the sidewall of the gate electrode 15 across the head 15a and the leg 15b, and the pair of main electrode regions 21a and 21b each provided in the semiconductor 5 located on both sides of the gate electrode 15 in the channel length direction (X direction) becomes almost completed.

Note that it is possible to form the n-type contact region 20 of each of the pair of main electrode regions 21a and 21b selectively in the second portion 6 (only the second portion 6) by controlling the width of the sidewall spacer 19 in the planar direction.

### Main Effects of Fourth Embodiment

In the method for manufacturing the semiconductor device according to the fourth embodiment, an impurity is selectively ion-implanted into the semiconductor 5 located outside the head 15a with the leg 15b remaining between the head 15a of the gate electrode 15 and the second portion 6 of the semiconductor 5 in plan view to form the extension region 18. Accordingly, the leg 15b located outside the head 15a functions as a protective layer (impurity introduction suppression layer) and thus can suppress a phenomenon where impurity ions are implanted into the semiconductor 5 and the base 4 through between the second portion 7 of the semiconductor 5 and the leg 15b of the gate electrode 15.

Furthermore, since it is possible to suppress the phenomenon where impurity ions are implanted into the semiconductor 5 or the base 4 through between the second portion 7 of the semiconductor 5 and the leg 15b of the gate electrode 15, it is possible to suppress a white spot phenomenon caused by the implantation of impurity ions. It is therefore possible to manufacture a semiconductor device with further improved reliability.

Furthermore, in the method for manufacturing the semiconductor device according to the fourth embodiment, the removal of the leg 15b located outside the head 15a in plan view is performed by collectively etching the head 15a and the leg 15b in the height direction of the semiconductor 5 (thickness direction of the semiconductor layer 2) so as to recess the side surfaces 15a₁ and 15a₂ of the head 15a in the gate length direction (X direction) inward.

Therefore, the two side surfaces 15a₁ and 15a₂ of the head 15a in the X direction (gate length direction) and the two side surfaces 15b₁ and 5b₂ of the leg 15b in the X direction (gate length direction) can be formed to be flush with each other in cross-sectional view.

Furthermore, the side surfaces 15a₁ and 15a₂ of the head 15a and the side surfaces 15b₁ and 5b₂ of the leg 15b can be made flush with each other in cross-sectional view, so that the parasitic capacitance Cgd between the gate electrode 15 and the drain region (for example, the main electrode region 21b) is not affected by process variations as in the related art, in a manner similar to the above-described manufacturing method of the first embodiment. Therefore, according to the method for manufacturing the semiconductor device of the fourth embodiment, it is also possible to suppress degradation of the noise characteristics of the field effect transistor Q.

Furthermore, according to the method for manufacturing the semiconductor device according to the fourth embodiment, the step portion 5a₁ formed on the upper surface 5a of the first portion 6 of the semiconductor 5 due to the inward recess of the side surfaces 15a₁ and 15a₂ on both sides of the head 15a in the X direction is covered with the sidewall spacer 19.

Note that the sidewall spacer 19 may include an insulating film lower in relative permittivity than the insulating layer 11, in a manner similar to the above-described dielectric portion 17 of the first embodiment. In this case, since the parasitic capacitance 25 added to the field effect transistor Q can be reduced, it is possible to suppress degradation of the noise characteristics of the field effect transistor Q and improve the reliability of the semiconductor device, in a manner similar to the above-described first embodiment.

### Fifth Embodiment

In this fifth embodiment, an example where the present technology is applied to a solid-state imaging device that is called a back-illuminated complementary metal oxide semiconductor (CMOS) image sensor will be described as a photodetector included in a semiconductor device with reference to FIGS. 72 to 75.

### <<Overall Configuration of Solid-State Imaging Device>>

First, an overall configuration of a solid-state imaging device 1D will be described.

As illustrated in FIG. 72, the solid-state imaging device 1D according to the fifth embodiment of the present technology mainly includes a semiconductor chip 102 having a rectangular two-dimensional planar shape in plan view. That is, the solid-state imaging device 1D is mounted on the semiconductor chip 102, and the semiconductor chip 102 may be regarded as the solid-state imaging device 1D. As illustrated in FIG. 123, the solid-state imaging device 1D (201) receives image light (incident light 206) from a subject through an optical lens 202, converts an amount of the incident light 206 formed, as an image, on an imaging surface into an electrical signal for each pixel, and outputs the electrical signal as a pixel signal (image signal).

As illustrated in FIG. 72, the semiconductor chip 102 on which the solid-state imaging device 1D is mounted includes, in a two-dimensional plane including the X direction and the Y direction orthogonal to each other, a rectangular pixel array unit 102A provided in a central portion, and a peripheral portion 102B provided outside the pixel array unit 102A so as to surround the pixel array unit 102A. The semiconductor chip 102 is formed in a manufacturing process by dicing a semiconductor wafer including semiconductor layers 2 and 130, which will be described later, into small pieces for each chip formation region. The configuration of the solid-state imaging device 102 to be described below, therefore, is substantially similar even in a wafer state before the semiconductor wafer is diced into small pieces. That is, the present technology is applicable to both a semiconductor chip and a semiconductor wafer.

The pixel array unit 102A is, for example, a light receiving surface that receives light condensed by the optical lens (optical system) 202 illustrated in FIG. 123. Then, a plurality of pixels 103 is arranged in the pixel array unit 102A in a matrix in the two-dimensional plane including the X direction and the Y direction. In other words, the pixels 103 are repeatedly arranged in the X direction and the Y direction orthogonal to each other in the two-dimensional plane.

As illustrated in FIG. 72, a plurality of bonding pads 114 is arranged in the peripheral portion 102B. Each of the plurality of bonding pads 114 is arranged, for example, along each of four sides of the semiconductor chip 102 in the two-dimensional plane. Each of the plurality of bonding pads 114 functions as an input/output terminal for electrically connecting the semiconductor chip 102 to an external device.

### <Logic Circuit>

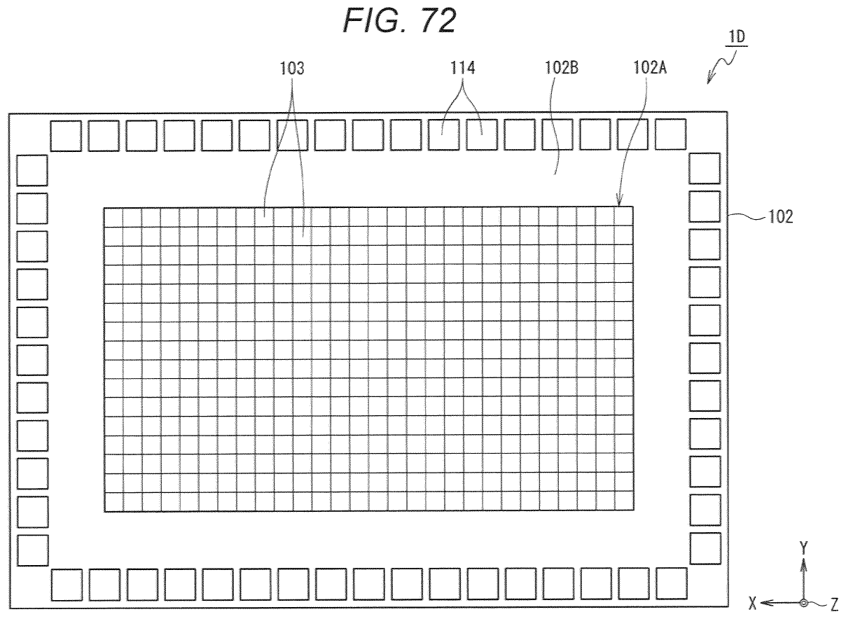

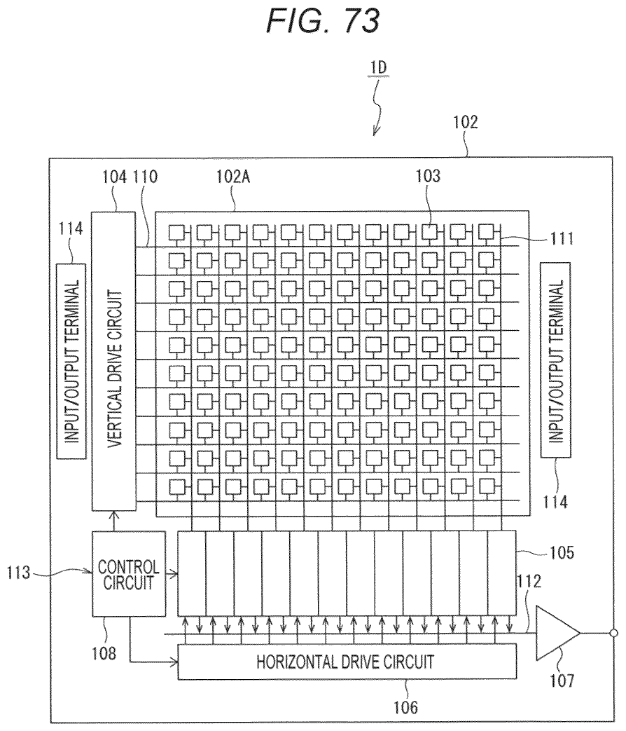

The semiconductor chip 102 includes a logic circuit 113 illustrated in FIG. 73. As illustrated in FIG. 73, the logic circuit 113 includes a vertical drive circuit 104, a column signal processing circuit 105, a horizontal drive circuit 106, an output circuit 107, a control circuit 108, and the like. The logic circuit 113 includes, for example, a complementary MOS (CMOS) circuit including an n-channel conductive metal oxide semiconductor field effect transistor (MOSFET) and a p-channel conductive MOSFET as field effect transistors.

The vertical drive circuit 104 includes, for example, a shift register. The vertical drive circuit 104 sequentially selects a desired pixel drive line 110, supplies a pulse for driving the pixel 103 to the selected pixel drive line 110, and drives each pixel 103 on a row-by-row basis. That is, the vertical drive circuit 104 selectively scans each of the pixels 103 in the pixel array unit 102A sequentially in a vertical direction on a row-by-row basis, and supplies a pixel signal from each of the pixels 103 based on a signal charge generated in accordance with the amount of received light by a photoelectric converter (photoelectric conversion element) of the pixel 103 to the column signal processing circuit 105 through a vertical signal line 111.

The column signal processing circuit 105 is arranged, for example, for every column of the pixels 103 and performs signal processing, such as noise removal on signals output from the pixels 103 of one row, for every pixel column. For example, the column signal processing circuit 105 performs signal processing such as correlated double sampling (CDS) for removing pixel-specific fixed pattern noise and analog digital (AD) conversion.

The horizontal drive circuit 106 includes, for example, a shift register. The horizontal drive circuit 106 sequentially outputs horizontal scanning pulses to the column signal processing circuits 105 to sequentially select each of the column signal processing circuits 105 and causes the column signal processing circuit 105 to output a pixel signal obtained as a result of the signal processing to a horizontal signal line 112.

The output circuit 107 performs signal processing on the pixel signals sequentially supplied from the column signal processing circuits 105 through the horizontal signal line 112 and outputs the processed signal. As the signal processing, buffering, black level adjustment, column variation correction, various kinds of digital signal processing, and the like can be used, for example.

The control circuit 108 generates, on the basis of a vertical synchronization signal, a horizontal synchronization signal, and a master clock signal, a clock signal or a control signals in accordance with which the vertical drive circuit 104, the column signal processing circuits 105, the horizontal drive circuit 106, and the like operate. The control circuit 108 then outputs the generated clock signal or control signal to the vertical drive circuit 104, the column signal processing circuits 105, the horizontal drive circuit 106, and the like.

### <Circuit Configuration of Pixel>

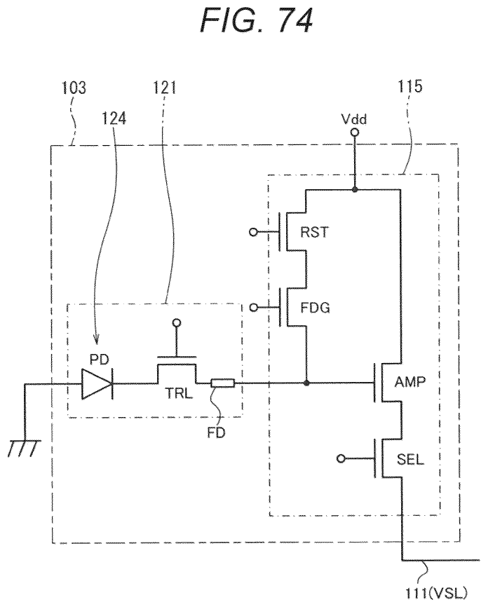

As illustrated in FIG. 74, each of the plurality of pixels 103 includes a photoelectric conversion region 121 and a pixel circuit (reading circuit) 115. The photoelectric conversion region 121 includes a photoelectric converter 124, a transfer transistor TR, and a charge holding region (floating diffusion) FD. The pixel circuit 115 is electrically connected to the charge holding region FD of the photoelectric conversion region 121. The third embodiment employs, as an example, a circuit configuration where one pixel circuit 115 is exclusively used by one pixel 103, but the circuit configuration is not limited thereto, and a circuit configuration where one pixel circuit 115 is shared by a plurality of pixels 103 may be employed. For example, a circuit configuration where one pixel circuit 115 is shared by four pixels 103 (one pixel block) arranged in a two-by-two layout, that is, two pixels 103 are arranged in the X direction and two pixels 103 are arranged in the Y direction, may be employed.

The photoelectric converter 124 illustrated in FIG. 74 is, for example, a p-n junction photodiode (PD) and generates a signal charge according to the amount of light received. The photoelectric converter 124 has a cathode side electrically connected to a source region of the transfer transistor TR and an anode side electrically connected to a reference potential line (e.g., ground).

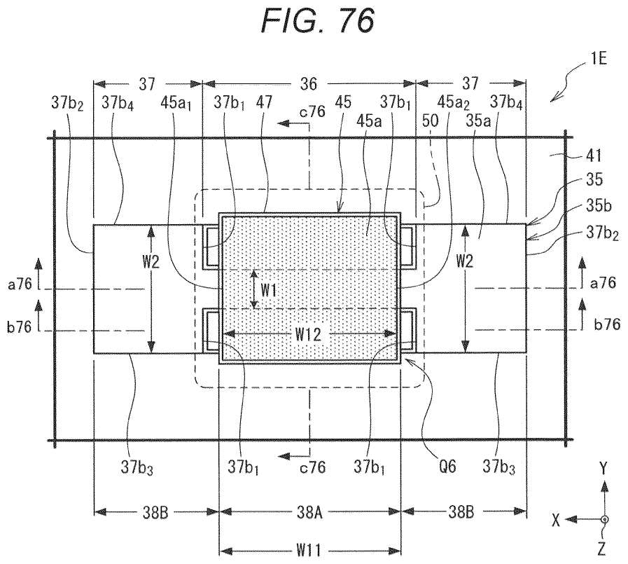

The transfer transistor TR illustrated in FIG. 74 transfers the signal charge generated as a result of photoelectric conversion in the photoelectric converter 124 to the charge holding region FD. The transfer transistor TR has the source region electrically connected to the cathode side of the photoelectric converter 124 and a drain region electrically connected to the charge holding region FD. Then, the transfer transistor TR has a gate electrode electrically connected to a transfer transistor drive line among the pixel drive lines 110 (see FIG. 76).

The charge holding region FD illustrated in FIG. 74 temporarily holds (accumulates) the signal charge transferred from the photoelectric converter 124 via the transfer transistor TR.

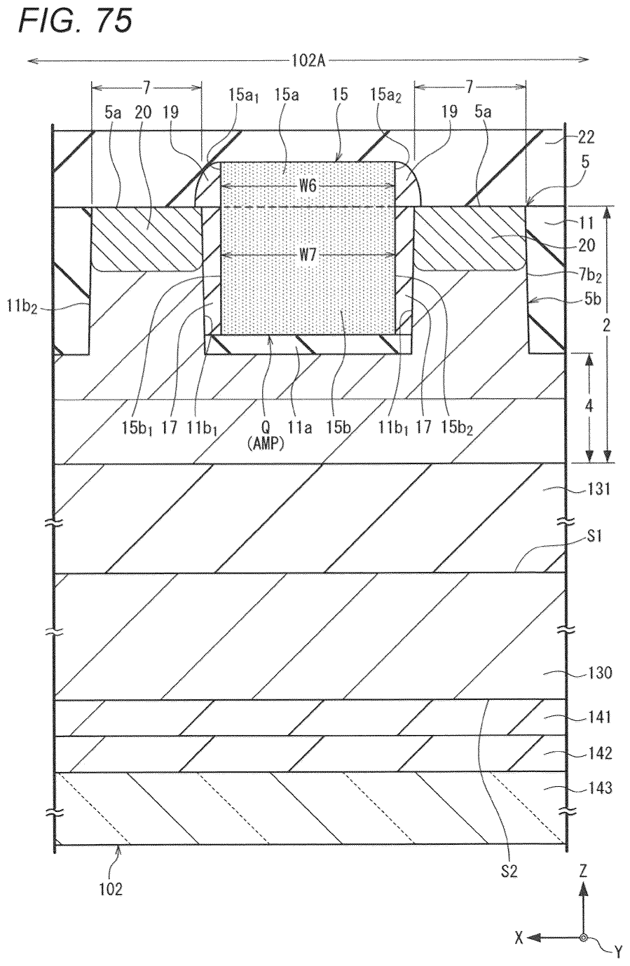

The photoelectric conversion region 121 including the photoelectric converter 124, the transfer transistor TR, and the charge holding region FD is provided in the semiconductor layer 130 (see FIG. 75) as a second semiconductor layer to be described later.

The pixel circuit 115 illustrated in FIG. 74 reads the signal charge held in the charge holding region FD, converts the read signal charge into a pixel signal, and outputs the pixel signal. In other words, the pixel circuit 115 converts the signal charge generated as a result of photoelectric conversion in a photoelectric conversion element PD into a pixel signal based on the signal charge and outputs the pixel signal. The pixel circuit 115 includes, but not limited to, an amplification transistor AMP, a selection transistor SEL, a reset transistor RST, and a switching transistor FDG as the pixel transistors, for example. Such pixel transistors (AMP, SEL, RST, and FDG) and the above-described transfer transistor TR are each include, for example, a MOSFET as a field effect transistor. Alternatively, these transistors may include MISFETs.

Among the pixel transistors included in the pixel circuit 115, the selection transistor SEL, the reset transistor RST, and the switching transistor FDG each function as a switching element, and the amplification transistor AMP functions as an amplification element. That is, the pixel circuit 115 includes field effect transistors for different purposes.

Note that the selection transistor SEL and the switching transistor FDG may be omitted as necessary.

As illustrated in FIG. 74, the amplification transistor AMP has a source region electrically connected to a drain region of the selection transistor SEL and a drain region electrically connected to a power supply line Vdd and a drain region of the reset transistor RST. Then, the amplification transistor AMP has a gate electrode electrically connected to the charge holding region FD and a source region of the switching transistor FDG.

The selection transistor SEL has a source electrically connected to a corresponding one of the vertical signal lines 111 (VSL) and the drain region electrically connected to the source region of the amplification transistor AMP. Then, the selection transistor SEL has a gate electrode electrically connected to a selection transistor drive line among the pixel drive lines 110 (see FIG. 73).

The reset transistor RST has a source region electrically connected to a drain region of the switching transistor FDG and the drain region electrically connected to the power supply line Vdd and the drain region of the amplification transistor AMP. Then, the reset transistor RST has a gate electrode electrically connected to a reset transistor drive line among the pixel drive lines 110 (see FIG. 73).

The switching transistor FDG has the source region electrically connected to the charge holding region FD and the gate electrode of the amplification transistor AMP and the drain region electrically connected to the power supply line Vdd and the drain region of the amplification transistor AMP. Then, the switching transistor FDG has a gate electrode electrically connected to a switching transistor drive line among the pixel drive lines 110 (see FIG. 73).

Note that in a case where the selection transistor SEL is omitted, the source region of the amplification transistor AMP is electrically connected to the corresponding one of the vertical signal lines (VSL) 111. Furthermore, in a case where the switching transistor FDG is omitted, the source region of the reset transistor RST is electrically connected to the gate electrode of the amplification transistor AMP and the charge holding region FD.

When turned on, the transfer transistor TR transfers the signal charge generated by the photoelectric converter 124 to the charge holding region FD.

When turned on, the reset transistor RST resets a potential (signal charge) of the charge holding region FD to a potential of the power supply line Vdd. The selection transistor SEL controls output timing of the pixel signal from the pixel circuit 115.

The amplification transistor AMP generates a signal of a voltage corresponding to a level of the signal charge held in the charge holding region FD as the pixel signal. The amplification transistor AMP constitutes a source follower amplifier and outputs a pixel signal of a voltage corresponding to the level of the signal charge generated by the photoelectric converter 124. When the selection transistor SEL is turned on, the amplification transistor AMP amplifies the potential of the charge holding region FD and outputs a voltage corresponding to the potential to the column signal processing circuit 105 via the corresponding one of the vertical signal lines (VSL) 111.

The switching transistor FDG controls charge holding by the charge holding region FD, and adjusts a voltage multiplication factor according to the potential amplified by the amplification transistors AMP.

While the solid-state imaging device 1D according to the fifth embodiment is in operation, the signal charge generated by the photoelectric converter 124 of the pixel 103 is held (accumulated) in the charge holding region FD via the transfer transistor TR of the pixel 103. Then, the signal charge held in the charge holding region FD is read by the pixel circuit 115 and applied to the gate electrode of the amplification transistor AMP of the pixel circuit 115. A vertical shift register supplies a horizontal line selection control signal to the gate electrode of the selection transistor SEL of the pixel circuit 115. Then, setting the selection control signal to a high (H) level brings the selection transistor SEL into conduction to allow a current corresponding to the potential of the charge holding region FD, amplified by the amplification transistor AMP, to flow to the vertical signal line 111. Furthermore, setting a reset control signal applied to the gate electrode of the reset transistor RST of the pixel circuit 115 to the high (H) level brings the reset transistor RST into conduction to reset the signal charge accumulated in the charge holding region FD.

### <<Longitudinal Cross-Sectional Structure of Solid-State Imaging Device>>

Next, a longitudinal cross-sectional structure of the semiconductor chip 102 (solid-state imaging device 1C) will be described with reference to FIG. 75. FIG. 75 is a schematic longitudinal cross-sectional view of a longitudinal cross-sectional structure of the pixel array unit in FIG. 72, which is upside down with respect to FIG. 72 in order to make the drawing easier to see.

### <Semiconductor Chip>

As illustrated in FIG. 75, the semiconductor chip 102 includes the semiconductor layer 130 having a first surface S1 and a second surface S2 located on opposite sides in the thickness direction (Z direction), an insulating layer 131 provided on the first surface S1 side of the semiconductor layer 130, and the semiconductor layer 2 provided on a side of the insulating layer 131 remote from the semiconductor layer 130.

The semiconductor chip 102 further includes, on the second surface S2 side of the semiconductor layer 130, a planarization layer 141, a color filter layer 142, a lens layer 143, and the like stacked in this order from the second surface S2 side.

The semiconductor layer 130 includes, for example, monocrystalline silicon.

The planarization layer 141 includes, for example, a silicon oxide film. Then, the planarization layer 141 covers the entire second surface S2 (light incident surface) side of the semiconductor layer 130 in the pixel array unit 102A so as to make the second surface S2 side of the semiconductor layer 130 flat without unevenness.

In the color filter layer 142, a color filter such as red (R), green (G), or blue (B) is provided for each pixel 103 and color-separates incident light incident from the light incident surface side of the semiconductor chip 102.

In the lens layer 143, a microlens that condenses irradiation light and allows the condensed light to efficiently enter the photoelectric conversion region 121 is provided for each pixel 103.

As illustrated in FIG. 75, the semiconductor layer 2 according to the fifth embodiment is similar in configuration to the semiconductor layer 2 according to the above-described first embodiment illustrated in FIGS. 2 and 3, and a field effect transistor Q is provided in the semiconductor 5 of the semiconductor layer 2. Then, the insulating layer 11 is provided on the base 4 of the semiconductor layer 2 so as to surround the semiconductor 5. The field effect transistor Q of the fifth embodiment is similar in configuration to the field effect transistors Q according to the above-described first embodiment.

The semiconductor layer 130 is arranged to overlap the semiconductor 5 of the semiconductor layer 2. That is, the semiconductor chip 102 has a two-layer structure with the semiconductor layer 130 and the semiconductor layer 2 stacked in their respective thickness directions (Z directions).

In the fifth embodiment, the photoelectric converter 124, the transfer transistor TR, and the charge holding region FD illustrated in FIG. 74 are each provided in the semiconductor layer 130 illustrated in FIG. 75 although not illustrated in detail.

The pixel transistors (AMP, SEL, RST, and FDG) included in the pixel circuit 115 in FIG. 74, on the other hand, are each provided in the semiconductor layer 2 illustrated in FIG. 75 although not illustrated in detail. Then, the pixel transistors (AMP, SEL, RST, and FDG) included in the pixel circuit 115 each include the field effect transistor Q illustrated in FIG. 75. FIG. 75 illustrates, as an example, the amplification transistor AMP including the field effect transistor Q.

### Main Effects of Fifth Embodiment

In the solid-state imaging device 1D according to the fifth embodiment, the pixel transistors (AMP, SEL, RST, and FDG) included in the pixel circuit 115 each include the field effect transistor Q. Therefore, the solid-state imaging device 1D according to the fifth embodiment can also produce effects similar to the effects produced by the semiconductor device 1A according to the above-described first embodiment.

Here, it is important for the amplification transistor AMP to suppress degradation of resistance to noise, such as 1/f noise or RTS noise, compared to the pixel transistors (SEL, RST, and FDG), which function as switching elements. Therefore, a case where the present technology is applied to the amplification transistor AMP included in the pixel circuit, in other words, the amplification transistor AMP includes the field effect transistor Q is particularly useful.

Furthermore, since the pixel transistors (AMP, SEL, RST, and FDG) included in the pixel circuit 115 are provided in the semiconductor layer 2 different from the semiconductor layer 130 provided with the photoelectric converter 124, the transfer transistor TR, and the charge holding region FD, a degree of freedom in arrangement of the pixel transistors (AMP, SEL, RST, and FDG) included in the pixel circuit 115 can be increased, and it is possible to achieve high integration and improvement in noise resistance compared to a case where the photoelectric converter 124, the transfer transistor TR, the charge holding region FD, and the pixel transistors are provided in the same semiconductor layer.

### Modification of Fifth Embodiment

Note that at least one of the pixel transistors (AMP, SEL, RST, and FDG) included in the pixel circuit 115 may include the field effect transistor Q.

Furthermore, as illustrated in FIGS. 41 to 43, two pixel transistors of the pixel transistors (AMP, SEL, RST, and FDG) included in the pixel circuit 115 may include two field effect transistors Q provided in one semiconductor 5. In this case, in order to increase the arrangement efficiency of the pixel transistors, it is preferable that the amplification transistor AMP and the selection transistor SEL include two field effect transistors Q provided in one semiconductor 5, and the reset transistor RST and the switching transistor FDG include two field effect transistors Q provided in one semiconductor 5.

Furthermore, at least one of the pixel transistors (AMP, SEL, RST, and FDG) included in the pixel circuit 115 may include a field effect transistor Q6 provided in a semiconductor 35 of the sixth embodiment to be described later.

### Sixth Embodiment

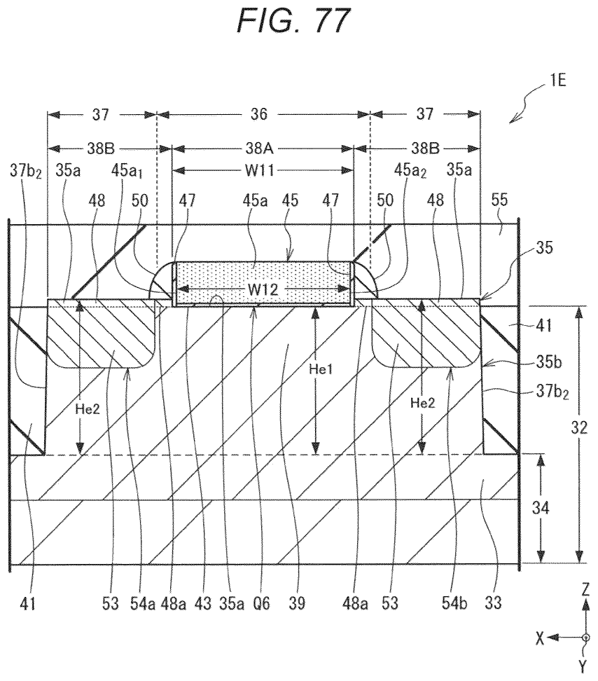

In the sixth embodiment, as illustrated in FIG. 77, a semiconductor device 1E including the semiconductor 35 in which a thickness He2 of a second region 38B is larger than a height He1 of a first region 38A, and the field effect transistor Q6 provided in the semiconductor 35 will be described.

### <<Overall Configuration of Semiconductor Device>>

First, an overall configuration of the semiconductor device 1E will be described with reference to FIGS. 76 to 79.

Note that, for convenience of description, an insulating layer 55 illustrated in FIGS. 77 to 79 is not illustrated in FIG. 76. Furthermore, in FIGS. 77 to 79, neither a contact electrode provided in the insulating layer 55 nor wiring and insulating layers located above the insulating layer 55 are illustrated.

As illustrated in FIGS. 76 to 79, the semiconductor device 1E according to the sixth embodiment of the present technology includes the island-shaped semiconductor 35 provided in a semiconductor layer 32, and the field effect transistor Q6 provided in the semiconductor 35. Furthermore, the semiconductor device 1E according to the sixth embodiment includes an insulating layer 41 provided outside the semiconductor 35 so as to surround the semiconductor 35.

### <Semiconductor Layer>

As illustrated in FIGS. 76 to 79, the semiconductor layer 32 includes a base 34 extending two-dimensionally in the X and Y directions, and the island-shaped semiconductor 35 protruding above the base 34 (in the Z direction).

### <Semiconductor>

As illustrated in FIGS. 76 to 79, the semiconductor 35 has a three-dimensional structure that includes a first portion 36 extending in the X direction (first direction), and a second portion 37 that is provided integrally alongside the first portion 36 (contiguous with the first portion 36) in the X direction and has a width W2 in a direction identical to a width W1 of the first portion 36 along the Y direction intersecting the X direction larger than the width W1 of the first portion 36, and in which the first portion 36 and the second portion 37 have an upper surface 35a and a side surface 5b.

The semiconductor 35 of the sixth embodiment has a three-dimensional structure including, but not limited to, one first portion 36 extending in the X direction and two second portions 37, each provided on either end side of the one first portion 36 in the X direction, for example. The one first portion 36 and the two second portions 37 each have a rectangular planar shape in plan view. In the X direction, the first portion 36 has one end connected to one of the two second portions 37 and has the other end connected to the other of the two second portions 37.

Furthermore, as illustrated in FIGS. 76 to 79, the semiconductor 35 further includes a first region 38A and a pair of second regions 38B provided integrally alongside the first region 38A (contiguous with the first region 38A) on both sides of the first region 38A in the X direction (first direction) and having the height (thickness) He2 in the Z direction larger than the height (thickness) He1 of the first region 38A in the Z direction. The first region 38A is provided in the first portion 36. One of the pair of second regions 38B is provided over one of the two second portions 37 and the first portion 36. Then, the other of the pair of second regions 38B is provided over the other of the two second portions 37 and the first portion 36.

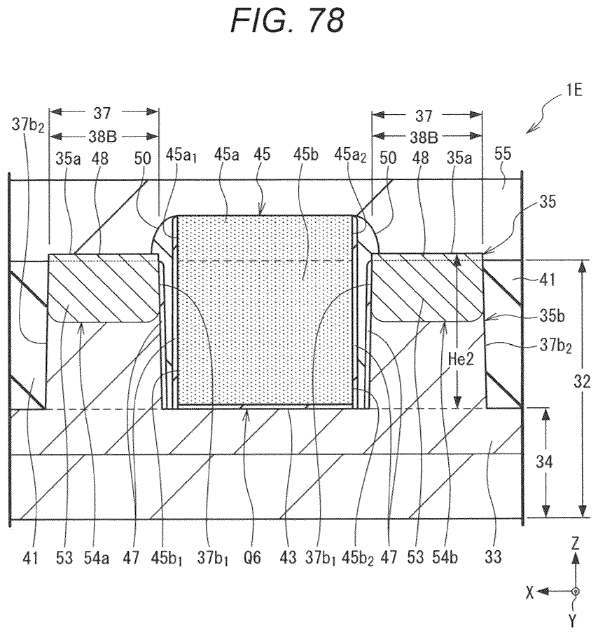

As illustrated in FIGS. 77 and 78, the first region 38A includes the semiconductor layer 32. Then, unlike the first region 38A, the second region 38B includes the semiconductor layer 32 and an n-type growth layer 48 selectively formed on an upper surface of the semiconductor layer 32 by epitaxial growth. The growth layer 48 is formed in alignment with an insulating film 47 provided on a sidewall of a gate electrode 45 to be described later.

Here, epitaxial growth can form an n-type, p-type, or i-type monocrystalline layer by inheriting the crystallinity of the semiconductor layer 32 as an underlayer. The monocrystalline layer formed by epitaxial growth, however, is covalently bonded to the semiconductor layer 32, so that in a case where the underlayer and the growth layer are of the same type and have the same conductivity type or i-type, the underlayer and the growth layer cannot be distinguished from each other under normal conditions. In the sixth embodiment, for convenience of description, the semiconductor layer 32 and the growth layer 48 will be described separately, but not limited thereto. In a case where the conductivity type is different between the underlayer and the growth layer, a depletion layer may make the underlayer and the growth layer distinguishable.

Note that, in the first region 38A, a surface layer of the semiconductor layer 32 becomes the upper surface 35a, and in the second region 38B, a surface layer of the growth layer 48 becomes the upper surface 35a. Therefore, in the semiconductor 35 of the sixth embodiment, a step is formed on the upper surface 35a between the first region 38A and the second region 38B.

As illustrated in FIGS. 76 to 79, the semiconductor 35 includes the upper surface 35a that is located on a side of the semiconductor 35 remote from the base 34 and extends two-dimensionally across the first portion 36 and the two second portions 37, and the side surface 35b that extends two-dimensionally across the first portion 36 and the two second portions 37 in the thickness direction (Z direction) of the semiconductor 35.

As illustrated in FIGS. 76 to 79, the side surface 35b includes side surfaces 36b₁ and 36b₂ located on the opposite sides of the first portion 36 in the Y direction, side surfaces 37b₁ and 37b₂ located on the opposite sides of each second portion 37 in the X direction, and side surfaces 37b₃ and 37b₄ located on the opposite sides of each second portion 37 in the Y direction. The side surface 37b₁ of the second portion 37 is divided into two portions by a connecting portion where the first portion 36 is connected to the second portion 37.

That is, the side surface 5b of the semiconductor 35 includes the side surfaces 36b₁ and 36b₂ of the first portion 36 and the side surfaces 37b₁, 37b₂, 37b₃, and 37b₄ of the each of the two second portions 37.

It is possible to form the semiconductor 35 including the first portion 36 and the second portion 37 by selectively etching the semiconductor layer 32 to such a depth that the base 34 remains. On the other hand, it is possible to make a difference in height between the first region 38A and the second region 38B of the semiconductor 35 by selectively forming the growth layer 48 on the semiconductor layer 32 of the second region 38B by epitaxial growth. The semiconductor layer 32 can be, but not limited to, a semiconductor substrate that includes, for example, silicon (Si) as a semiconductor material, is, for example, monocrystalline as crystallinity, and is, for example, of a p-conductive type as a conductivity type. The growth layer 48 includes, for example, a monocrystalline silicon layer doped with an n-type impurity.

Here, the height He1 of the first region 38A is defined as the protrusion from the base 34 to the upper surface 35a of the first region 38A. Furthermore, the height He2 of the first region 38B is defined as the protrusion from the base 34 to the upper surface 35a of the second region 38A.

As illustrated in FIGS. 77 to 79 the semiconductor layer 32 is provided with a p-type well region 33, which is, for example, a p-type semiconductor region. The p-type well region 33 is provided throughout the semiconductor 35 and provided throughout a surface layer of the base 34 adjacent to the semiconductor 35. Then, the p-type well region 33 is separated from a back surface of the base 34 remote from the semiconductor 35.

### <Insulating Layer>

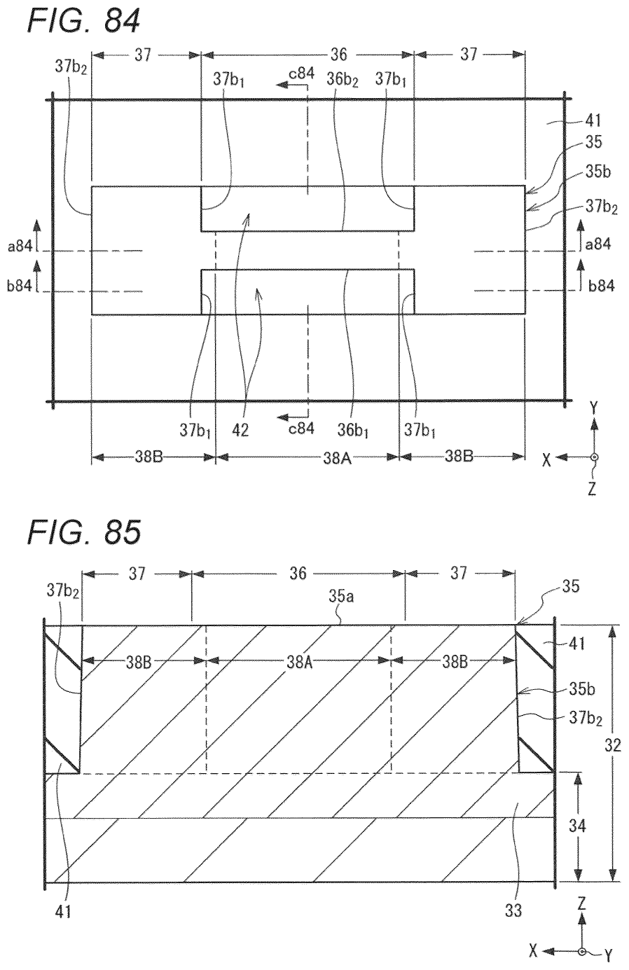

As illustrated in FIGS. 77 to 79, the insulating layer 41 is provided on the semiconductor 35 side of the semiconductor layer 32 so as to surround the semiconductor 35. The insulating layer 41 has a surface layer remote from the base 34 of the semiconductor layer 32 planarized, and has a film thickness almost equal to the height He1 of the first region 38A of the semiconductor 35 except for recessed portions 42 and 42 (see FIGS. 84, 86, and 87) to be described later. The insulating layer 41 includes, for example, a silicon oxide (SiO₂) film.

As illustrated in FIGS. 77 to 79, on a side of the insulating layer 41 remote from the base 34, the insulating layer 55 is provided to cover a head 45a of the gate electrode 45 of the field effect transistor Q6 to be described later and the semiconductor 35. The insulating layer 55 also includes, for example, a silicon oxide (SiO₂) film.

### <Field Effect Transistor>

The field effect transistor Q6 illustrated in FIG. 76 is of, but not limited to, an n-channel conductivity type. Then, the field effect transistor Q6 includes a MOSFET including a silicon oxide (SiO₂) as a gate insulating film. The field effect transistor Q6 may be of a p-channel conductivity type, instead. Furthermore, the field effect transistor Q6 may include a MISFET including, as a gate insulating film, a silicon nitride film or a multilayer film (composite film) including a silicon nitride (Si₃N₄) film and a silicon oxide film.

As illustrated in FIGS. 76 to 79, the field effect transistor Q6 is provided in the semiconductor 35 of the semiconductor layer 32.

The field effect transistor Q6 includes a channel formation portion 39 provided in the first portion 36 of the semiconductor 35, and the gate electrode 45 provided across the upper surface 5a and the side surfaces 36b₁ and 36b₂ of the first region 38A of the semiconductor 35 with a gate insulating film 43 interposed therebetween.

Furthermore, the field effect transistor Q6 includes an insulating film (isolation insulating film) 47 and a sidewall spacer 50 provided on the sidewall of the gate electrode 45 so as to surround the gate electrode 45, and a pair of main electrode regions 54a and 54b provided in the pair of second regions 38B of the semiconductor 35 and functioning as a source region and a drain region.

Here, for convenience of description, the main electrode region 54a that is one of the pair of main electrode regions 54a and 54b may be referred to as a source region 54a, and the other main electrode region 54b may be referred to as a drain region 54b.

### <Gate Electrode>

As illustrated in FIGS. 77 to 79, the gate electrode 45 includes the head 45a provided on the upper surface 35a of the first portion 36 (first region 38A) of the semiconductor 35 with the gate insulating film 43 interposed therebetween, and two legs 45b integrated with the head 45a and provided outside each of the two side surfaces 36b₁ and 36b₂ located on the opposite sides of the first portion 36 (first region 38A) of the semiconductor 35 with the gate insulating film 43 interposed therebetween.

Here, the gate electrode 45 is preferably configured such that the first portion 36 of the semiconductor 35 is sandwiched between the legs 45b in the lateral direction (Y direction). Therefore, when the number of the first portions 36 is denoted by “n”, the number of the legs 45b of gate electrode 45 is normally “n+1”. In the sixth embodiment, since one first portion 36 is provided, the gate electrode 45 includes two legs 45b.

The head 45a of the gate electrode 45 protrudes above the insulating layer 41. Then, each of the two legs 45b of the gate electrode 45 is provided in the insulating layer 41 together with the semiconductor 35. The gate electrode 45 including the head 45a and the legs 45b includes, for example, a polycrystalline silicon (doped polysilicon) film doped with an impurity for reducing a resistance value.

The head 45a has a rectangular shape in plan view, and has a three-dimensional structure including an upper surface and four side surfaces. Each of the two legs 45b has a three-dimensional structure extending from the head 45a in the thickness direction (Z direction) of the semiconductor layer 32 and in the height direction of the semiconductor 35 and including a lower surface and four side surfaces.

As illustrated in FIG. 78, the gate electrode 45 has two side surfaces 45a₁ and 45a₂ of the head 45a in the X direction (gate length direction) and two side surfaces 45b₁ and 45b₂ of the leg 45b in the X direction (gate length direction) flush with each other in cross-sectional view. In other words, the side surface 45a₁ of the head 45a and the side surface 45b₁ of the leg 45b form one flat surface continuously extending in the thickness direction (Z direction) of the semiconductor layer 32, and the side surface 45a₂ of the head 45a and the side surface 45b₂ of the leg 45b form one flat surface continuously extending in the thickness direction (Z direction) of the semiconductor layer 32.

Herein, the plan view refers to a case where the semiconductor layer 32 is viewed from a direction along the thickness direction (Z direction) of the semiconductor layer 32. Furthermore, the cross-sectional view refers to a case where a longitudinal cross section along the thickness direction (Z direction) of the semiconductor layer 32 is viewed from a direction (X direction or Y direction) orthogonal to the thickness direction (Z direction) of the semiconductor layer 32.

Note that, as illustrated in FIGS. 76 and 77, the first region 38A of the semiconductor 35 has a width W11 in a direction identical to the gate length direction (X direction, first direction) of the gate electrode 45 larger than a width W12 of the gate electrode 45 in the gate length direction.

### <Gate Insulating Film>

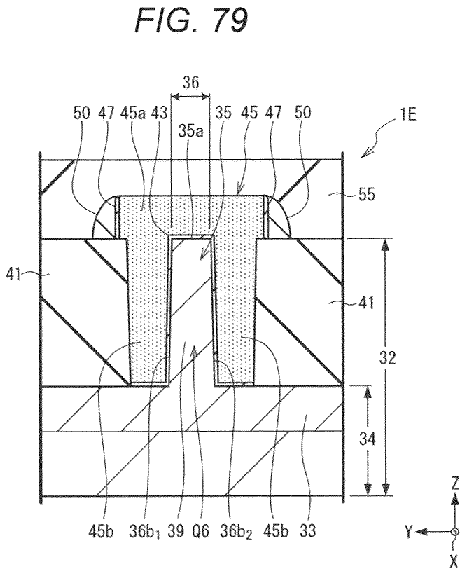

As illustrated in FIG. 79, the gate insulating film 43 is provided between the first portion 36 (first region 38A) of the semiconductor 35 and the gate electrode 45 across the upper surface 35a of the first portion 36 (first region 38A) and the two side surfaces 36b₁ and 36b₂ of the first portion 36 (first region 38A). In the sixth embodiment, since the semiconductor 35 includes one first portion 36, the gate insulating film 43 is provided across the upper surface 35a and the two side surfaces 36b₁ and 36b₂ of the one first portion 36. The gate insulating film 43 includes, for example, a silicon oxide film.

### <Insulating Film and Sidewall Spacer>

As illustrated in FIGS. 76 to 79, the insulating film 47 is provided on the sidewall of the head 45a of the gate electrode 45 so as to surround the head 45a. The insulating film 47 is provided to electrically isolate the growth layer 48 of the second region 38B of the semiconductor 35 from the gate electrode 45. Therefore, the insulating film 47 may be referred to as an isolation insulating film 47.

The insulating film 47 is provided in alignment with the head 45a of the gate electrode 45. In other words, the insulating film 47 is formed in a self-aligned manner with respect to the head 45a of the gate electrode 45. It is possible to form the insulating film 47 by, for example, forming a thin silicon oxide film on a side of the insulating layer 41 remote from the base 34 so as to cover the gate electrode 45 by a chemical vapor deposition (CVD) method, and then subjecting the silicon oxide film to anisotropic dry etching such as reactive ion etching (RIE) to selectively remove the silicon oxide film on the head 45a of the gate electrode 45 and the silicon oxide film located outside the head 45a of the gate electrode 45. The insulating film 47 is preferably formed with a film thickness of, for example, about 2 nm to 10 nm.

Note that, as illustrated in FIG. 78, the insulating film 47 is further provided on the side surface 37b₁ of the second portion 37 of the semiconductor 35.

As illustrated in FIGS. 76 to 79, the sidewall spacer 50 is provided on the sidewall of the head 45a of the gate electrode 45 so as to surround the head 45a of the gate electrode 45 with the insulating film 47 interposed therebetween. That is, the insulating film 47 is formed with a film thickness along the upper surface and the side surfaces of the gate electrode 45.

The sidewall spacer 50 is provided in alignment with the gate electrode 45 and the insulating film 47. In other words, the sidewall spacer 50 is formed in a self-aligned manner with respect to the gate electrode 45 and the insulating film 47. It is possible to form the sidewall spacer 50, by, for example, forming an insulating film by a CVD method so as to cover the gate electrode 45 and the insulating film 47 on a side of the insulating layer 41 remote from the base 34, and then subjecting the insulating film to anisotropic dry-line etching such as RIE. The sidewall spacer 50 includes, for example, a silicon nitride film.

As illustrated in FIG. 76, the sidewall spacer 50 is provided on the semiconductor 35 and the insulating layer 41 to cross the semiconductor 35. Then, of the sidewall spacer 50, a portion located on the semiconductor 35 is provided adjacent to the head 45a of the gate electrode 45, and a portion located between the side surface 37b₁ of the second portion 37 of the semiconductor 35 and the gate electrode 45 in plan view is provided adjacent to the head 45a and the leg 45b of the gate electrode 45. That is, of the sidewall spacer 50 of the sixth embodiment, a portion located on the semiconductor 35 illustrated in FIG. 77 and a portion (see FIG. 78) located between the side surface 37b₁ of the second portion 37 of the semiconductor 35 and the gate electrode 45 in plan view are different in length along the height direction (Z direction) of the semiconductor 35, and the portion illustrated in FIG. 78 is longer than the portion illustrated in FIG. 77.

As illustrated in FIG. 77, in the second region 38B of the first portion 36 of semiconductor 35, the sidewall spacer 50 is formed on the growth layer 48 located outside the insulating film 47 in alignment with the insulating film 47 located on the sidewall of the gate electrode 45. That is, in the second region 38B of the first portion 36 of the semiconductor 35, the sidewall spacer 50 is formed outside the sidewall of the gate electrode 45 in alignment with the insulating film 47 and overlap the growth layer 48 in plan view.

### <Main Electrode Region>

As illustrated in FIG. 77, each of the pair of main electrode regions 54a and 54b includes an n-type semiconductor region 53 that is aligned with the sidewall spacer 50 and is formed across the growth layer 48 and the semiconductor layer 32. The n-type semiconductor region 53 is separated from the insulating film 47 located on the sidewall of the gate electrode 45. Then, the n-type semiconductor region 53 is in contact with an n-type growth layer 48a remaining as a part of the n-type growth layer 48 between the n-type semiconductor region 53 and the insulating film 47 in the second region 38B of the first portion 36 of the semiconductor 35 and is higher in impurity concentration than the n-type growth layer 48a. The n-type growth layer 48a overlaps the sidewall spacer 50 in plan view.

The n-type growth layer 48a and the n-type semiconductor region 53 are in contact with the p-type well region 33 to form a p-n junction.

The n-type semiconductor region 53 has a thickness in the thickness direction (Z direction) of the semiconductor layer 32 and in the height direction of the semiconductor 35. Then, the n-type semiconductor region 53 is formed deeper than, in other words, thicker than the n-type growth layer 48a.

As described above, the n-type semiconductor region 53 is formed across the growth layer 48 and the semiconductor layer 32 in the second region 38B of the semiconductor 35. That is, each of the pair of main electrode regions 54a and 54b has a structure protruding above the first region 38A, in other words, a structure protruding upward.

As illustrated in FIGS. 77 and 79, the field effect transistor Q6 of the sixth embodiment is configured as a so-called fin type in which the gate electrode 45 is provided in the island-shaped semiconductor 35 as a fin portion with the gate insulating film 43 interposed therebetween.

In such a fin field effect transistor Q6, a length between the pair of main electrode regions 54a and 54b is a channel length L (≈gate length Lg), and a value obtained by multiplying a length including the width W1 of the first portion 36 on the upper surface 35a side in the lateral direction (Y direction) and a height of the two side surfaces 6b₁ and 6b₂ of the first portion 36 (length of a contour of the semiconductor 35) in a region where the gate electrode 45 and the first portion 36 of the semiconductor 35 overlap each other in three dimensions by the number of the first portions 36 is a channel width W (≈gate width).

It is therefore possible for the fin field effect transistor Q6 to increase the channel width W by increasing the width W1 of the first portion 36 of the semiconductor 35 and the height of the first portion 36 in the Z direction, thereby allowing an increase in effective channel area (channel length L×channel width W). Then, it is possible for the fin field effect transistor Q6 to increase the channel area (channel length L×channel width W) by increasing the number of the first portions 36. Although a case where the field effect transistor Q6 is provided in one semiconductor 35 has been described in the sixth embodiment, the field effect transistor Q6 may be provided in a plurality of semiconductors 35 arranged in parallel.

Furthermore, it is possible for the fin field effect transistor Q6 to increase the effective channel area without increasing its own occupied area (footprint).

The field effect transistor Q6 is, for example, of an enhancement type (normally-off type) in which a drain current flows when a gate voltage higher than or equal to a threshold voltage is applied to the gate electrode 45 or a depression type (normally-off type) in which a drain current flows even with no voltage applied to the gate electrode 45. The first embodiment employs, but not limited to, the enhancement type, for example. In the case of the enhancement type, in the field effect transistor Q6, a channel (inversion layer) electrically connecting the pair of main electrode regions 54a and 54b is formed (induced) in the channel formation portion 39 by a voltage applied to the gate electrode 45, and a current (drain current) flows from a drain region side (e.g., the main electrode region 54b side) to a source region side (e.g., the main electrode region 54a side) through the channel of the channel formation portion 39.

### <Contact Electrode and Wire>

Although not illustrated in FIGS. 76 to 79, the gate electrode 4 is electrically connected to a wire provided in a wiring layer located on the insulating layer 55 via a contact electrode provided in the insulating layer 55, in a manner similar to the above-described first embodiment. Furthermore, the main electrode region 54a that is one of the pair of main electrode regions 54a and 54b is electrically connected to a wire provided in a wiring layer located on the insulating layer 55 via a contact electrode provided in the insulating layer 55. Then, the main electrode region 54b that is the other of the pair of main electrode regions 54a and 54b, on the other hand, is electrically connected to a wire provided in a wiring layer located on the insulating layer 55 via a contact electrode provided in the insulating layer 55. As a material of the contact electrodes, for example, tungsten (W), which is a high melting point metal, may be used. Furthermore, as a material of the wires, for example, a metal material such as aluminum (Al) or copper (Cu), an alloy material mainly containing Al or Cu, or the like may be used.

### <<Method for Manufacturing Semiconductor Device>>

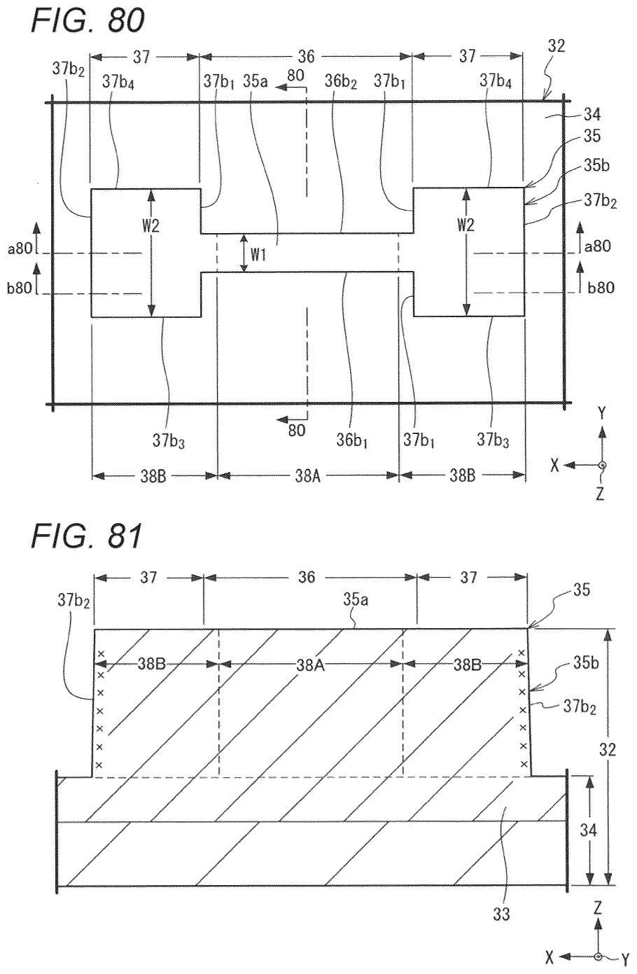

Next, a method for manufacturing the semiconductor device 1E according to the sixth embodiment will be described with reference to FIGS. 80 to 118.

Also in the sixth embodiment, a description will be given focusing on the formation of the semiconductor 35 and the charge effect transistor Q6 included in the method for manufacturing the semiconductor device 1E.

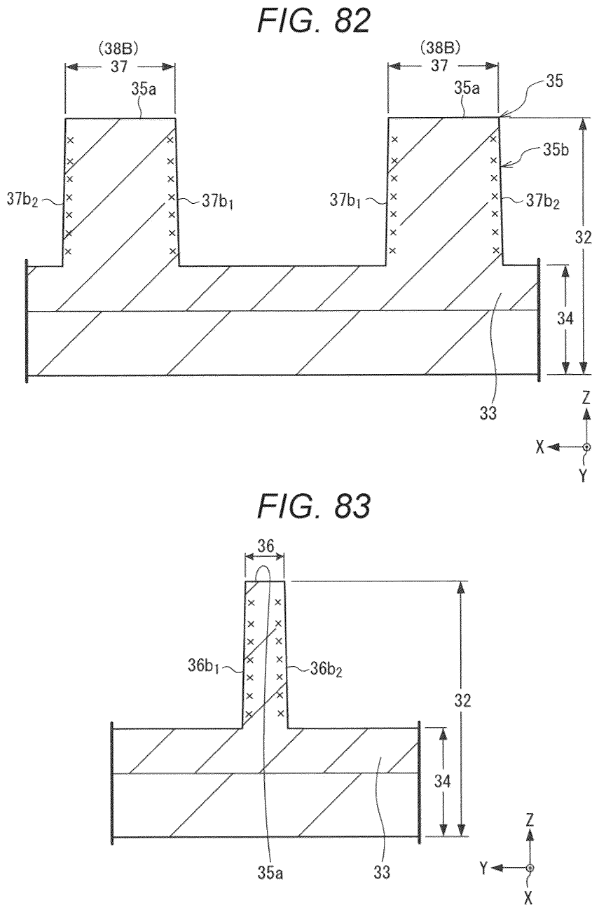

First, as illustrated in FIG. 80 (schematic plan view of the main part), FIG. 81 (schematic cross-sectional view taken along line a80-a80 in FIG. 80), FIG. 82 (schematic cross-sectional view taken along line b80-b480 in FIG. 80), and FIG. 82 (schematic cross-sectional view taken along line c80-c80 in FIG. 80), the island-shaped semiconductor 35 protruding above the base 34 is formed.

The semiconductor 35 is formed in a three-dimensional structure that includes the first portion 36 extending in the X direction (first direction), and the second portion 37 that is provided integrally alongside the first portion 36 in the X direction and has the width W2 in a direction identical to the width W1 of the first portion 36 along the Y direction (second direction) intersecting the X direction larger than the width W1 of the first portion 36, and in which the first portion 36 and the second portion 37 have the upper surface 35a and the side surface 35b. The side surface 35b includes the side surfaces 36b₁ and 36b₂ of the first portion 36 and the side surfaces 37b₁, 37b₂, 37b₃, and 37b₄ of the second portion 37. In the sixth embodiment, the semiconductor 35 is formed in a three-dimensional structure including one first portion 36 and two second portions 37, each provided on either end side of the one first portion 36 in the X direction.

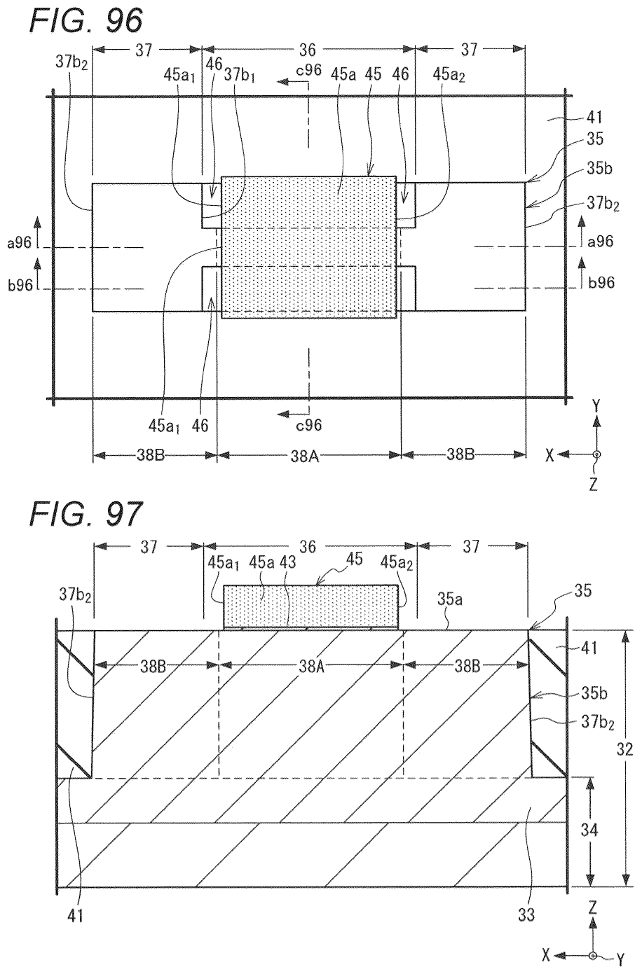

Furthermore, the semiconductor 35 further includes the first region 38A in which the gate electrode 45 (see FIG. 96) to be described later is formed, and the pair of second regions 38B and 38B that are provided contiguous with the first region 38A on both sides of the first region 38A in the X direction and in which the n-type growth layer 48 to be described later is formed. The first region 38A is provided in the first portion 36. One of the pair of second regions 38B is provided over one of the two second portions 37 and the first portion 36. Then, the other of the pair of second regions 38B is provided over the other of the two second portions 37 and the first portion 36.

It is possible to form the semiconductor 35 including the first portion 36 and the second portion 37 and including the first region 38A and the second region 38B by selectively etching the semiconductor layer 32 to such a depth that the base 34 remains. The semiconductor layer 32 can be, but not limited to, a semiconductor substrate that includes, for example, silicon (Si) as a semiconductor material, is, for example, monocrystalline as crystallinity, and is, for example, of a p-conductive type as a conductivity type.

In this step, the side surface 35b (36b₁, 36b₂, and 37b₁ to 37b₄) of the semiconductor 35 suffers damage due to processing of the semiconductor layer 32.

Note that, in the semiconductor layer 32, the p-type well region 33, which is a p-type semiconductor region, is formed before the semiconductor 35 is formed.

Next, the insulating layer 41 surrounding the semiconductor 35 is formed by a method similar to the formation of the insulating layer 11 illustrated in FIG. 9 of the above-described first embodiment.

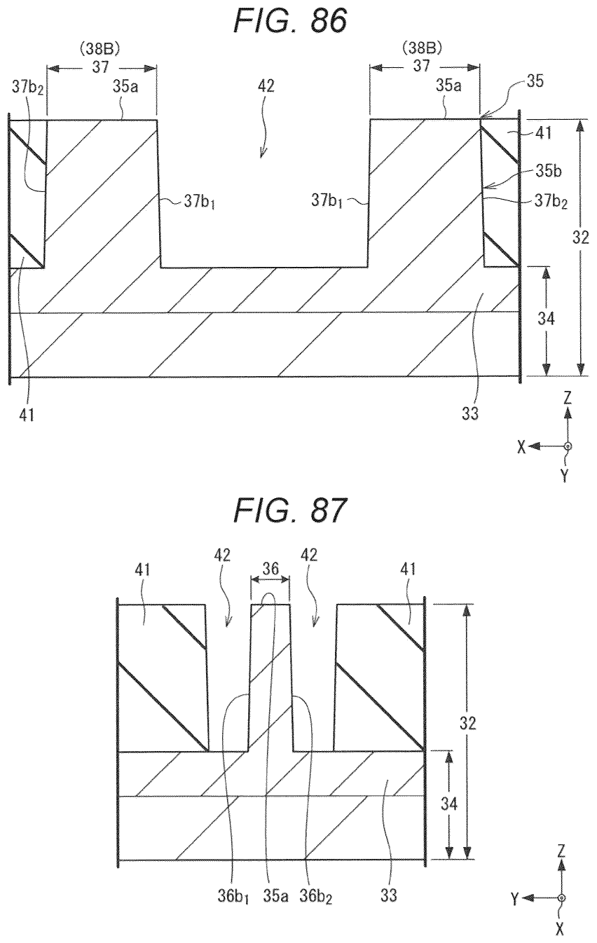

Then, after the insulating layer 41 is formed, the insulating layer 41 located outside the second portion 36 of the semiconductor 35 in the lateral direction (Y direction) is selectively removed to form the recessed portions 42a and 42a that expose the side surface 36b₁ and 36b₂ of the first portion 36 and the side surface 37b₁ of the second portion 37 outside the first portion 36 of the semiconductor 35 in the lateral direction (Y direction) as illustrated in FIG. 84 (schematic plan view of the main part), FIG. 85 (schematic cross-sectional view taken along line a84-a84 in FIG. 84), FIG. 86 (schematic cross-sectional view taken along line b84-b84 in FIG. 84), and FIG. 87 (schematic cross-sectional view taken along line c84-c84 in FIG. 84).

One of the two recessed portions 42 and 42 is formed on the side surface 36b₁ side of the first portion 36 to expose the side surface 36b₁ of the first portion 36 and the side surface 37b₁ of each of the two second portions 37 contiguous with the side surface 36b₁.

Furthermore, the other of the two recessed portions 42 and 42 is formed on the side surface 36b₂ side of the first portion 36 to expose the side surface 36b₂ of the first portion 36 and the side surface 37b₁ of each of the two second portions 37 contiguous with the side surface 36b₂.

In this step, the recessed portions 42 and 42 are formed to, but not limited to, a depth that reaches the base 34 of the semiconductor layer 32, for example, unlike the above-described first embodiment.

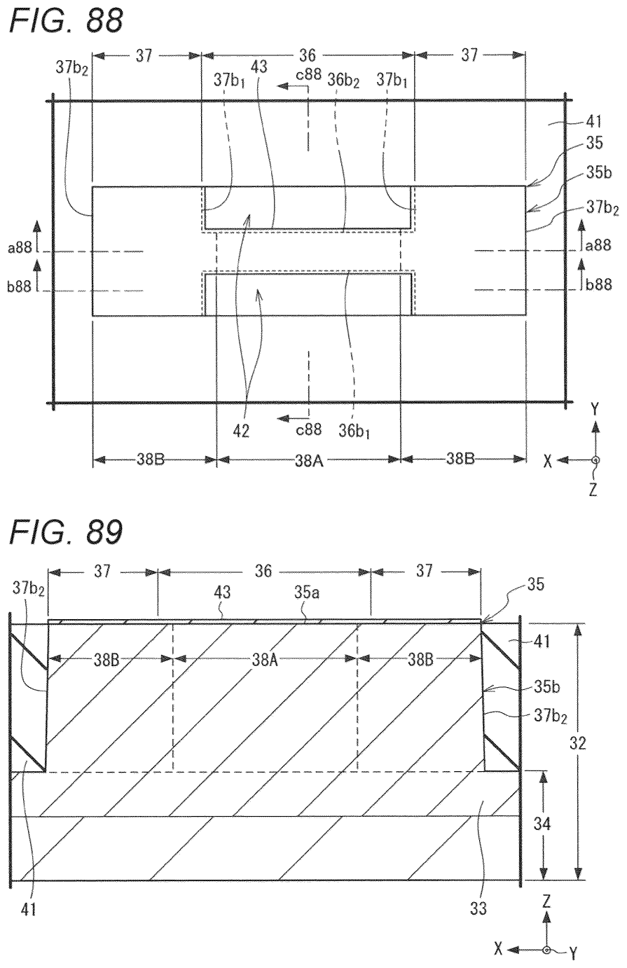

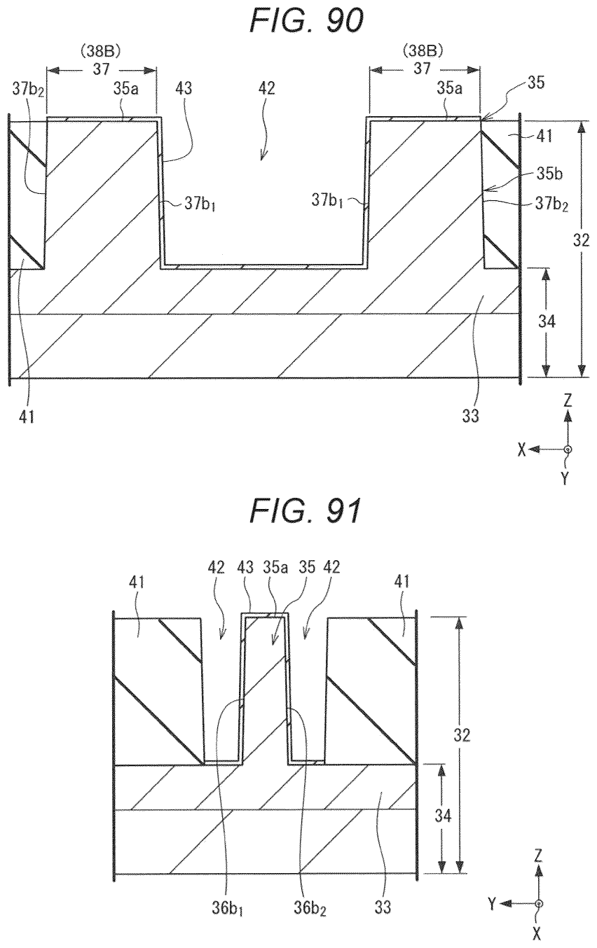

Next, as illustrated in FIG. 88 (schematic plan view of the main part), FIG. 89 (schematic cross-sectional view taken along line a88-a88 in FIG. 88), FIG. 90 (schematic cross-sectional view taken along line b88-b88 in FIG. 88), and FIG. 91 (schematic cross-sectional view taken along line c88-c88 in FIG. 88), the gate insulating film 43 is formed on the upper surface 35a of the first portion 36 of the semiconductor 35 and the two side surfaces 36b₁ and 36b₂ of the first portion 36. It is possible to form the gate insulating film 43 by forming a silicon oxide film by, for example, a thermal oxidation method or a deposition method.

In this step, the gate insulating film 43 is further formed on the upper surface 35a and the side surface 37b₁ of the second portion 37 of the semiconductor 35 and on a front surface of the base 34 of the semiconductor layer 32.

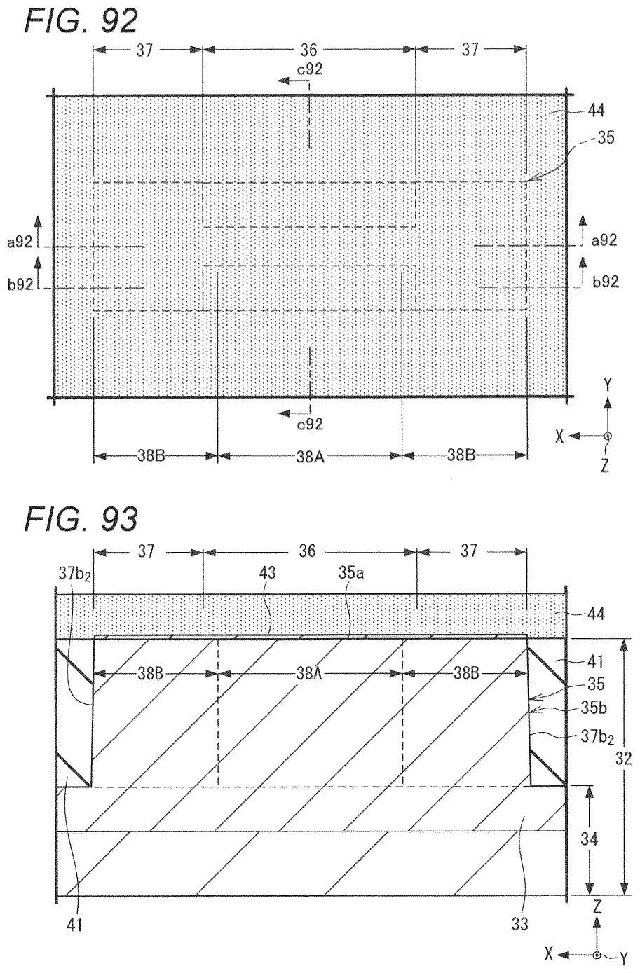

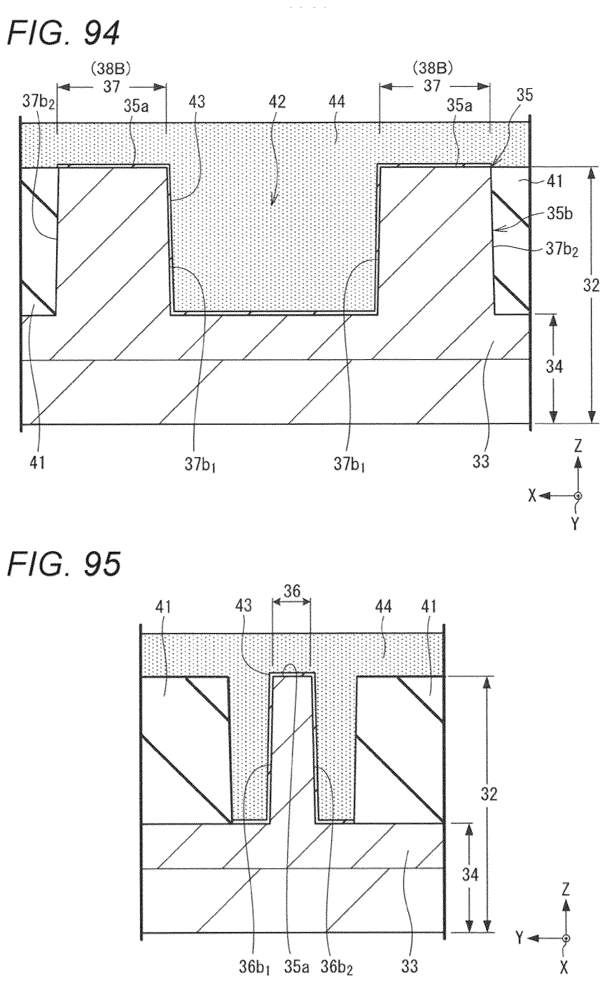

Next, after the gate insulating film 43 is formed, as illustrated in FIG. 92 (schematic plan view of the main part), FIG. 93 (schematic cross-sectional view taken along line a92-a92 in FIG. 92), FIG. 94 (schematic cross-sectional view taken along line b92-b92 in FIG. 92), and FIG. 95 (schematic cross-sectional view taken along line c92-c92 in FIG. 92), the conductive film 44 (gate electrode material) covering the semiconductor 35 and the insulating layer 41 is formed to fill the inside of each of the two recessed portions 42 and 42. As the conductive film 44, for example, a polycrystalline silicon (doped polysilicon) film doped with an impurity for reducing a resistance value during or after film formation can be used. At the portion where the gate insulating film 43 is formed on the semiconductor 35, the gate insulating film 43 is interposed between the semiconductor 35 and the conductive film 44.

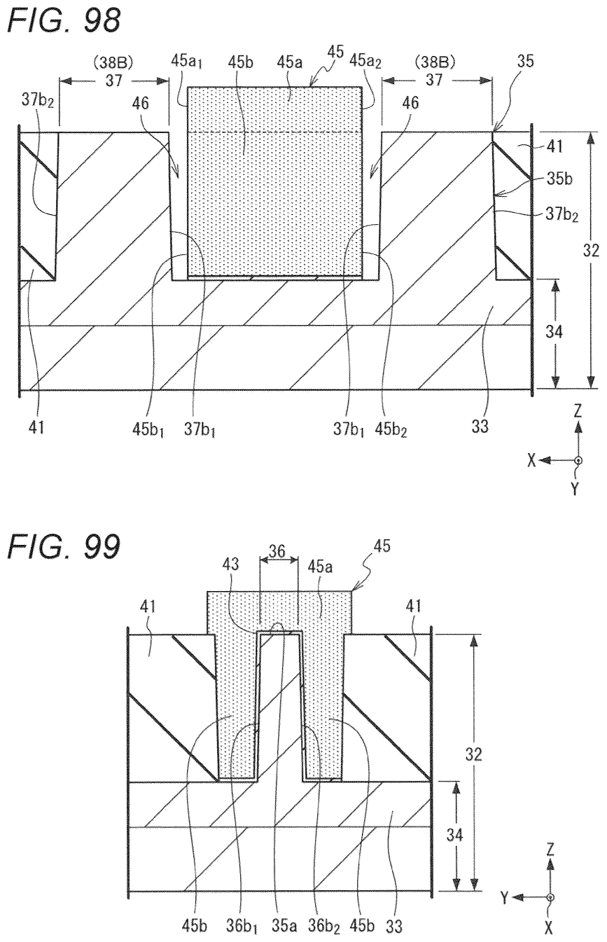

Next, the conductive film 44 is patterned using a known photolithography technique and dry etching technique, and as illustrated in FIG. 96 (schematic plan view of the main part), FIG. 97 (schematic cross-sectional view taken along line a96-a96 in FIG. 96), FIG. 98 (schematic cross-sectional view taken along line b96-b96 in FIG. 96), and FIG. 99 (schematic cross-sectional view taken along line c96-c96 in FIG. 96), the gate electrode 45 separated from each of the two second portions 37 of the semiconductor 35 and facing the upper surface 5a and the side surfaces 36b₁ and 36b₂ of the first portion 36 (first region 38A) with the gate insulating film 43 interposed therebetween is formed.

The gate electrode 45 includes the head 45a provided on the upper surface 35a of the first portion 36 of the semiconductor 35 with the gate insulating film 43 interposed therebetween, and the leg 45b integrated with the head 45 and provided outside each of the two side surfaces 36b₁ and 36b₂ located on the opposite sides of the first portion 36 of the semiconductor 35 with the gate insulating film 43 interposed therebetween.

The head 45a crosses one of the recessed portions 42, the first portion 36, the other recessed portion 42 in this order in the lateral direction (Y direction) of the first portion 36 of the semiconductor 35.

Each of the two legs 45b is formed in a corresponding one of the two recessed portions 42 and has one end connected to the head 45a.

In this step, as illustrated in FIG. 98, the gate electrode 45 is formed to make two side surfaces 45a₁ and 45a₂ of the head 45a in the X direction (gate length direction) and two side surfaces 45b₁ and 45b₂ of the leg 45b in the X direction (gate length direction) flush with each other in cross-sectional view. In other words, one side surface 45a₁ of the head 45a and one side surface 45b₁ of the leg 45b form one flat surface continuously extending in the height direction (Z direction) of the semiconductor 35, and the other side surface 45a₂ of the head 45a and the other side surface 45b₂ of the leg 45b form one flat surface continuously extending in the height direction (Z direction) of the semiconductor 35.

Furthermore, in this step, as illustrated in FIGS. 96 and 98, a gap (space) 46 is formed between the side surface 7b₁ of the second portion 37 of the semiconductor 35 and leg 45b of gate electrode 45. In FIG. 98, as an example, the gap 46 on the side surface 36b₁ side of the first portion 36 is illustrated.

In the first embodiment, since the semiconductor 35 includes one first portion 36 and two second portions 37, the gap 46 includes two gaps formed on either side (side adjacent to each of the two second portions 37) of the gate electrode 45 in the gate length direction in plan view.

Furthermore, in this step, the gate insulating film 43 on the upper surface 35a and the side surface 37b₁ of the second portion 37 of the semiconductor 35 is removed by side etching and over etching when the conductive film 44 is patterned.

Furthermore, in this step, as illustrated in FIGS. 96 to 98, the gate electrode 45 facing the upper surface 35a and the side surface 35b of the first region 38A of the semiconductor 35 with the gate insulating film 43 interposed therebetween is formed in the first region 38A.

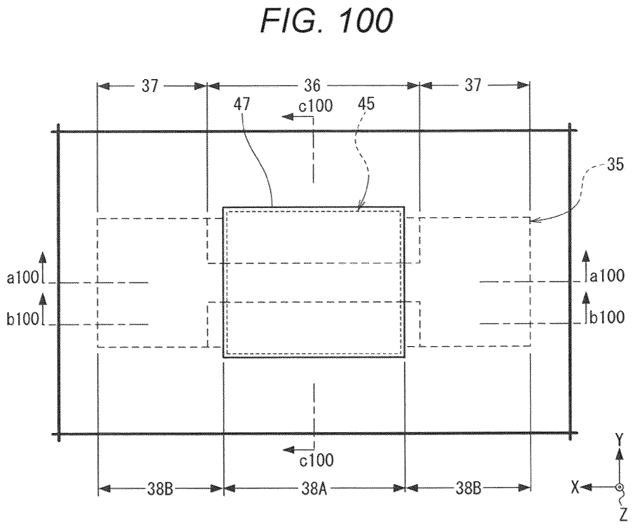

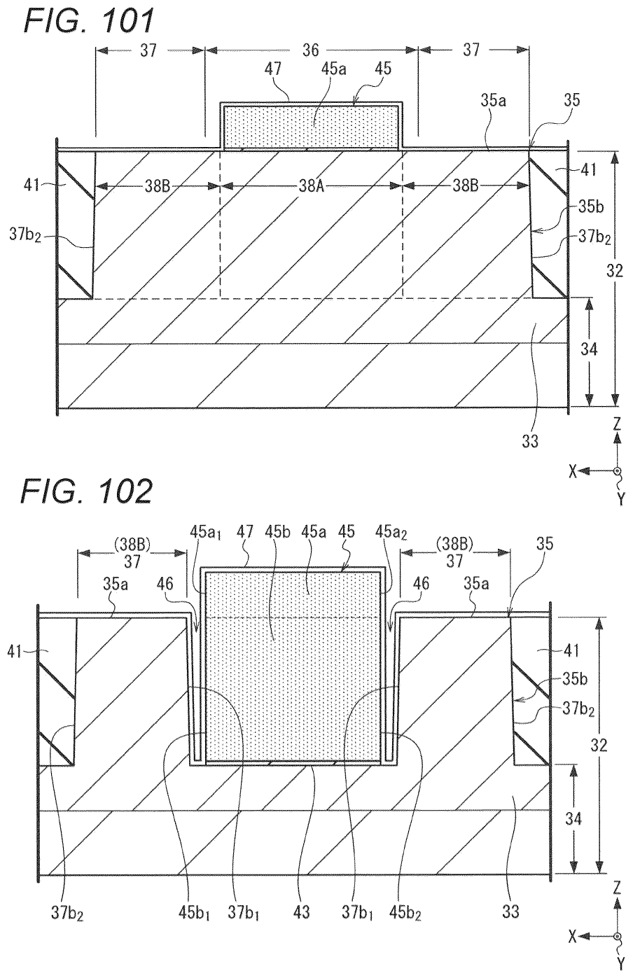

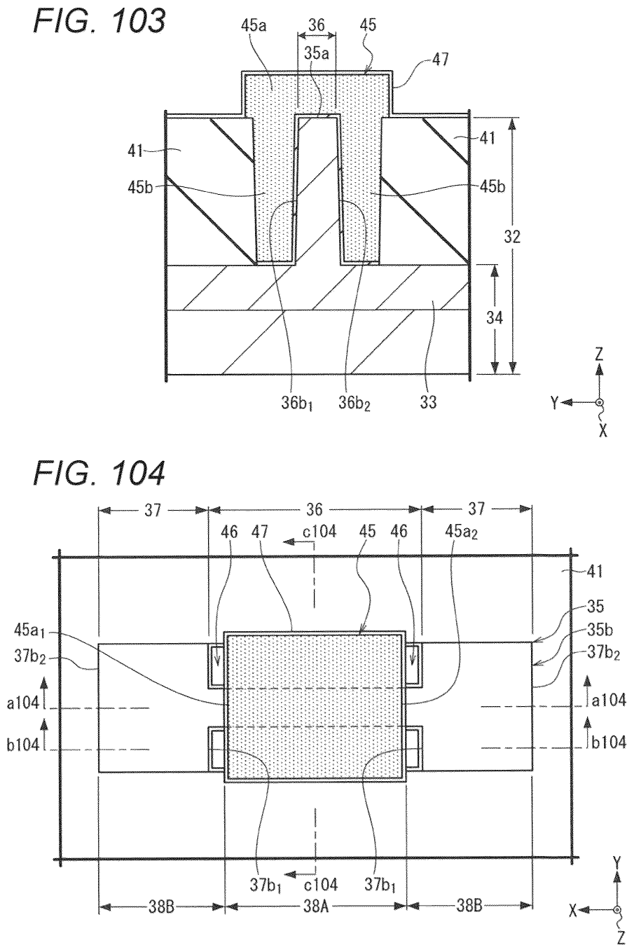

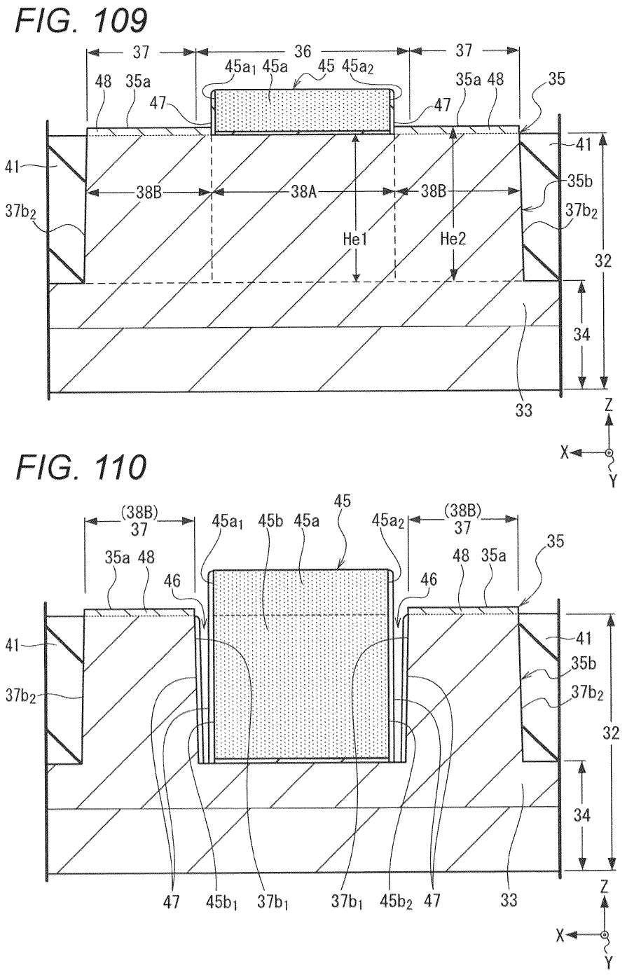

Next, as illustrated in FIG. 100 (schematic plan view of the main part), FIG. 101 (schematic cross-sectional view taken along line a100-a100 in FIG. 100), FIG. 102 (schematic cross-sectional view taken along line b100-b100 in FIG. 100), and FIG. 103 (schematic cross-sectional view taken along line c100-c100 in FIG. 100), the insulating film 47 is formed across the semiconductor 35, the gate electrode 45, and the insulating layer 41 so as to cover the sidewall of the gate electrode 45. It is possible to form the insulating film 47 by forming a silicon oxide film by, for example, a CVD method. The insulating film 47 is provided to electrically isolate the gate electrode 45 from the growth layer 48 (see FIGS. 109 and 110) to be described later, and is preferably formed with a thin film thickness of, for example, about 2 nm to 10 nm. That is, the insulating film 47 is formed with a film thickness along the upper surface and the side surfaces of the gate electrode 45.

In this step, as illustrated in FIG. 102, the insulating film 47 is formed across the side surfaces 45a₁ and 45a₂ of the head 45a of the gate electrode 45 and the side surfaces 45b₁ and 45b₂ of the leg 45b. Furthermore, the insulating film 47 is further formed on the side surface 37b₁ of the second portion 37 of the semiconductor 35.

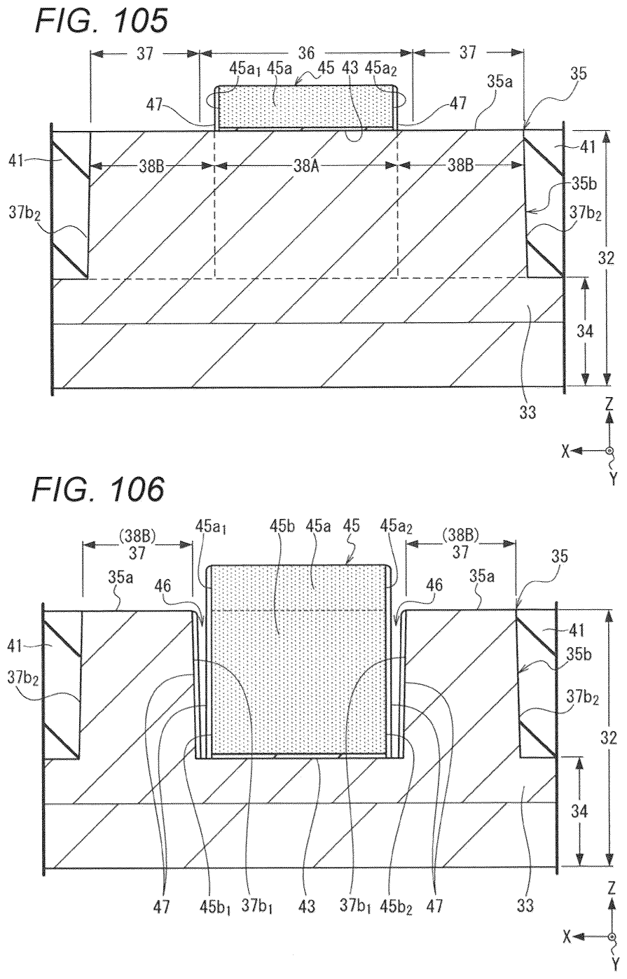

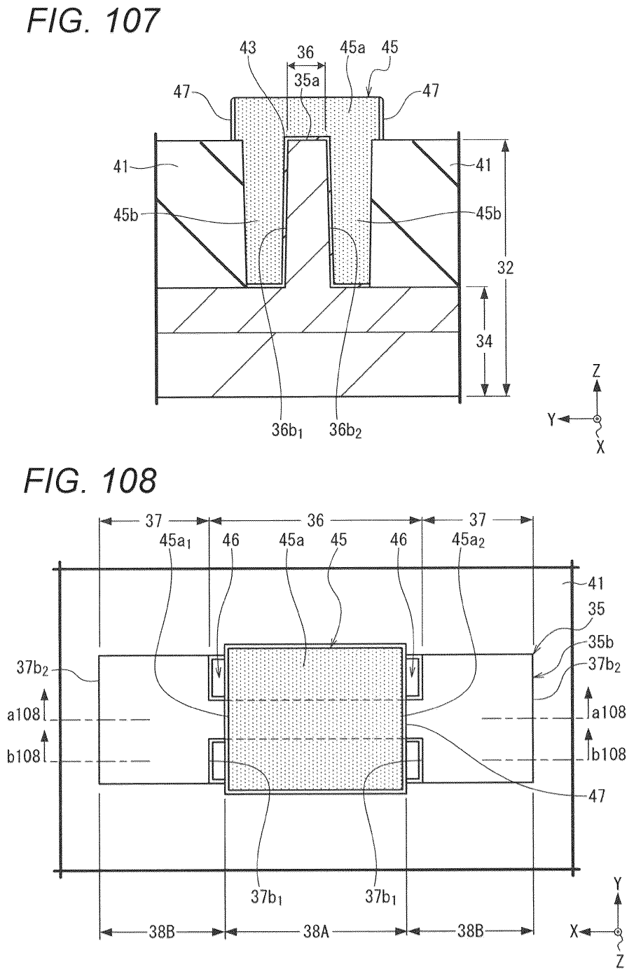

Next, the insulating film 47 located on the gate electrode 45 and outside the gate electrode 45 is selectively removed such that the insulating film 47 remains on the sidewall of the gate electrode 45, and as illustrated in FIG. 104 (schematic plan view of the main part), FIG. 105 (schematic cross-sectional view taken along line a104-a104 in FIG. 104), FIG. 106 (schematic cross-sectional view taken along line b104-b104 in FIG. 104), and FIG. 107 (schematic cross-sectional view taken along line c104-c104 in FIG. 104), the insulating film 47 is formed on the sidewall of the gate electrode 45 to cover the sidewall of the gate electrode 45. The selective removal of the insulating film 47 can be performed by known anisotropic dry etching such as RIE. Furthermore, the selective removal of the insulating film 47 can also be performed by patterning the insulating film 47 using an etching mask.

Next, in the semiconductor 35, the growth layer 48 is selectively formed by epitaxial growth on the upper surface 35a of each of the pair of second regions 38B and 38B located on both sides of the first region 38A in the X direction where the gate electrode 45 is formed, and as illustrated in FIG. 108 (schematic plan view of the main part), FIG. 109 (schematic cross-sectional view taken along line a108-a108 in FIG. 108), and FIG. 110 (schematic cross-sectional view taken along line b108-b108 in FIG. 108), the height (thickness) He2 in the Z direction of each of the pair of second regions 38B and 38B is made larger (thicker) than the height (thickness) He1 in the Z direction of the first region 38A. The growth layer 48 is formed by inheriting the crystallinity of the semiconductor layer 32 as a base, so that the growth layer 48 is formed as, for example, a monocrystalline silicon layer doped with an n-type impurity.

In this step, the growth layer 48 is formed in alignment with the gate electrode 45 and the insulating film 47. Then, the growth layer 48 is formed to be isolated from the gate electrode 45 by the insulating film 47.

Furthermore, in this step, since the side surface 37b₁ of the second portion 37 of the semiconductor 35 is covered with the insulating film 47, the growth layer 48 is generally not formed on the side surface 37b₁ of the second portion 37.

Furthermore, in this step, the first region 38A of the semiconductor 35 includes the semiconductor layer 32, and the surface layer of the semiconductor layer 32 becomes the upper surface 35a. On the other hand, the second region 38B of the semiconductor 35 includes the semiconductor layer 32 and the growth layer 48, and the front surface of the growth layer 48 becomes the upper surface 35a.

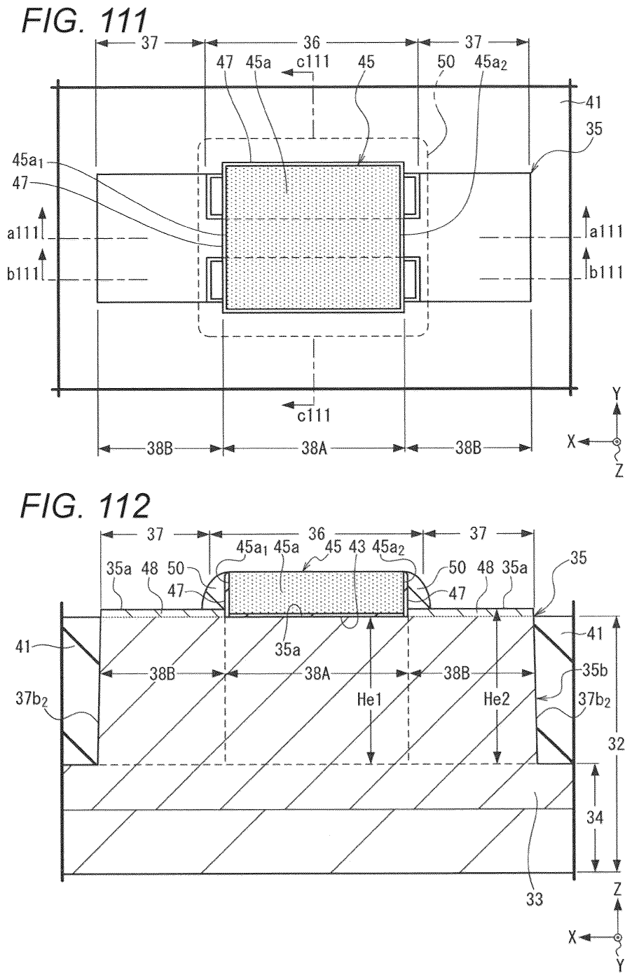

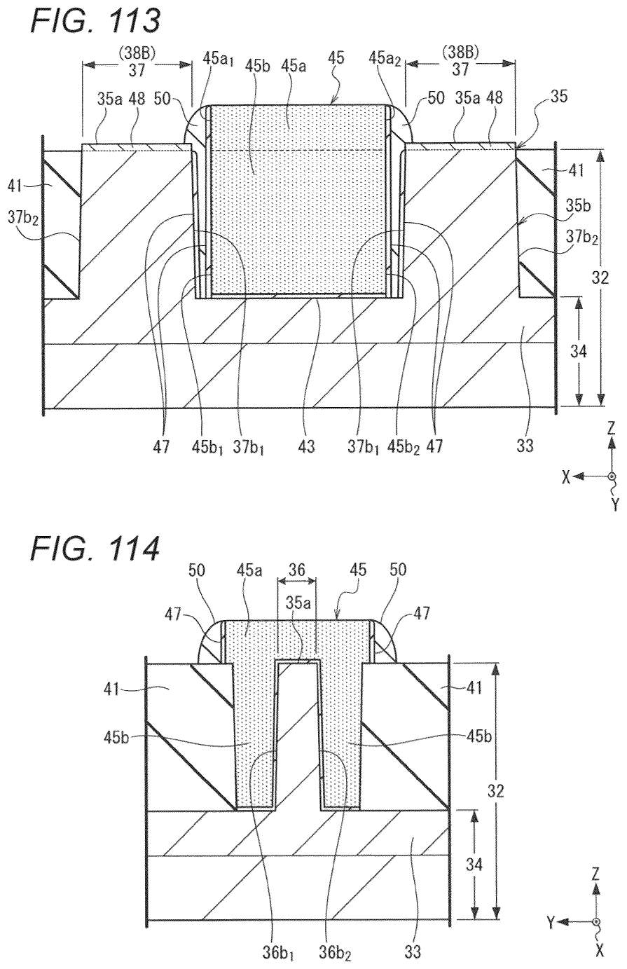

Next, as illustrated in FIG. 111 (schematic plan view of the main part), FIG. 112 (schematic cross-sectional view taken along line a111-a111 in FIG. 111), FIG. 113 (schematic cross-sectional view taken along line b111-b111 in FIG. 111), and FIG. 114 (schematic cross-sectional view taken along line c111-c111 in FIG. 111), the sidewall spacer 50 covering the side surfaces 45a₁ and 45a₂ of the head 45a and the side surfaces 45b₁ and 45b₂ of the leg 45b is formed on the sidewall of the gate electrode 45. It is possible to form the sidewall spacer 50 by forming an insulating film across the insulating layer 41 by a CVD method so as to fill the gap 46 illustrated in FIG. 110 and cover the semiconductor 35 and the head 45a of the gate electrode 45, and then subjecting the insulating film to anisotropic dry etching such as RIE. As the insulating film, for example, a silicon oxide film can be used.

In this step, the sidewall spacer 50 is formed on the sidewall of the head 45a of the gate electrode 45 with the insulating film 47 interposed therebetween so as to surround the head 45a of the gate electrode 45 and is formed in a self-aligned manner with respect to the gate electrode 45. The sidewall spacer 50 crosses, in the Y direction, the first portion 36 located outside the gate electrode 45 in the gate length direction.

Furthermore, in this step, as illustrated in FIGS. 112 and 113, the sidewall spacer 50 is formed to overlap the growth layer 48 of the second region 38B of the semiconductor 35 in plan view.

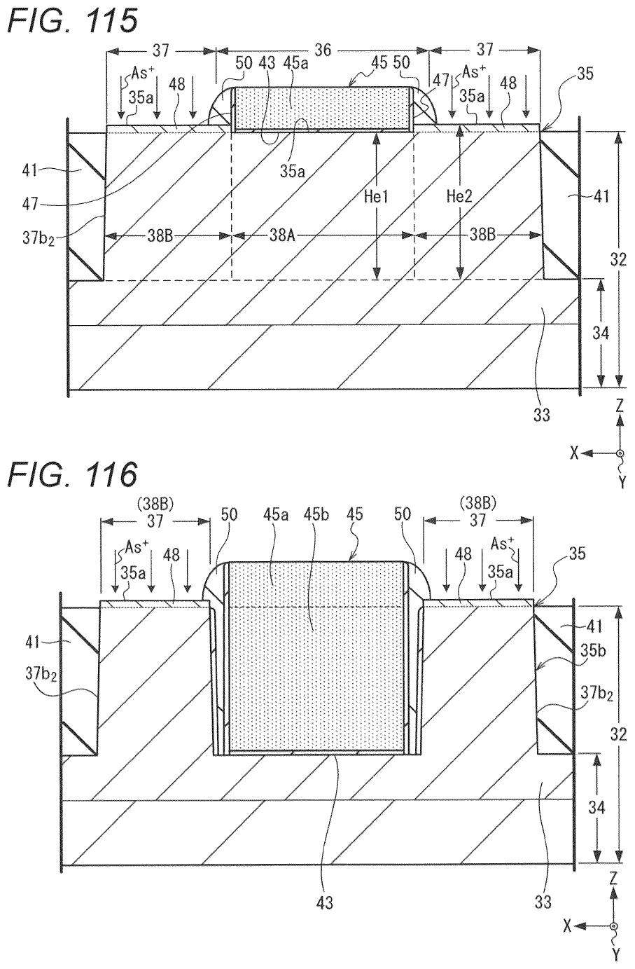

Next, using the gate electrode 45, the insulating film 47, and the sidewall spacer 50 as a mask for impurity introduction, as illustrated in FIG. 115 (schematic longitudinal cross-sectional view taken along line a111-a111 in FIG. 111) and FIG. 116 (schematic longitudinal cross-sectional view taken along line b111-b111 in FIG. 111), for example, arsenic ions (As⁺) are selectively implanted as an n-type impurity into the pair of second regions 38B of the semiconductor 35. As the n-type impurity, phosphorus ions (P⁺) may be used.

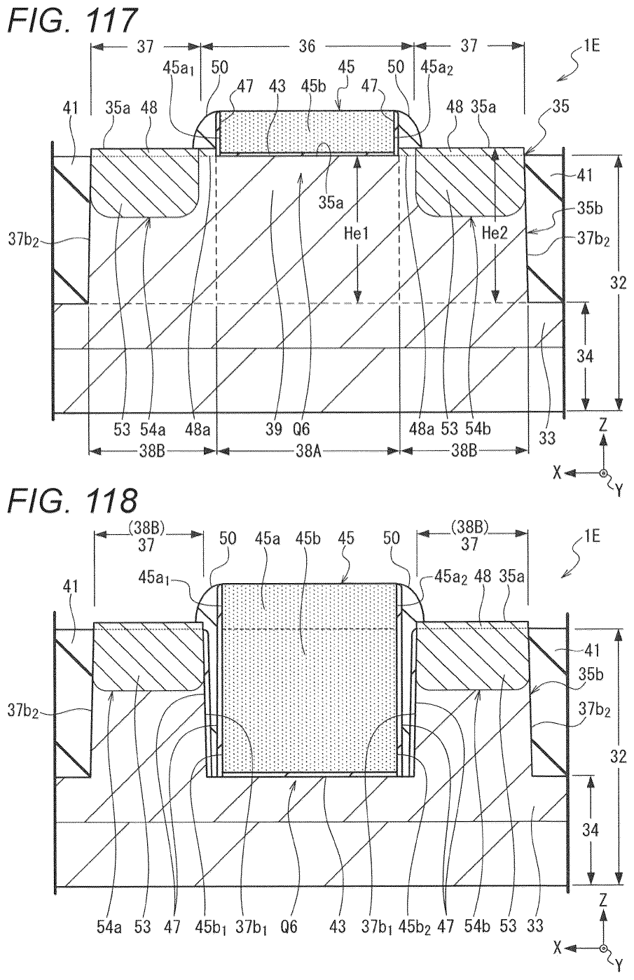

Next, heat treatment for activating the impurity (arsenic ions As⁺) implanted into the second region 38B of the semiconductor 35 is performed to form the pair of n-type semiconductor regions 53 and 53 in the pair of second regions 38B and 38B of the semiconductor 35 as illustrated in FIG. 117 (schematic longitudinal cross-sectional view taken along line a111-a111 in FIG. 111) and FIG. 118 (schematic longitudinal cross-sectional view taken along line b111-b111 in FIG. 111). Each of the pair of n-type semiconductor regions 53 is aligned with the sidewall spacer 50 and is formed across the growth layer 48 and the semiconductor layer 32. Then, each of the pair of n-type semiconductor regions 53 is in contact with the n-type growth layer 48a remaining as a part of the n-type growth layer 48 between the n-type semiconductor region 53 and the insulating film 47 in the second region 38B of the semiconductor 35 and is formed with a higher impurity concentration than the n-type growth layer 48a. The n-type growth layer 48a overlaps the sidewall spacer 50 in plan view.

In this step, the pair of main electrode regions 54a and 54b each including the n-type semiconductor region 53 are formed in the pair of second regions 38B of the semiconductor 35.

Furthermore, in this step, the channel formation portion 39 is formed in the semiconductor 35 between the pair of main electrode regions 54a and 54b.

Furthermore, in this step, the field effect transistor Q6 including the gate insulating film 43, the gate electrode 45, the pair of main electrode regions 54a and 54b, the channel formation portion 39, and the like is formed in the semiconductor 35.

Furthermore, in this step, each of the pair of main electrode regions 54a and 54b is formed in a structure protruding above the first region 38A (structure protruding upward). Next, the insulating layer 55 covering the semiconductor 35 and the field effect transistor Q6 is formed on the insulating layer 41, and a surface layer of the insulating layer 55 remote from the semiconductor 35 is planarized, which results in a state illustrated in FIGS. 76 to 79.

### Main Effects of Sixth Embodiment

The semiconductor device 1E according to the sixth embodiment includes the semiconductor 35 and the field effect transistor Q6 provided in the semiconductor 35. Then, the semiconductor 35 includes the first region 38A and the pair of second regions 38B and 38B provided contiguous with the first region 38A on both sides of the first region 38A in the X direction (first direction) and having the height He2 larger than the height He1 of the first region 38A. Then, the field effect transistor Q6 includes the gate electrode 45 provided on the upper surface 35a and the side surfaces 35b₁ and 35b₂ of the first region 38A with the gate insulating film 43 interposed therebetween, and the pair of main electrode regions 54a and 54b provided in the pair of second regions 38B and 38B.

Therefore, the semiconductor device 1E according to the sixth embodiment has a structure in which the pair of main electrode regions 54a and 54b protrude above the first region 38A of the semiconductor 35, which increases the effective channel length as compared with a conventional structure in which the first region 38A and the second region 38B of the semiconductor 35 are flat, so that a short channel effect can be suppressed. It is therefore possible to improve the reliability of the semiconductor device 1E.

Furthermore, in the step of forming the gate electrode 45 of the method for manufacturing the semiconductor device 1E according to the sixth embodiment, the gate electrode 45 including the head 45a and the leg 45b is formed by processing the conductive film 44 once, so that the two side surfaces 45a₁ and 45a₂ of the head 45a in the X direction (gate length direction) and the two side surfaces 45b₁ and 45b₂ of the leg 45b in the X direction (gate length direction) can be made flush with each other in cross-sectional view.

Furthermore, in the method for manufacturing the semiconductor device 1E according to the sixth embodiment, the side surfaces 45a₁ and 45a₂ of the head 45a and the side surfaces 45b₁ and 45b₂ of the leg 45b can be made flush with each other in cross-sectional view, so that the parasitic capacitance Cgd between the gate electrode 45 and the drain region (for example, the main electrode region 54b) is not affected by process variations as in the related art, in a manner similar to the above-described first embodiment. Therefore, according to the method for manufacturing the semiconductor device 1E of the sixth embodiment, it is possible to suppress degradation of the noise characteristics of the field effect transistor Q6, in a manner similar to the above-described first embodiment.

Furthermore, in the method for manufacturing the semiconductor device 1E according to the sixth embodiment, since the pair of main electrode regions 54a and 54b are formed in the pair of second regions 48B and 48B having the height He2 larger than the height He1 of the first region 48A of the semiconductor 35, it is possible to form a structure in which the pair of main electrode regions 54a and 54b protrude above the first region 38A of the semiconductor 35. It is therefore possible to increase the effective channel length of the field effect transistor Q6 and suppress the short channel effect as compared with a conventional structure in which the first region 38A and the second region 38B of the semiconductor 35 are flat. It is therefore possible to manufacture, according to the method for manufacturing the semiconductor device 1E according to the sixth embodiment, the semiconductor device 1E with higher reliability.

Note that although a case where the growth layer 48 is selectively formed by epitaxial growth with the side surface 37b₁ of the second portion 37 (second region 38B) of the semiconductor 35 covered with the insulating film 47 has been described in the above-described sixth embodiment, the side surface 37b₁ of the second portion 37 (second region 38B) of the semiconductor 35 need not be necessarily covered with the insulating film. That is, when the semiconductor layer 32 is processed to form the semiconductor 35, the side surface 35b of the semiconductor 35 suffers etching damage due to processing of the semiconductor layer 32. In a case where such etching damage remains in the side surface 37b₁ of the second portion 37 (second region 38B) of the semiconductor 35, a monocrystalline layer formed by epitaxial growth is not formed on the side surface 37b₁ of the second portion 37 (second region 38B). It is therefore possible to selectively form, even if the side surface 37b₁ of the second portion 37 (second region 38B) is not covered with the insulating film, the growth layer 48 on the upper surface of the second region 38B of the semiconductor 35 by epitaxial growth.

Furthermore, unlike the polycrystalline growth layer 48, even if a polycrystalline or amorphous growth layer is formed on the side surface 37b₁ of the second portion 37 (second region 38B), such growth layers can be selectively removed.

### Seventh Embodiment

A semiconductor device 1F according to a seventh embodiment of the present technology is basically similar in configuration to the semiconductor device 1E according to the above-described sixth embodiment, and the configuration of the semiconductor is different.

That is, as illustrated in FIG. 77, the semiconductor 35 of the above-described sixth embodiment has a configuration in which one growth layer 48 is provided in the second region 38B.

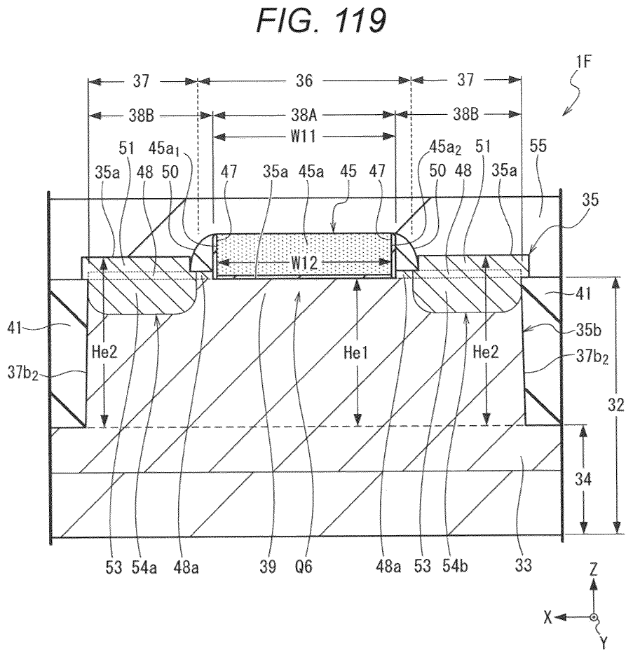

On the other hand, as illustrated in FIG. 119, a semiconductor 35 of the seventh embodiment has a configuration in which two growth layers 48 and 51 are provided in the second region 38B. The two growth layers 48 and 51 are obtained by selectively forming the growth layer 51 on the growth layer 48 by epitaxial growth after forming the sidewall spacer 50 in a manufacturing process of the semiconductor device 1F.

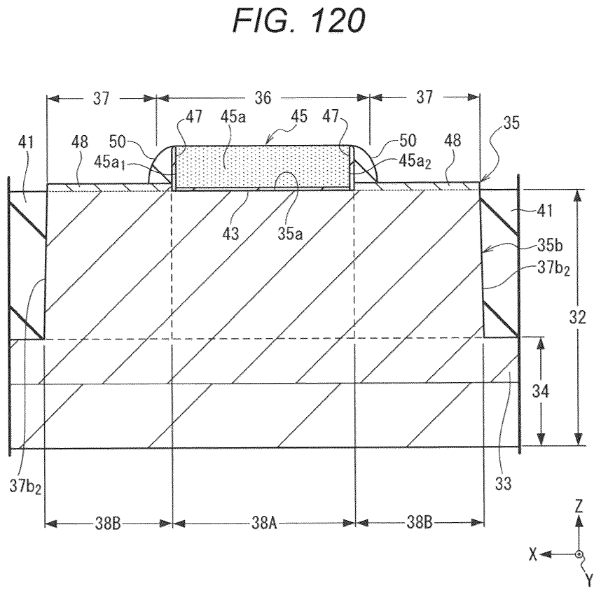

Specifically, as illustrated in FIG. 120, steps similar to the steps in the above-described sixth embodiment are performed to form up to the sidewall spacer 50.

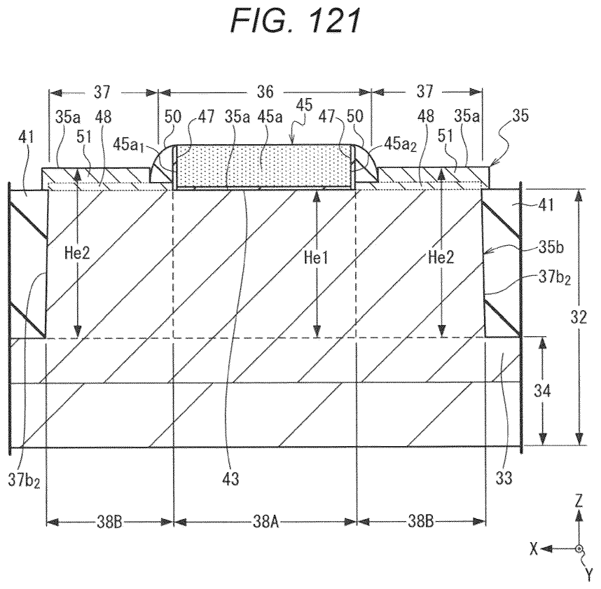

Next, as illustrated in FIG. 121, in the pair of second regions 38B and 38B of the semiconductor 35, the growth layer 51 is selectively formed on the upper surface of each growth layer 48 by epitaxial growth. The growth layer 51 is formed by inheriting the crystallinity of the growth layer 48 as a base, so that growth layer 51 can be formed as, for example, a monocrystalline silicon layer doped with an n-type impurity.

In this step, the growth layer 51 is formed in alignment with the sidewall spacer 50. Then, the growth layer 51 is formed to be isolated from the gate electrode 45 by the sidewall spacer 50 and the insulating film 47.

Furthermore, in this step, each of the pair of second regions 38B and 38B of the semiconductor 35 includes the semiconductor layer 32 and the growth layers 48 and 51, and a surface layer of the growth layer 51 becomes the upper surface 35a. Then, the height (thickness) He2 of each of the pair of second regions 38B and 38B in the Z direction can be made larger (thicker) than the height (thickness) He1 of the first region 38A in the Z direction.

Next, using the gate electrode 45, the insulating film 47, and the sidewall spacer 50 as a mask for impurity introduction, for example, arsenic ions (As⁺) are selectively implanted as an n-type impurity into each of the pair of second regions 38B and 38B of the semiconductor 35. As the n-type impurity, phosphorus ions (P⁺) may be used.

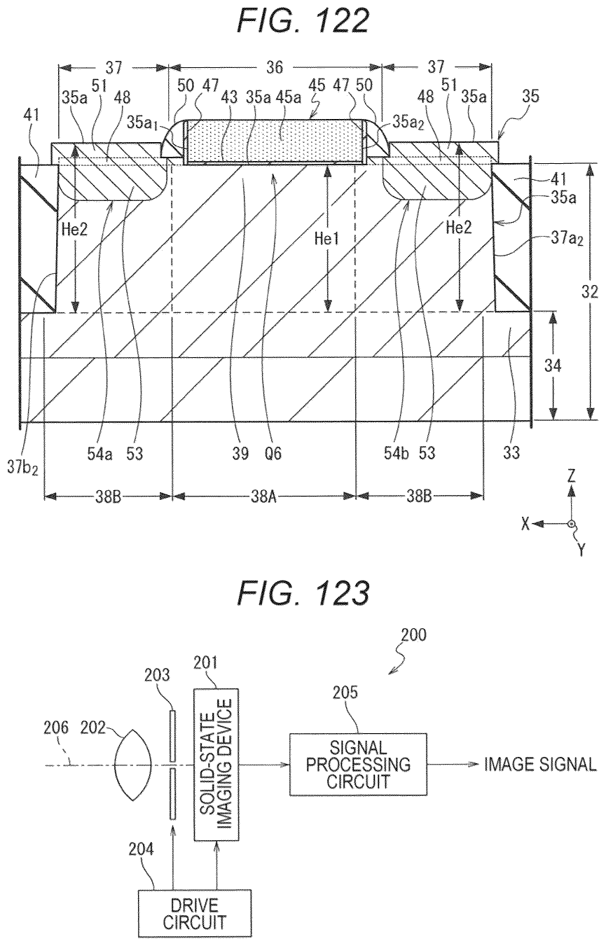

Next, heat treatment for activating the impurity (arsenic ions As⁺) implanted into the pair of second regions 38B and 38B of the semiconductor 35 is performed to form the pair of n-type semiconductor regions 53 and 53 in the pair of second regions 38B and 38B of the semiconductor 35 as illustrated in FIG. 122. Each of the pair of n-type semiconductor regions 53 is aligned with the sidewall spacer 50 and is formed across the growth layer 51, the growth layer 48, and the semiconductor layer 32. Then, each of the pair of n-type semiconductor regions 53 is in contact with the n-type growth layer 48a remaining as a part of the n-type growth layer 48 between the n-type semiconductor region 53 and the insulating film 47 in the second region 38B of the semiconductor 35 and is formed with a higher impurity concentration than the n-type growth layer 48a. The n-type growth layer 48a overlaps the sidewall spacer 50 in plan view.

In this step, the pair of main electrode regions 54a and 54b each including the n-type semiconductor region 53 are formed in the pair of second regions 38B and 38B of the semiconductor 35.

Furthermore, in this step, the channel formation portion 39 is formed in the semiconductor 35 between the pair of main electrode regions 54a and 54b.

Furthermore, in this step, the field effect transistor Q6 including the gate insulating film 43, the gate electrode 45, the pair of main electrode regions 54a and 54b, the channel formation portion 39, and the like is formed in the semiconductor 35.

Furthermore, in this step, the pair of main electrode regions 54a and 54b are formed in a structure protruding above the first region 38A of the semiconductor 35 (structure protruding upward).

Next, the insulating layer 55 covering the semiconductor 35 and the field effect transistor Q6 is formed on the insulating layer 41, and a surface layer of the insulating layer 55 remote from the semiconductor 35 is planarized, which results in a state illustrated in FIG. 119.

The semiconductor device 1F and the method for manufacturing the same according to the seventh embodiment can also produce effects similar to the effects produced by the semiconductor device 1E and the method for manufacturing the same according to the above-described sixth embodiment.

### Eighth Embodiment

### Examples of Application to Electronic Apparatus

The present technology (technology of the present disclosure) can be applied to various electronic apparatuses such as an imaging device such as a digital still camera or a digital video camera, a mobile phone having an imaging function, or other apparatuses having an imaging function, for example.

FIG. 123 is a diagram illustrating a schematic configuration of an electronic apparatus (for example, a camera) according to the sixth embodiment of the present technology.

As illustrated in FIG. 123, an electronic apparatus 200 includes the solid-state imaging device 201, the optical lens 202, a shutter device 203, a drive circuit 204, and a signal processing circuit 205. The electronic apparatus 200 is an embodiment in a case where the solid-state imaging device 1D according to the fifth embodiment of the present technology is used in an electronic apparatus (e.g., a camera) as the solid-state imaging device 201.

The optical lens 202 forms an image of image light (incident light 206) from a subject on an imaging surface of the solid-state imaging device 201. As a result, signal charges are accumulated in the solid-state imaging device 201 over a certain period of time. The shutter device 203 controls a light radiation period and a light blocking period for the solid-state imaging device 201. The drive circuit 204 supplies a drive signal for controlling a transfer operation of the solid-state imaging device 201 and a shutter operation of the shutter device 203. A signal of the solid-state imaging device 201 is transferred in accordance with the drive signal (timing signal) supplied from the drive circuit 204. The signal processing circuit 205 performs various types of signal processing on a signal (pixel signal (image signal) output from the solid-state imaging device 201. An image signal subjected to the signal processing is stored into a storage medium such as a memory, or is output to a monitor.

With such a configuration, since improvement in the reliability is achieved in the solid-state imaging device 201, improvement in the reliability can also be achieved in electronic apparatus 200 of the eighth embodiment.

Note that the electronic apparatus 200 to which the solid-state imaging device according to one of the above-described embodiments can be applied is not limited to a camera, and the solid-state imaging device can also be applied to other electronic apparatuses. For example, the solid-state imaging device may be applied to an imaging device such as a camera module for a mobile device such as a mobile phone or a tablet terminal.

Furthermore, the present technology can be applied to any photodetector including not only the above-described solid-state imaging device as an image sensor but also a ranging sensor that is also called a time of flight (ToF) sensor and measures a distance, and the like. The ranging sensor is a sensor that emits irradiation light toward an object, detects reflected light that is the irradiation light reflected from a surface of the object, and calculates a distance to the object on the basis of a flight time from the emission of the irradiation light to reception of the reflected light. As a structure of an element isolation region of the ranging sensor, the structure of the element isolation region described above may be employed.

### Other Embodiments

In the above-described embodiments, the case where the field effect transistor is provided in the rectangular parallelepiped semiconductor 5 extending in the X direction has been described. The present technology, however, is not limited to the rectangular parallelepiped semiconductor 5.

For example, the present technology can also be applied to a field effect transistor in which a channel formation portion and a gate electrode are provided at a corner of a semiconductor having an L-shaped planar shape.

Furthermore, in the above-described first to fifth embodiments, the island-shaped semiconductor 5 integrated with the base 4 of the semiconductor layer 2 have been described as a semiconductor. The present technology, however, is not limited to the island-shaped semiconductor 5 integrated with the base 4.

For example, the present technology can also be applied to a so-called silicon on insulator (SOI) structure in which a semiconductor is provided on an insulating layer. In this case, the semiconductor has a bottom surface in contact with the insulating layer on a side opposite an upper surface.

Furthermore, the present technology can also be applied to a semiconductor device including both a fin field effect transistor and a planar field effect transistor.

Note that the present technology may also have the following configurations.
(1)

A semiconductor device including:
an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including the upper surface and the side surface;
an insulating layer that surrounds each of the first portion and the second portion;
a field effect transistor including a gate electrode that is separated from the second portion and is provided across the upper surface and the side surface of the first portion; and
a dielectric portion that is provided between the gate electrode and the second portion and is lower in relative permittivity than the insulating layer.
(2)

The semiconductor device according to the above (1), in which
the dielectric portion includes a dielectric film lower in relative permittivity than the insulating layer.
(3)

The semiconductor device according to the above (1), in which
the dielectric portion includes a cavity lower in relative permittivity than the insulating layer.
(4)

The semiconductor device according to any one of the above (1) to (3), in which
the field effect transistor further includes a gate insulating film interposed between the first portion and the gate electrode, and
the dielectric portion is lower in relative permittivity than the gate insulating film.
(5)

The semiconductor device according to any one of the above (1) to (4), in which
a width of the dielectric portion along the first direction is larger than a film thickness of the gate insulating film.
(6)

The semiconductor device according to any one of the above (1) to (5), in which
the gate electrode includes a head protruding above the insulating layer and a leg integrated with the head and provided in the insulating layer, and
a side surface of the head in the first direction and a side surface of the leg in the first direction are flush with each other in cross-sectional view.
(7)

The semiconductor device according to any one of the above (1) to (6), in which
the gate electrode includes a head protruding above the insulating layer and a leg integrated with the head and provided in the insulating layer, and
the dielectric portion is surrounded by the first portion, the second portion, the leg, and
the insulating layer on all sides in plan view.
(8)

The semiconductor device according to any one of the above (1) to (7), in which
the field effect transistor further includes a pair of main electrode regions provided in the semiconductor located on both sides of the gate electrode in a gate length direction.
(9)

The semiconductor device according to the above (8), in which
the field effect transistor further includes a sidewall spacer provided on a sidewall of the gate electrode, and
each of the pair of main electrode regions includes an extending region that is provided in the semiconductor, aligned with the gate electrode and a contact region that is provided in the semiconductor, aligned with the sidewall spacer and is higher in impurity concentration than the extension region.
(10)

The semiconductor device according to any one of the above (1) to (9), further including:
a photoelectric converter; and
a pixel circuit that converts a signal charge generated as a result of photoelectric conversion in the photoelectric converter into a pixel signal, in which
at least one of a plurality of pixel transistors included in the pixel circuit includes the field effect transistor.
(11)

The semiconductor device according to the above (10), further including a semiconductor layer arranged to overlap the semiconductor in plan view and provided with the photoelectric converter.
(12)

A method for manufacturing a semiconductor device, the method including:
forming an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
forming an insulating layer that surrounds each of the first portion and the second portion;
forming a gate electrode that is separated from the second portion and faces the upper surface and the side surface of the first portion; and
forming a dielectric portion between the gate electrode and the second portion, the dielectric portion being lower in relative permittivity than the insulating layer.
(13)

The method for manufacturing a semiconductor device according to the above (12), further including forming an extension region by ion-implanting an impurity into the semiconductor located outside the gate electrode using the gate electrode and the dielectric portion as a mask.
(14)

A method for manufacturing a semiconductor device, the method including:
forming an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
forming an insulating layer that surrounds each of the first portion and the second portion;
forming a recessed portion by selectively removing the insulating layer located outside the first portion in the second direction;
forming a conductive film that covers the semiconductor so as to be embedded in the recessed portion;
forming a gate electrode by patterning the conductive film, the gate electrode including a leg and head, the leg being located adjacent to the first portion and embedded in the recessed portion, the head being integrated with the leg, overlapping the first portion, and having a width in a direction identical to a width of the leg along the first direction smaller than the width of the leg;
forming an extension region by selectively ion-implanting an impurity into the semiconductor located outside the head with the leg remaining between the head and the second portion in plan view; and
removing the leg located outside the head.
(15)

The method for manufacturing a semiconductor device according to the above (14), in which
the removing the leg located outside the head is performed by collectively etching the head and the leg in a height direction of the semiconductor so as to recess a side surface of the head inward.
(16)

The method for manufacturing a semiconductor device according to the above (15), in which
the etching is performed to a depth near a bottom of the recessed portion.
(17)

The method for manufacturing a semiconductor device according to any one of the above (14) to (16), further including forming a sidewall spacer on a sidewall of the gate electrode after the leg located outside the head is removed, the sidewall spacer covering respective side surfaces of the head and the leg.
(18)

The method for manufacturing a semiconductor device according to the above (17), in which
the sidewall spacer includes an insulating film lower in relative permittivity than the insulating layer.
(19)

A semiconductor device including:
a semiconductor including an upper surface and a side surface; and
a field effect transistor provided in the semiconductor, in which
the semiconductor includes a first region and a pair of second regions that are provided contiguous with the first region on both sides of the first region in a first direction and are higher than the first region, and
the field effect transistor includes a gate electrode provided across the upper surface and the side surface of the first region with a gate insulating film interposed between the gate electrode and the first region, and a pair of main electrode regions provided in the pair of second regions.
(20)

The semiconductor device according to the above (19), in which
the first region has a width in a direction identical to a gate length direction of the gate electrode larger than a width of the gate electrode in the gate length direction.
(21)

The semiconductor device according to the above (19) or (20), in which
the field effect transistor further includes an insulating film provided on a sidewall of the gate electrode, and
each of the pair of second regions is located outside the insulating film.
(22)

The semiconductor device according to any one of the above (19) to (21), in which
the first region of the semiconductor includes a semiconductor layer,
the second regions of the semiconductor each include the semiconductor layer and a growth layer formed on the semiconductor layer by epitaxial growth, aligned with the insulating film,
the field effect transistor further includes a sidewall spacer formed on the growth layer located outside the insulating film, aligned with the insulating film, and
each of the pair of main electrode regions includes a semiconductor region aligned with the sidewall spacer and formed across the growth layer and the semiconductor layer of a corresponding one of the second regions.
(23)

The semiconductor device according to any one of the above (19) to (22), further including:
a photoelectric converter; and
a pixel circuit that converts a signal charge generated as a result of photoelectric conversion in the photoelectric converter into a pixel signal, in which
at least one of a plurality of pixel transistors included in the pixel circuit includes the field effect transistor.
(24)

The semiconductor device according to the above (23), further including a semiconductor layer arranged to overlap the semiconductor in plan view and provided with the photoelectric converter.
(25)

A method for manufacturing a semiconductor device, the method including:
forming a semiconductor including a first region, a pair of second regions provided contiguous with the first region on both sides of the first region in a first direction, and an upper surface and a side surface provided across the first region and the second region;
forming a gate electrode facing the upper surface and the side surface of the first region with a gate insulating film interposed between the gate electrode and the first region in a second direction intersecting the first direction;
making each of the pair of second regions higher than the first region by epitaxial growth; and
forming a pair of main electrode regions in the pair of second regions.
(26)

An electronic apparatus including:
a semiconductor device;
an optical lens that forms an image of image light from a subject on an imaging surface of the semiconductor device; and
a signal processing circuit that performs signal processing on a signal output from the semiconductor layer, in which
the semiconductor device includes:
an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
an insulating layer that surrounds each of the first portion and the second portion;
a field effect transistor including a gate electrode that is separated from the second portion and is provided across the upper surface and the side surface of the first portion; and
a dielectric portion that is provided between the gate electrode and the second portion and is lower in relative permittivity than the insulating layer.

The scope of the present technology is not limited to the exemplary embodiments illustrated in the drawings and described above, but includes all embodiments that produce effects equivalent to the effects that the present technology intends to produce. Moreover, the scope of the present technology is not limited to the combinations of the features of the invention defined by the claims, and may be defined by any desired combination of specific features among all the disclosed features.

### REFERENCE SIGNS LIST

1A, 1B, 1C, 1E, 1F Semiconductor device
1D Solid-state imaging device
2 Semiconductor layer
3 Well region
4 Base
5 Semiconductor
5a Upper surface
5a₁ Step portion
5b Side surface
6 First portion
6b₁, 6b₂ Side surface
7 Second portion
7b₁, 7b₂, 7b₃, 7b₄ Side surface
9 Channel formation portion
11 Insulating layer
12a, 12b Recessed portion (gate electrode recessed portion)
13 Gate insulating film
14 Conductive film (gate electrode material)
15 Gate electrode
15a Head
15a₁, 15a₂ Side surface
15b Leg
15b₁, 15b₂ Side surface
16 Gap (opening)
17, 17B Dielectric portion
17b₁ Cavity
17b₂ Insulating film
18 Extension region
19 Sidewall spacer
20 Contact region
21a, 21b Main electrode region
22 Insulating layer
22a, 22b, 22c Contact electrode
23a, 23b, 23c Wire
25, 26 Parasitic capacitance
28 Third portion
32 Semiconductor layer
33 p-type well region
34 Base
35 Semiconductor
35a Upper surface
35b Side surface
36 First portion
36b₁, 6b₂ Side surface
37 Second portion
37b₁, 37b₂, 37b₃, 37b₄ Side surface
38A First region
38B Second region
39 Channel formation portion
41 Insulating layer
42a, 42b Recessed portion (gate electrode recessed portion)
43 Gate insulating film
44 Conductive film (gate electrode material)
45 Gate electrode
45a Head
45a₁, 15a₂ Side surface
45b Leg
45b₁, 15b₂ Side surface
46 Gap (opening)
47 Insulating film (isolation insulating film)
48 Growth layer (epitaxial layer)
50 Sidewall spacer
51 Growth layer (epitaxial layer)
53 n-type semiconductor region
54a, 54b Main electrode region
55 Insulating layer
102 Semiconductor chip
102A Pixel array unit
102B Peripheral portion
103 Pixel
104 Vertical drive circuit
105 Column signal processing circuit
106 Horizontal drive circuit
107 Output circuit
108 Control circuit
110 Pixel drive line
111 Vertical signal line
113 Logic circuit
114 Bonding pad
115 Reading circuit
130 Semiconductor layer (second semiconductor layer)
131 Wiring layer
141 Planarization layer
142 Filter layer
143 Lens layer
200 Electronic apparatus
201 Solid-state imaging device
202 Optical lens
203 Shutter device
204 Drive circuit
205 Signal processing circuit
206 Incident light
AMP Amplification transistor
FDG Switching transistor
RST Reset transistor
SEL Selection transistor
S1 First surface
S2 Second surface
TR Transfer transistor
Q, Q1, Q2 Field effect transistor

What is claimed is:

1. A semiconductor device, comprising:
an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including the upper surface and the side surface;
an insulating layer that surrounds each of the first portion and the second portion;
a field effect transistor including a gate electrode that is separated from the second portion and is provided across the upper surface and the side surface of the first portion; and
a dielectric portion that is provided between the gate electrode and the second portion and is lower in relative permittivity than the insulating layer.

2. The semiconductor device according to claim 1, wherein
the dielectric portion includes a dielectric film lower in relative permittivity than the insulating layer.

3. The semiconductor device according to claim 1, wherein
the dielectric portion includes a cavity lower in relative permittivity than the insulating layer.

4. The semiconductor device according to claim 1, wherein
the field effect transistor further includes a gate insulating film interposed between the first portion and the gate electrode, and
the dielectric portion is lower in relative permittivity than the gate insulating film.

5. The semiconductor device according to claim 4, wherein
a width of the dielectric portion along the first direction is larger than a film thickness of the gate insulating film.

6. The semiconductor device according to claim 4, wherein
the gate electrode includes a head protruding above the insulating layer and a leg integrated with the head and provided in the insulating layer, and
a side surface of the head in the first direction and a side surface of the leg in the first direction are flush with each other in cross-sectional view.

7. The semiconductor device according to claim 1, wherein
the gate electrode includes a head protruding above the insulating layer and a leg integrated with the head and provided in the insulating layer, and
the dielectric portion is surrounded by the first portion, the second portion, the leg, and the insulating layer on all sides in plan view.

8. The semiconductor device according to claim 1, wherein
the field effect transistor further includes a pair of main electrode regions provided in the semiconductor located on both sides of the gate electrode in a gate length direction.

9. The semiconductor device according to claim 8, wherein
the field effect transistor further includes a sidewall spacer provided on a sidewall of the gate electrode, and
each of the pair of main electrode regions includes an extending region that is provided in the semiconductor, aligned with the gate electrode and a contact region that is provided in the semiconductor, aligned with the sidewall spacer and is higher in impurity concentration than the extension region.

10. The semiconductor device according to claim 1, further comprising:
a photoelectric converter; and
a pixel circuit that converts a signal charge generated as a result of photoelectric conversion in the photoelectric converter into a pixel signal, wherein
at least one of a plurality of pixel transistors included in the pixel circuit includes the field effect transistor.

11. The semiconductor device according to claim 10, further comprising a semiconductor layer arranged to overlap the semiconductor in plan view and provided with the photoelectric converter.

12. A method for manufacturing a semiconductor device, the method comprising:
forming an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
forming an insulating layer that surrounds each of the first portion and the second portion;
forming a gate electrode that is separated from the second portion and faces the upper surface and the side surface of the first portion; and
forming a dielectric portion between the gate electrode and the second portion, the dielectric portion being lower in relative permittivity than the insulating layer.

13. The method for manufacturing a semiconductor device according to claim 12, further comprising forming an extension region by ion-implanting an impurity into the semiconductor located outside the gate electrode using the gate electrode and the dielectric portion as a mask.

14. A method for manufacturing a semiconductor device, the method comprising:
forming an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
forming an insulating layer that surrounds each of the first portion and the second portion;
forming a recessed portion by selectively removing the insulating layer located outside the first portion in the second direction;
forming a conductive film that covers the semiconductor so as to be embedded in the recessed portion;
forming a gate electrode by patterning the conductive film, the gate electrode including a leg and head, the leg being located adjacent to the first portion and embedded in the recessed portion, the head being integrated with the leg, overlapping the first portion, and having a width in a direction identical to a width of the leg along the first direction smaller than the width of the leg;
forming an extension region by selectively ion-implanting an impurity into the semiconductor located outside the head with the leg remaining between the head and the second portion in plan view; and
removing the leg located outside the head.

15. The method for manufacturing a semiconductor device according to claim 14, wherein
the removing the leg located outside the head is performed by collectively etching the head and the leg in a height direction of the semiconductor so as to recess a side surface of the head inward.

16. The method for manufacturing a semiconductor device according to claim 15, wherein
the etching is performed to a depth near a bottom of the recessed portion.

17. The method for manufacturing a semiconductor device according to claim 14, further comprising forming a sidewall spacer on a sidewall of the gate electrode after the leg located outside the head is removed, the sidewall spacer covering respective side surfaces of the head and the leg.

18. The method for manufacturing a semiconductor device according to claim 17, wherein
the sidewall spacer includes an insulating film lower in relative permittivity than the insulating layer.

19. A semiconductor device, comprising:
a semiconductor including an upper surface and a side surface; and
a field effect transistor provided in the semiconductor, wherein
the semiconductor includes a first region and a pair of second regions that are provided contiguous with the first region on both sides of the first region in a first direction and are higher than the first region, and
the field effect transistor includes a gate electrode provided across the upper surface and the side surface of the first region with a gate insulating film interposed between the gate electrode and the first region, and a pair of main electrode regions provided in the pair of second regions.

20. The semiconductor device according to claim 19, wherein
the first region has a width in a direction identical to a gate length direction of the gate electrode larger than a width of the gate electrode in the gate length direction.

21. The semiconductor device according to claim 19, wherein
the field effect transistor further includes an insulating film provided on a sidewall of the gate electrode, and
each of the pair of second regions is located outside the insulating film.

22. The semiconductor device according to claim 21, wherein
the first region of the semiconductor includes a semiconductor layer,
the second regions of the semiconductor each include the semiconductor layer and a growth layer formed on the semiconductor layer by epitaxial growth, aligned with the insulating film,
the field effect transistor further includes a sidewall spacer formed on the growth layer located outside the insulating film, aligned with the insulating film, and
each of the pair of main electrode regions includes a semiconductor region aligned with the sidewall spacer and formed across the growth layer and the semiconductor layer of a corresponding one of the second regions.

23. A method for manufacturing a semiconductor device, the method comprising:
forming a semiconductor including a first region, a pair of second regions provided contiguous with the first region on both sides of the first region in a first direction, and an upper surface and a side surface provided across the first region and the second region;
forming a gate electrode facing the upper surface and the side surface of the first region with a gate insulating film interposed between the gate electrode and the first region in a second direction intersecting the first direction;
making each of the pair of second regions higher than the first region by epitaxial growth; and
forming a pair of main electrode regions in the pair of second regions.

24. An electronic apparatus, comprising:
a semiconductor device;
an optical lens that forms an image of image light from a subject on an imaging surface of the semiconductor device; and
a signal processing circuit that performs signal processing on a signal output from the semiconductor layer, wherein
the semiconductor device includes:
an island-shaped semiconductor including a first portion and a second portion that is provided integrally alongside the first portion in a first direction and has a width in a direction identical to a width of the first portion along a second direction intersecting the first direction larger than the width of the first portion, the first portion and the second portion each including an upper surface and a side surface;
an insulating layer that surrounds each of the first portion and the second portion;
a field effect transistor including a gate electrode that is separated from the second portion and is provided across the upper surface and the side surface of the first portion; and
a dielectric portion that is provided between the gate electrode and the second portion and is lower in relative permittivity than the insulating layer.
